(19) United States
(12) Patent Application Publication
(10) Pub. No.: US 2026/0227494 A1
(43) Pub. Date: Aug. 6, 2026

(54) PHOTODETECTOR AND DISTANCE MEASUREMENT SYSTEM

(71) Applicant: SONY SEMICONDUCTOR SOLUTIONS CORPORATION, KANAGAWA (JP)

(72) Inventors: MASATAKA YAMANE, KANAGAWA (JP); YHANG SILVA, KANAGAWA (JP); TAKAHIRO TOYOSHIMA, KANAGAWA (JP); YOSHIAKI TASHIRO, KANAGAWA (JP)

(21) Appl. No.: 19/151,338

(22) PCT Filed: Dec. 15, 2023
(86) PCT No.: PCT/JP2023/044961

§ 371 Date: Jul. 28, 2025

(30) Foreign Application Priority Data
Feb. 8, 2023 (JP) 2023-017424

(51) Int. Cl. G01S 7/4863; G01S 17/10

(52) U.S. Cl. CPC G01S 7/4863; G01S 17/10

(57) ABSTRACT

A photodetector includes: a SPAD that is provided in a first region of a first base, and amplifies a carrier generated by an incident photon; one or more elements that are provided in a second region adjacent to the first region of the first base in a plane direction of the first base, and are different from the SPAD; and an insulating isolator that is provided between the first region and the second region, and at least electrically isolates the SPAD and the one or more elements from each other.

### TECHNICAL FIELD

The present disclosure relates to a photodetector and a distance measurement system.

### BACKGROUND ART

PTL 1 discloses a light-receiving device and a distance measurement device. The light-receiving device includes a light-receiving element and a readout circuit. The light-receiving element generates a signal in response to reception of a photon. The readout circuit reads out the signal generated by the light-receiving element.

A single-photon avalanche diode (hereinafter simply referred to as a “SPAD”) is used for the light-receiving element.

The distance measurement device includes the light-receiving device. The distance measurement device measures time of flight (ToF) it takes for light emitted from a light source to be reflected by a distance measurement target and return.

In the light-receiving element disclosed in PTL 1, a protective circuit is interposed between the SPAD and the readout circuit coupled to the SPAD. The protective circuit includes a resistor, a diode, or a MOS (Metal Oxide Semiconductor) transistor.

For example, in a case where the SPAD is irradiated with a larger amount of laser light than expected, an internal impedance of the SPAD greatly decreases, and an excessive voltage is applied to the readout circuit. The protective circuit allows for reduction or absorption of such an excessive voltage.

### CITATION LIST

### Patent Literature

PTL 1: International Publication No. WO 2021/192770A1

### SUMMARY OF THE INVENTION

In a light-receiving element and a distance measurement device disclosed in PTL 1 described above, a protective circuit is disposed to overlap a SPAD on a side opposite to a photon incident side of the SPAD.

In a case where the protective circuit includes, for example, a resistor, an insulator is formed between the SPAD and the resistor. In order to mitigate an effect of an electric field from the resistor to the SPAD, it is necessary to increase a film thickness of the insulator.

In addition, in a case where the protective circuit includes, for example, a MOS transistor, a potential to be applied to a well region where the MOS transistor is disposed is different from a potential to be applied to a well region where the SPAD is disposed. For this reason, it is necessary to secure a well region where a potential is separated for the SPAD.

It is therefore desirable to provide a photodetector and a distance measurement system in which it is possible to easily provide an element or the like that constructs each of an avalanche diode and a protective circuit without being restricted by the avalanche diode.

A photodetector according to a first aspect of the present disclosure includes an avalanche diode, one or more elements, and an insulating isolator. The avalanche diode is provided in a first region of a first base, and amplifies a carrier generated by an incident photon. The one or more elements are provided in a second region adjacent to the first region of the first base in a plane direction of the first base, and are different from the avalanche diode. The insulating isolator is provided between the first region and the second region, and at least electrically isolates the avalanche diode and the one or more elements from each other.

A distance measurement system according to a second aspect of the present disclosure includes a photodetector and a circuit device. The photodetector includes an avalanche diode, a protective circuit, and an insulating isolator. The avalanche diode is provided in a first region of a first base, and amplifies a carrier generated by an incident photon. The protective circuit is provided in a second region adjacent to the first region of the first base in a plane direction of the first base, and includes one or more elements that reduce an overcurrent from the avalanche diode. The insulating isolator is provided between the first region and the second region, and at least electrically isolates the avalanche diode and the one or more elements from each other. The circuit device includes a readout circuit and a time measurement circuit. The readout circuit is electrically coupled to the avalanche diode via the protective circuit, and reads out the amplified carrier. The time measurement circuit is electrically coupled to the readout circuit, and measures time of flight of light.

A photodetector according to a third aspect of the present disclosure includes an avalanche diode, a light-receiving element, and an insulating isolator. The avalanche diode is provided in a first region of a first base, and amplifies a carrier generated by an incident photon. The light-receiving element is provided in a second region adjacent to the first region of the first base in a plane direction of the first base, and converts incident light into electric charge. The insulating isolator is provided between the first region and the second region, and at least electrically isolates the avalanche diode and the light-receiving element from each other.

A distance measurement system according to a fourth aspect of the present disclosure includes a photodetector, a first time measurement circuit, and a second time measurement circuit. The photodetector includes an avalanche diode, a light-receiving element, and an insulating isolator. The avalanche diode is provided in a first region of a first base, and amplifies a carrier generated by an incident photon. The light-receiving element is provided in a second region adjacent to the first region of the first base in a plane direction of the first base, and converts incident light into electric charge. The insulating isolator is provided between the first region and the second region, and at least electrically isolates the avalanche diode and the light-receiving element from each other. The first time measurement circuit is electrically coupled to the avalanche diode, and measures time of flight of light. The second time measurement circuit is electrically coupled to the light-receiving element, and measures time of flight of light at a shorter distance than the first time measurement circuit.

A photodetector according to a fifth aspect of the present disclosure includes an avalanche diode, a charge storage type photodiode, and an insulating isolator. The avalanche diode is provided in a first region of a first base, and amplifies a carrier generated by an incident photon. The charge storage type photodiode is provided in a second region adjacent to the first region of the first base in a plane direction of the first base, and converts incident light into electric charge. The insulating isolator is provided between the first region and the second region, and at least electrically isolates the avalanche diode and the charge storage type photodiode from each other.

A distance measurement system according to a sixth aspect of the present disclosure includes a photodetector, a time measurement circuit, and an analog-to-digital convertor circuit. The photodetector includes an avalanche diode, a charge storage type photodiode, and an insulating isolator. The avalanche diode is provided in a first region of a first base, and amplifies a carrier generated by an incident photon. The charge storage type photodiode is provided in a second region adjacent to the first region of the first base in a plane direction of the first base, and converts incident light into electric charge. The insulating isolator is provided between the first region and the second region, and at least electrically isolates the avalanche diode and the charge storage type photodiode from each other. The time measurement circuit is electrically coupled to the avalanche diode, and measures time of flight of light. The analog-to-digital convertor circuit is electrically coupled to the charge storage type photodiode, and converts electric charge from an analog signal to a digital signal.

### BRIEF DESCRIPTION OF THE DRAWINGS

FIG. 1 is a circuit configuration diagram of one pixel in a photodetector and a distance measurement system according to a 1-1st embodiment of the present disclosure.

FIG. 2 is a schematic longitudinal cross-sectional configuration diagram (a cross-sectional view taken along a cutting line A-A illustrated in FIG. 3) of the one pixel in the photodetector and the distance measurement system that are illustrated in FIG. 1.

FIG. 3 is a planar configuration diagram of the one pixel in the photodetector illustrated in FIG. 2.

FIG. 4 is a planar configuration diagram of the photodetector in which a plurality of pixels illustrated in FIG. 3 is arranged.

FIG. 5 is a circuit configuration diagram of one pixel in a photodetector and a distance measurement system according to a 1-2nd embodiment of the present disclosure.

FIG. 6 is a schematic longitudinal cross-sectional configuration diagram (a cross-sectional view taken along a cutting line B-B illustrated in FIG. 7) of the one pixel in the photodetector and the distance measurement system that are illustrated in FIG. 5.

FIG. 7 is a planar configuration diagram of the one pixel in the photodetector illustrated in FIG. 6.

FIG. 8 is a circuit configuration diagram of one pixel in a photodetector and a distance measurement system according to a 1-3rd embodiment of the present disclosure.

FIG. 9 is a schematic longitudinal cross-sectional configuration diagram (a cross-sectional view taken along a cutting line C-C illustrated in FIG. 10) of the one pixel in the photodetector and the distance measurement system that are illustrated in FIG. 8.

FIG. 10 is a planar configuration diagram of the one pixel in the photodetector illustrated in FIG. 9.

FIG. 11 is a circuit configuration diagram of one pixel in a photodetector and a distance measurement system according to a 1-4th embodiment of the present disclosure.

FIG. 12 is a schematic longitudinal cross-sectional configuration diagram (a cross-sectional view taken along a cutting line D-D illustrated in FIG. 13) of the one pixel in the photodetector and the distance measurement system that are illustrated in FIG. 11.

FIG. 13 is a planar configuration diagram of the one pixel in the photodetector illustrated in FIG. 12.

FIG. 14 is a circuit configuration diagram of one pixel in a photodetector and a distance measurement system according to a 1-5th embodiment of the present disclosure.

FIG. 15 is a schematic longitudinal cross-sectional configuration diagram (a cross-sectional view taken along a cutting line E-E illustrated in FIG. 16) of the one pixel in the photodetector and the distance measurement system that are illustrated in FIG. 14.

FIG. 16 is a planar configuration diagram of the one pixel in the photodetector illustrated in FIG. 15.

FIG. 17 is a circuit configuration diagram of one pixel in a photodetector and a distance measurement system according to a 1-6th embodiment of the present disclosure.

FIG. 18 is a schematic longitudinal cross-sectional configuration diagram (a cross-sectional view taken along a cutting line F-F illustrated in FIG. 19) of the one pixel in the photodetector and the distance measurement system that are illustrated in FIG. 17.

FIG. 19 is a planar configuration diagram of the one pixel in the photodetector illustrated in FIG. 18.

FIG. 20 is a circuit configuration diagram of one pixel in a photodetector and a distance measurement system according to a 1-7th embodiment of the present disclosure.

FIG. 21 is a schematic longitudinal cross-sectional configuration diagram (a cross-sectional view taken along a cutting line G-G illustrated in FIG. 22) of the one pixel in the photodetector and the distance measurement system that are illustrated in FIG. 20.

FIG. 22 is a planar configuration diagram of the one pixel in the photodetector illustrated in FIG. 21.

FIG. 23 is a planar configuration diagram, corresponding to FIG. 3, of one pixel in a photodetector and a distance measurement system according to a 1-8th embodiment of the present disclosure.

FIG. 24 is a planar configuration diagram, corresponding to FIG. 4, of the photodetector in which a plurality of pixels illustrated in FIG. 23 is arranged.

FIG. 25 is a planar configuration diagram, corresponding to FIG. 4 in which the plurality of pixels is arranged, of a photodetector according to a first modification example of the 1-8th embodiment.

FIG. 26 is a planar configuration diagram, corresponding to FIG. 4 in which the plurality of pixels is arranged, of a photodetector according to a second modification example of the 1-8th embodiment.

FIG. 27 is a circuit configuration diagram of a plurality of pixels in a photodetector and a distance measurement system according to a 1-9th embodiment of the present disclosure.

FIG. 28 is a schematic longitudinal cross-sectional configuration diagram (a cross-sectional view taken along a cutting line H-H illustrated in FIG. 29) of the plurality of pixels in the photodetector and the distance measurement system that are illustrated in FIG. 27.

FIG. 29 is a planar configuration diagram of the plurality of pixels in the photodetector illustrated in FIG. 28.

FIG. 30 is a circuit configuration diagram of a plurality of pixels in a photodetector and a distance measurement system according to a 1-10th embodiment of the present disclosure.

FIG. 31 is a schematic longitudinal cross-sectional configuration diagram (a cross-sectional view taken along a cutting line I-I illustrated in FIG. 32) of the plurality of pixels in the photodetector and the distance measurement system that are illustrated in FIG. 30.

FIG. 32 is a planar configuration diagram of the plurality of pixels in the photodetector illustrated in FIG. 31.

FIG. 33 is a circuit configuration diagram of a plurality of pixels in a photodetector and a distance measurement system according to a 1-11th embodiment of the present disclosure.

FIG. 34 is a schematic longitudinal cross-sectional configuration diagram (a cross-sectional view taken along a cutting line J-J illustrated in FIG. 35) of the plurality of pixels in the photodetector and the distance measurement system illustrated in FIG. 33.

FIG. 35 is a planar configuration diagram of the plurality of pixels in the photodetector illustrated in FIG. 34.

FIG. 36 is a circuit configuration diagram of a plurality of pixels in a photodetector and a distance measurement system according to a 1-12th embodiment of the present disclosure.

FIG. 37 is a schematic longitudinal cross-sectional configuration diagram (a cross-sectional view taken along a cutting line K-K illustrated in FIG. 38) of the plurality of pixels in the photodetector and the distance measurement system that are illustrated in FIG. 36.

FIG. 38 is a planar configuration diagram of the plurality of pixels in the photodetector illustrated in FIG. 37.

FIG. 39 is a circuit configuration diagram of a plurality of pixels in a photodetector and a distance measurement system according to a 1-13th embodiment of the present disclosure.

FIG. 40 is a schematic longitudinal cross-sectional configuration diagram (a cross-sectional view taken along a cutting line L-L illustrated in FIG. 38) of the plurality of pixels in the photodetector and the distance measurement system that are illustrated in FIG. 39.

FIG. 41 is a planar configuration diagram of the plurality of pixels in the photodetector illustrated in FIG. 40.

FIG. 42 is a circuit configuration diagram of a plurality of pixels in a photodetector and a distance measurement system according to a 1-14th embodiment of the present disclosure.

FIG. 43 is a schematic longitudinal cross-sectional configuration diagram (a cross-sectional view taken along a cutting line M-M illustrated in FIG. 44) of the plurality of pixels in the photodetector and the distance measurement system that are illustrated in FIG. 42.

FIG. 44 is a planar configuration diagram of the plurality of pixels in the photodetector illustrated in FIG. 43.

FIG. 45 is a planar configuration diagram of a plurality of pixels in a photodetector according to a 1-15th embodiment of the present disclosure.

FIG. 46 is a planar configuration diagram of a plurality of pixels in a photodetector according to a 1-16th embodiment of the present disclosure.

FIG. 47 is a circuit configuration diagram of one pixel in a photodetector and a distance measurement system according to a 2-1st embodiment of the present disclosure.

FIG. 48 is a schematic longitudinal cross-sectional configuration diagram (a cross-sectional view taken along a cutting line N-N illustrated in FIG. 49) of the photodetector in which a plurality of pixels illustrated in FIG. 47 is arranged.

FIG. 49 is a planar configuration diagram of the photodetector in which the plurality of pixels illustrated in FIG. 48 is arranged.

FIG. 50 is a schematic longitudinal cross-sectional configuration diagram (a cross-sectional view taken along a cutting line O-O illustrated in FIG. 51) of a pixel in a photodetector according to a 2-2nd embodiment of the present disclosure.

FIG. 51 is a planar configuration diagram of the pixel in the photodetector illustrated in FIG. 50.

FIG. 52 is a circuit configuration diagram of one pixel in a photodetector and a distance measurement system according to a 2-3rd embodiment of the present disclosure.

FIG. 53 is a schematic longitudinal cross-sectional configuration diagram (a cross-sectional view taken along a cutting line P-P illustrated in FIG. 54) of the photodetector in which a plurality of pixels illustrated in FIG. 52 is arranged.

FIG. 54 is a planar configuration diagram of the pixel in the photodetector illustrated in FIG. 53.

FIG. 55 is a planar configuration diagram of a plurality of pixels in a photodetector according to a 2-4th embodiment of the present disclosure.

FIG. 56 is a planar configuration diagram of a plurality of pixels in a photodetector according to a 2-5th embodiment of the present disclosure.

FIG. 57 is a planar configuration diagram of a plurality of pixels in a photodetector according to a 2-6th embodiment of the present disclosure.

FIG. 58 is a planar configuration diagram of a plurality of pixels in a photodetector according to a 2-7th embodiment of the present disclosure.

FIG. 59 is a circuit configuration diagram of one pixel in a photodetector and a distance measurement system according to a 3-1st embodiment of the present disclosure.

FIG. 60 is a schematic longitudinal cross-sectional configuration diagram (a cross-sectional view taken along a cutting line Q-Q illustrated in FIG. 61) of a plurality of pixels in the photodetector illustrated in FIG. 59.

FIG. 61 is a planar configuration diagram of the plurality of pixels in the photodetector illustrated in FIG. 60.

FIG. 62 is a first step cross-sectional view for describing a manufacturing method of the photodetector and the distance measurement system according to the 3-1st embodiment for each of steps.

FIG. 63 is a second step cross-sectional view of the photodetector and the distance measurement system.

FIG. 64 is a third step cross-sectional view of the photodetector and the distance measurement system.

FIG. 65 is a fourth step cross-sectional view of the photodetector and the distance measurement system.

FIG. 66 is a fifth step cross-sectional view of the photodetector and the distance measurement system.

FIG. 67 is a sixth step cross-sectional view of the photodetector and the distance measurement system.

FIG. 68 is a seventh step cross-sectional view of the photodetector and the distance measurement system.

FIG. 69 is an eighth step cross-sectional view of the photodetector and the distance measurement system.

FIG. 70 is a ninth step cross-sectional view of the photodetector and the distance measurement system.

FIG. 71 is a circuit configuration diagram of one pixel in a photodetector and a distance measurement system according to a 3-2nd embodiment of the present disclosure.

FIG. 72 is a schematic longitudinal cross-sectional configuration diagram (a cross-sectional view taken along a cutting line R-R illustrated in FIG. 73) of a plurality of pixels in the photodetector illustrated in FIG. 73.

FIG. 73 is a planar configuration diagram of the plurality of pixels in the photodetector illustrated in FIG. 72.

FIG. 74 is a schematic longitudinal cross-sectional configuration diagram (a cross-sectional view taken along a cutting line S-S illustrated in FIG. 75) of a plurality of pixels in a photodetector and a distance measurement system according to a 3-3rd embodiment of the present disclosure.

FIG. 75 is a planar configuration diagram of the plurality of pixels in the photodetector illustrated in FIG. 74.

FIG. 76 is a circuit configuration diagram of one pixel in a photodetector and a distance measurement system according to a 3-4th embodiment of the present disclosure.

FIG. 77 is a schematic longitudinal cross-sectional configuration diagram, corresponding to FIG. 60, of a plurality of pixels in a photodetector and a distance measurement system according to a 3-5th embodiment of the present disclosure.

FIG. 78 is a schematic longitudinal cross-sectional configuration diagram, corresponding to FIG. 77, of a plurality of pixels in a photodetector and a distance measurement system according to a first modification example of the 3-5th embodiment.

FIG. 79 is a schematic longitudinal cross-sectional configuration diagram, corresponding to FIG. 77, of a plurality of pixels in a photodetector and a distance measurement system according to a second modification example of the 3-5th embodiment.

FIG. 80 is a schematic longitudinal cross-sectional configuration diagram, corresponding to FIG. 77, of a plurality of pixels in a photodetector and a distance measurement system according to a third modification example of the 3-5th embodiment.

FIG. 81 is a circuit configuration diagram of a plurality of pixels in a photodetector and a distance measurement system according to a 3-6th embodiment of the present disclosure.

FIG. 82 is a schematic longitudinal cross-sectional configuration diagram, corresponding to FIG. 60, of the plurality of pixels in the photodetector illustrated in FIG. 81.

FIG. 83 is a circuit configuration diagram of a plurality of pixels in a photodetector and a distance measurement system according to a 3-7th embodiment of the present disclosure.

FIG. 84 is a schematic longitudinal cross-sectional configuration diagram, corresponding to FIG. 60, of the plurality of pixels in the photodetector illustrated in FIG. 83.

FIG. 85 is a circuit configuration diagram of a plurality of pixels in a photodetector and a distance measurement system according to a 3-8th embodiment of the present disclosure.

FIG. 86 is a schematic longitudinal cross-sectional configuration diagram, corresponding to FIG. 60, of the plurality of pixels in the photodetector illustrated in FIG. 85.

FIG. 87 is a circuit configuration diagram of a plurality of pixels in a photodetector and a distance measurement system according to a 3-9th embodiment of the present disclosure.

FIG. 88 is a schematic longitudinal cross-sectional configuration diagram, corresponding to FIG. 60, of the plurality of pixels in the photodetector illustrated in FIG. 87.

FIG. 89 is a planar configuration diagram of a plurality of pixels in a photodetector according to a 3-10th embodiment of the present disclosure.

FIG. 90 is a planar configuration diagram, corresponding to FIG. 89, of a plurality of pixels in a photodetector according to a first modification example of the 3-10th embodiment.

FIG. 91 is a planar configuration diagram, corresponding to FIG. 89, of a plurality of pixels in a photodetector according to a second modification example of the 3-10th embodiment.

FIG. 92 is a planar configuration diagram, corresponding to FIG. 89, of a plurality of pixels in a photodetector according to a third modification example of the 3-10th embodiment.

FIG. 93 is a planar configuration diagram, corresponding to FIG. 89, of a plurality of pixels in a photodetector according to a fourth modification example of the 3-10th embodiment.

FIG. 94 is a block diagram depicting an example of schematic configuration of a vehicle control system.

FIG. 95 is a diagram of assistance in explaining an example of installation positions of an outside-vehicle information detecting section and an imaging section.

### MODES FOR CARRYING OUT THE INVENTION

Some embodiments of the present disclosure are described below in detail with reference to the drawings. It is to be noted that description is given in the following order.
1. 1-1st Embodiment

A 1-1st embodiment describes a first example in which the present technology is applied to a photodetector and a distance measurement system. The 1-1st embodiment describes, in detail, circuit configurations and device configurations of the photodetector including a protective circuit, and the distance measurement system including the photodetector.
2. 1-2nd embodiment

A 1-2nd embodiment describes a second example in which an arrangement mode of the protective circuit is changed in the photodetector and the distance measurement system according to the 1-1st embodiment.
3. 1-3rd Embodiment

A 1-3rd embodiment describes a third example in which the arrangement mode of the protective circuit is changed in the photodetector and the distance measurement system according to the 1-1st embodiment.
4. 1-4th embodiment

A 1-4th embodiment describes a fourth example in which a configuration of the protective circuit is changed in the photodetector and the distance measurement system according to the 1-1st embodiment.
5. 1-5th embodiment

A 1-5th embodiment describes a fifth example in which the configuration of the protective circuit is changed in the photodetector and the distance measurement system according to the 1-4th embodiment.
6. 1-6th Embodiment

A 1-6th embodiment describes a sixth example in which the arrangement mode of the protective circuit is changed in the photodetector and the distance measurement system according to the 1-5th embodiment.
7. 1-7th Embodiment

A 1-7th embodiment describes a seventh example in which the arrangement mode of the protective circuit is changed in the photodetector and the distance measurement system according to the 1-5th embodiment.
8. 1-8th Embodiment

A 1-8th embodiment describes an eighth example in which a planar shape of a pixel is changed in the photodetector and the distance measurement system according to the 1-1st embodiment. The 1-8th embodiment also describes modification examples.
9. 1-9th Embodiment

A 1-9th embodiment describes a ninth example in which an arrangement mode of a plurality of pixels is changed in the photodetector and the distance measurement system according to the 1-1st embodiment.
10. 1-10th embodiment

A 1-10th embodiment describes a tenth example in which the arrangement mode of the protective circuit is changed in the photodetector and the distance measurement system according to the 1-9th embodiment.
11. 1-11th embodiment

A 1-11th embodiment describes an eleventh example in which the arrangement mode of the protective circuit is changed in the photodetector and the distance measurement system according to the 1-9th embodiment.
12. 1-12th Embodiment

A 1-12th embodiment describes a twelfth example in which the configuration of the protective circuit is changed in the photodetector and the distance measurement system according to the 1-9th embodiment.
13. 1-13th embodiment

A 1-13th embodiment describes a thirteenth example in which the arrangement mode of the protective circuit is changed in the photodetector and the distance measurement system according to the 1-12th embodiment.
14. 1-14th embodiment

A 1-14th embodiment describes a fourteenth example in which the arrangement mode of the protective circuit is changed in the photodetector and the distance measurement system according to the 1-12th embodiment.
15. 1-15th Embodiment

A 1-15th embodiment describes a fifteenth example in which the planar shape of the pixel is changed in the photodetector and the distance measurement system according to the 1-1st embodiment.
16. 1-16th Embodiment

A 1-16th embodiment describes a sixteenth example in which the planar shape of the pixel is changed in the photodetector and the distance measurement system according to the 1-1st embodiment.
17. 2-1st embodiment

A 2-1st embodiment describes a seventeenth example in which the present technology is applied to a photodetector and a distance measurement system. The 2-1st embodiment describes, in detail, circuit configurations and device configurations of a photodetector including pixels with different photoelectric characteristics arranged, and a distance measurement system including the photodetector.
18. 2-2nd Embodiment

A 2-2nd embodiment describes an eighteenth example in which a configuration of the pixel is changed in the photodetector and the distance measurement system according to the 2-1st embodiment.
19. 2-3rd Embodiment

A 2-3rd embodiment describes a nineteenth example in which the configuration of the pixel is changed in the photodetector and the distance measurement system according to the 2-1st embodiment.
20. 2-4th Embodiment

A 2-4th embodiment describes a twentieth example in which a planar shape of the pixel is changed in the photodetector and the distance measurement system according to the 2-1st embodiment.
21. 2-5th embodiment

A 2-5th embodiment describes a twenty-first example in which the planar shape and an arrangement mode of the pixel are changed in the photodetector and the distance measurement system according to the 2-4th embodiment.
22. 2-6th Embodiment

A 2-6th embodiment describes a twenty-second example in which the arrangement mode of the pixel is changed in the photodetector and the distance measurement system according to the 2-5th embodiment.
23. 2-7th Embodiment

A 2-7th embodiment describes a twenty-third example in which the arrangement mode of the pixel is changed in the photodetector and the distance measurement system according to the 2-1st embodiment.
24. 3-1st embodiment

A 3-1st embodiment describes a twenty-fourth example in which the present technology is applied to a photodetector and a distance measurement system. The 3-1st embodiment describes, in detail, circuit configurations and device configurations, and a manufacturing method of a photodetector including pixels with different photoelectric characteristics arranged, and a distance measurement system including the photodetector.
25. 3-2nd embodiment

A 3-2nd embodiment describes a twenty-fifth example in which a configuration of a readout circuit coupled to the pixel is changed in the photodetector and the distance measurement system according to the 3-1st embodiment.
26. 3-3rd Embodiment

A 3-3rd embodiment describes a twenty-sixth example in which the configuration of the readout circuit is changed in the photodetector and the distance measurement system according to the 3-1st embodiment.
27. 3-4th embodiment

A 3-4th embodiment describes a twenty-seventh example in which the configuration of the readout circuit is changed in the photodetector and the distance measurement system according to the 3-1st embodiment.
28. 3-5th embodiment

A 3-5th embodiment describes a twenty-eighth example in which a configuration of a filter mounted on the pixel is changed in the photodetector and the distance measurement system according to the 3-1st embodiment. The 3-5th embodiment also describes modification examples.
29. 3-6th embodiment

A 3-6th embodiment describes a twenty-ninth example in which the configuration of the readout circuit is changed in the photodetector and the distance measurement system according to the 3-1st embodiment.
30. 3-7th Embodiment

A 3-7th embodiment describes a thirtieth example in which the configuration of the readout circuit is changed in the photodetector and the distance measurement system according to the 3-1st embodiment.
31. 3-8th Embodiment

A 3-8th embodiment describes a thirty-first example in which the configuration of the readout circuit is changed in the photodetector and the distance measurement system according to the 3-1st embodiment.
32. 3-9th Embodiment

A 3-9th embodiment describes a thirty-second example in which the configuration of the readout circuit is changed in the photodetector and the distance measurement system according to the 3-1st embodiment.
33. 3-10th embodiment

A 3-10th embodiment describes a thirty-third example in which a planar shape and an arrangement mode of the pixel are changed in the photodetector and the distance measurement system according to the 3-1st embodiment. The 3-10th embodiment also describes modification examples.
34. Example of Application to Mobile Body

The application example describes an example in which the present technology is applied to a vehicle control system that is an example of a mobile body control system.
35. Other Embodiments

### 1. 1-1st Embodiment

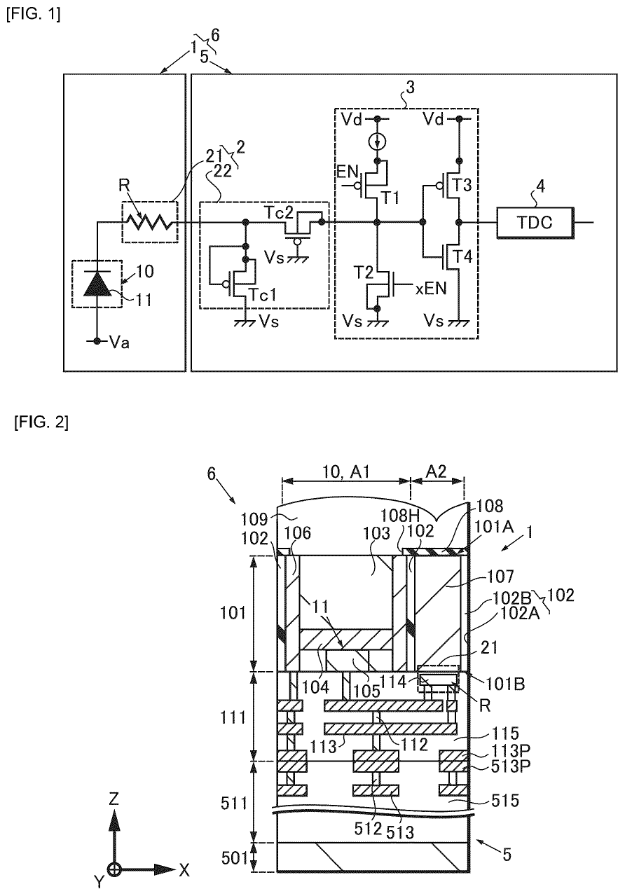

Description is given of a photodetector 1 and a distance measurement system 6 according to the 1-1st embodiment of the present disclosure with reference to FIGS. 1 to 4.

Here, an arrow-X direction indicated as appropriate in the drawings indicates one planar direction of the photodetector 1 and the distance measurement system 6 placed on a plane for convenience. An arrow-Y direction indicates another planar direction orthogonal to the arrow-X direction. In addition, an arrow-Z direction indicates an upward direction orthogonal to the arrow-X direction and the arrow-Y direction. That is, the arrow-X direction, the arrow-Y direction, and the arrow-Z direction exactly coincide with an X-axis direction, a Y-axis direction, and a Z-axis direction, respectively, of a three-dimensional coordinate system.

It is to be noted that these directions are each indicated to aid understanding of descriptions, and are not intended to limit directions used in the present technology.

### [1. Circuit Configurations of Photodetector 1 and Distance Measurement System 6]

### (1) Overall Schematic Configurations of Photodetector 1 and Distance Measurement System 6

FIG. 1 illustrates an example of circuit configurations of the photodetector 1 and the distance measurement system 6 according to the 1-1st embodiment.

First, the distance measurement system 6 to which the present technology is applied measures a distance to a subject as a measurement object. To describe this in detail, the distance measurement system 6 uses a ToF method for distance measurement. The ToF method is a method in which the subject is irradiated with light and the light reflected by the subject is received to thus measure time of flight of the light from irradiation with the light to reception of the light. As the light, for example, laser light is used that is superior in directivity and has a peak wavelength in an infrared wavelength band.

As illustrated in FIG. 1, the distance measurement system 6 includes at least the photodetector 1. In the 1-1st embodiment, the distance measurement system 6 includes at least the photodetector 1 and a circuit device 5.

The distance measurement system 6 may further include, as a device that implements the ToF method, for example, a laser oscillator including an unillustrated laser light source.

### (2) Circuit Configuration of Photodetector 1

As illustrated in FIG. 1, the photodetector 1 is constructed as a sensor element or a sensor chip. The photodetector 1 here includes a pixel 10 including a SPAD 11 as a light-receiving element. FIG. 1 illustrates one pixel 10. In actuality, the photodetector 1 includes a plurality of pixels 10 arranged (see FIG. 4).

The SPAD 11 is a single-photon avalanche diode that amplifies a carrier generated by an incident photon. The SPAD 11 operates in a nonlinear region (a Geiger mode). That is, the SPAD 11 operates with a reverse voltage exceeding a breakdown voltage (a breakdown voltage).

An anode electrode of the SPAD 11 is coupled to an anode power supply Va. The anode power supply Va supplies a large negative voltage that causes an avalanche multiplication, i.e., a voltage greater than or equal to the breakdown voltage. Specifically, the anode power supply Va supplies, for example, a voltage of −20 V.

A cathode electrode of the SPAD 11 is coupled to a readout circuit 3 with a protective circuit 2 interposed therebetween. A cathode voltage clamped by the protective circuit 2 (a second protective circuit 22 of the protective circuit 2) is applied to the cathode electrode. The cathode voltage is, for example, a voltage of about 3 V to be supplied from an operating power supply Vd.

It is to be noted that the pixel 10 may be constructed using, in place of the SPAD 11, an avalanche photodiode (APD: Avalanche Photo Diode), silicon photomultiplier (SiPM: Silicon Photomultiplier), or the like that operates in the nonlinear region.

### (3) Circuit Configuration of First Protective Circuit 21 of Protective Circuit 2

The protective circuit 2 includes a first protective circuit 21 and the second protective circuit 22. In addition to the pixel 10, the first protective circuit 21 is also provided in the photodetector 1. When the SPAD 11 is irradiated with a larger amount of photons than expected, an internal impedance of the SPAD 11 greatly decreases, and an overcurrent flows through the readout circuit 3. The first protective circuit 21 is configured to reduce such an overcurrent to thereby protect the readout circuit 3.

In the 1-1st embodiment, the first protective circuit 21 includes a resistor element R. The resistor element R is electrically coupled in series between the SPAD 11 and the readout circuit 3. To describe this in detail, one end of the resistor element R is coupled to the cathode electrode of the SPAD 11. Another end of the resistor element R is coupled to the readout circuit 3. The first protective circuit 21 is provided closer to the SPAD 11 than the second protective circuit 22.

### (4) Circuit Configuration of Circuit Device 5

The circuit device 5 is constructed as a circuit element or a circuit chip. The circuit device 5 includes at least the second protective circuit 22 of the protective circuit 2, the readout circuit 3, and a time measurement circuit 4.

### (5) Circuit Configuration of Second Protective Circuit 22

The second protective circuit 22 is provided between the first protective circuit 21 and the readout circuit 3. The second protective circuit 22 includes a first clamp element Tc1 and a second clamp element Tc2. That is, the second protective circuit 22 is configured to clamp an overcurrent that is to flow from the first protective circuit 22 to the readout circuit 3 to thereby protect the readout circuit 3.

The first clamp element Tc1 includes an insulated gate field effect transistor (IGFET: Insulated Gate Field Effect Transistor) of p-type as a first electrically-conductive type. Hereinafter, the insulated gate field effect transistor is simply referred to as “IGFET”. Here, the IGFET is used in a sense including a MOSFET (Metal Oxide Semiconductor Field Effect Transistor) and a MISFET (Metal Insulator Semiconductor Field Effect Transistor). The IGFET includes a pair of main electrodes as a source electrode and a drain electrode, and a gate electrode.

One of the pair of main electrodes of the first clamp element Tc1 and the gate electrode of the first clamp element Tc1 are electrically coupled to the other end of the resistor element R of the first protective circuit 21. Another one of the pair of main electrodes of the first clamp element Tc1 is electrically coupled to a reference power supply Vs. That is, the first clamp element Tc1 is electrically coupled in parallel between the first protective circuit 21 and the readout circuit 3.

The reference power supply Vs supplies, for example, a voltage of 0 V.

The second clamp element Tc2 includes a p-type IGFET, as with the first clamp element Tc1. One of a pair of main electrodes of the second clamp element Tc2 is electrically coupled to the other main electrode of the first clamp element Tc1. Another one of the pair of main electrodes of the second clamp element Tc2 is electrically coupled to the readout circuit 3. A gate electrode of the second clamp element Tc2 is electrically coupled to the reference power supply Vs.

### (6) Circuit Configuration of Readout Circuit 3

The readout circuit 3 includes a first control element T1, a second control element T2, a first output element T3, and a second output element T4.

The first control element T1 is used as a quench (Quench) element, and includes a p-type IGFET. One of a pair of main electrodes of the first control element T1 is electrically coupled to the operating power supply Vd via an ammeter with no reference numeral. Another one of the pair of main electrodes of the first control element T1 is electrically coupled to the second protective circuit 22, the second control element T2, the first output element T3, and the second output element T4. An enable signal EN is inputted to a gate electrode of the first control element T1.

When the enable signal EN with a low level is inputted to the first control element T1, the first control element T1 is brought into an electrically conductive state, and supplies an operating voltage from the operating power supply Vd to the SPAD 11. That is, an avalanche current is extracted by the first control element T1, and the readout circuit 3 is brought into a reset state.

The second control element T2 includes an IGFET of n-type as a second electrically-conductive type opposite to the first electrically-conductive type. One of a pair of main electrodes of the second control element T2 is electrically coupled to the reference power supply Vs. Another one of the pair of main electrodes of the second control element T2 is electrically coupled to the second protective circuit 22, the first control element T1, the first output element T3, and the second output element T4. A signal xEN having a phase opposite to that of the enable signal EN is inputted into a gate electrode of the second control element T2.

When the signal xEN with a high level is inputted into the second control element T2, the second control element T2 is brought into the electrically conductive state. That is, a reference voltage is supplied from the reference power supply Vs to the cathode electrode of the SPAD 11, and the readout circuit 3 is brought into an active state.

The first output element T3 and the second output element T4 construct a complementary output circuit.

The first output element T3 includes a p-type IGFET. One of a pair of main electrodes of the first output element T3 is electrically coupled to the operating power supply Vd. Another one of the pair of main electrodes of the first output element T3 is electrically coupled to the time measurement circuit 4. A gate electrode of the first output element T3 is electrically coupled to the other main electrode of each of the first control element T1 and the second control element T2. When a signal with the low level is inputted to the gate electrode in response to output of the SPAD 11, the first output element T3 is brought into the electrically conductive state. This allows the readout circuit 3 to output a readout signal with the high level to the time measurement circuit 4. When the signal with the high level is inputted to the gate electrode, the first output element T3 is brought into a non-electrically-conductive state.

The second output element T4 includes an n-type IGFET. One of a pair of main electrodes of the second output element T4 is electrically coupled to the reference power supply Vs. Another one of the pair of main electrodes of the second output element T4 is electrically coupled to the time measurement circuit 4. A gate electrode of the second output element T4 is electrically coupled to the other main electrode of each of the first control element T1 and the second control element T2, as with the gate electrode of the first output element T3.

When a signal with the high level is inputted to the gate electrode in response to output of the SPAD 11, the second output element T4 is brought into the electrically conductive state. This allows the readout circuit 3 to output the readout signal with the low level to the time measurement circuit 4. When the signal with the low level is inputted to the gate electrode, the second output element T4 is brought into the non-electrically-conductive state.

### (7) Circuit Configuration of Time Measurement Circuit 4

The time measurement circuit 4 is electrically coupled to an output of the readout circuit 3. An output of the readout circuit 3 is outputted as an output of the SPAD 11 (an output of the pixel 10) to the time measurement circuit 4. The time measurement circuit 4 measures, on the basis of the output of the SPAD 11, time of flight of light it takes for the light to be applied to the subject (the distance measurement object), reflected by the subject, and return.

The time measurement circuit 4 is constructed by a hardware configuration in the 1-1st embodiment.

It is to be noted that the time measurement circuit 4 may include an input circuit, an output circuit, a central processing unit (CPU: Central Processing Unit), a memory unit, and the like, and may be configured by a software configuration.

### [2. Device Configurations of Photodetector 1 and Distance Measurement System 6]

### (1) Device Configuration of Photodetector 1

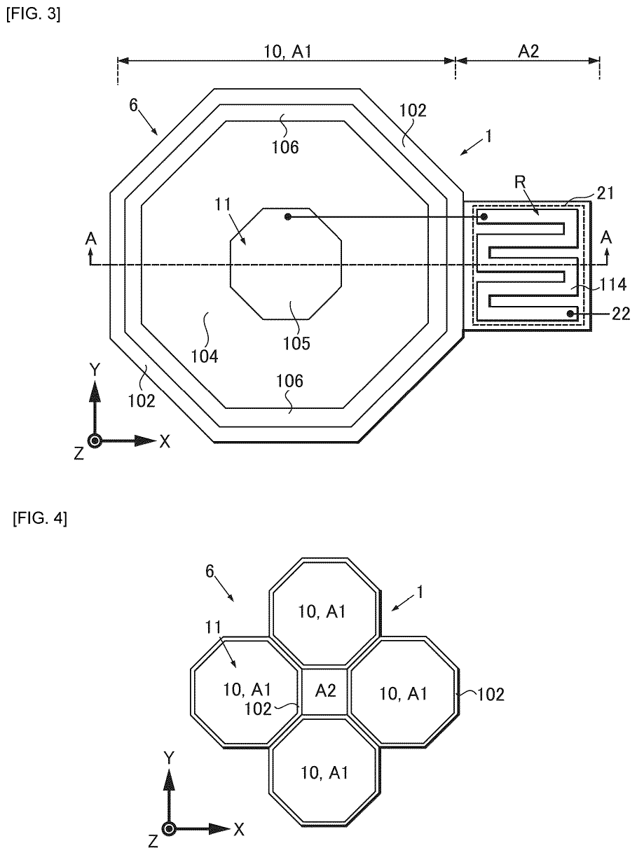

FIG. 2 illustrates an example of a longitudinal cross-sectional configuration of one pixel 10 of the photodetector 1 illustrated in FIG. 1. FIG. 2 also illustrates an example of a longitudinal cross-sectional configuration of a portion of the circuit device 5 of the distance measurement system 6. FIG. 3 illustrates an example of a planar configuration of the one pixel 10 of the photodetector 1 illustrated in FIG. 2. Moreover, FIG. 4 illustrates an example of a planar configuration of a portion of a pixel region in which a plurality of pixels 10 illustrated in FIG. 3 is arranged.

As illustrated in FIGS. 2 and 3, the photodetector 1 is constructed using a first base 101 as a base. In the 1-1st embodiment, the first base 101 is formed by, for example, a monocrystalline silicon (Si) substrate doped with an n-type impurity with a low impurity density.

As illustrated in FIGS. 2 to 4, the pixel 10 including the SPAD 11 is provided in a first region A1 of the first base 101. Moreover, the first protective circuit 21 including the resistor element R is provided in a second region A2 adjacent to the first region A1 of the first base 101. In other words, the SPAD 11 is provided in the first region A1 of the first base 101, and the resistor element R that is an element different from the SPAD 11 is provided in the second region A2.

Here, a plane direction of the first base 101 is used to mean a planar direction extending in the arrow-X direction and the arrow-Y direction.

An insulating isolator 102 is provided between the first region A1 and the second region A2, as viewed in the arrow-Y direction (hereinafter, referred to as “in a side view”) or as viewed in the arrow-Z direction (hereinafter, simply referred to as “in a plan view”). The insulating isolator 102 is configured to physically divide the first region A1 and the second region A2 from each other, and to at least electrically isolate the SPAD 11 and the resistor element R from each other.

### (2) Configuration of Insulating Isolator 102

The insulating isolator 102 is configured to surround the pixel 10. Here, the insulating isolator 102 includes an isolation trench 102A and an embedded member 102B. Detailed description is given.

As illustrated in FIG. 2, the isolation trench 102A is formed to penetrate the first base 101 from a first surface 101A on a side of the arrow-Z direction to a second surface 101B opposed to the first surface 101A on a opposite side in a side view. In other words, the isolation trench 102A is provided to penetrate the first base 101 in a thickness direction. The isolation trench 102A here is formed to have a uniform width dimension in the arrow-X direction or in the arrow-Y direction.

The embedded member 102B is embedded inside the isolation trench 102A. The embedded member 102B includes an insulator such as silicon oxide (SiO₂) in the 1-1st embodiment.

In addition, the embedded member 102B may be formed to include an insulator formed along an inner wall of the isolation trench 102A and an electrical conductor embedded inside the isolation trench 102A with the insulator interposed therebetween. For example, it is possible to use SiO2 described above as the insulator. For example, it is possible to use polycrystalline Si, or a metallic body such as tungsten (W) or aluminum (Al) as the electrical conductor.

The electrical conductor may be electrically coupled to a fixed power supply, or may be electrically floating. In a case where the fixed power supply is coupled to the electrical conductor, for example, it is possible to use the anode power supply Va as the fixed power supply.

As illustrated in FIGS. 3 and 4, a planar shape of the insulating isolator 102 is formed in a triangular or more polygonal shape in a plan view. Here, the planar shape of the insulating isolator 102 is formed in an octagonal shape or a regular octagonal shape.

The insulating isolator 102 is provided to surround a side surface of the pixel 10. Accordingly, a planar shape of the first region A1 that constructs one pixel is formed in a polygonal shape that is similar to the planar shape of the insulating isolator 102 and is smaller in size than the planar shape of the insulating isolator 102.

### (3) Configuration of Pixel 10

As illustrated in FIGS. 2 to 4, the pixel 10 is provided in an n-type semiconductor region (an n-well region) 103 formed in the first base 101 within a region surrounded by the insulating isolator 102. The n-type semiconductor region 103 has a low impurity density, and is electrically coupled to the anode power supply Va.

As described above, the pixel 10 includes the SPAD 11. The SPAD 11 is provided on an inner side of the insulating isolator 102 with a p-type semiconductor region 106 interposed therebetween. The p-type semiconductor region 106 is formed along an inner wall of the insulating isolator 102. The p-type semiconductor region 106 is used as a pinning region that suppresses generation of a dark current.

The SPAD 11 includes an anode region 104 and a cathode region 105.

The anode region 104 is provided on a side of the second surface 101B of the first base 101. The anode region 104 is formed by a p-type semiconductor region having a higher impurity density than an impurity density of the p-type semiconductor region 106. The anode region 104 is formed to have a concentration profile in a thickness direction of the first base 101 in a middle portion of the first base 101 in a side view.

In addition, the anode region 104 is formed on the inner wall of the insulating isolator 102 with the p-type semiconductor region 106 interposed therebetween in a plan view. Accordingly, a planar shape of the anode region 104 is formed in a polygonal shape (here, an octagonal shape or a regular octagonal shape) similar to the planar chape of the insulating isolator 102, and is formed in a shape similar to but smaller in size than the planar shape of the insulating isolator 102.

The cathode region 105 is provided between the second surface 101B of the first base 101 and the anode region 104. The cathode region 105 is formed by an n-type semiconductor region having a higher impurity density than the impurity density of the first base 101. The cathode region 105 is p-n joined to the anode region 104. As with the anode region 104, the cathode region 105 is formed to have a concentration profile in the thickness direction of the first base 101 in a side view.

In addition, the cathode region 105 is formed on the inner wall of the insulating isolator 102 with the n-type semiconductor region of the first base 101 interposed therebetween in a plan view. Accordingly, a planar shape of the cathode region 105 is formed in a polygonal shape (here, an octagonal shape or a regular octagonal shape) similar to the planar chape of the anode region 104, and is formed in a shape similar to but smaller in size than the planar shape of the anode region 104.

FIG. 4 illustrates a portion of the pixel region, and the pixels 10 are arranged in the arrow-X direction with the second region A2 interposed therebetween. Moreover, the pixels 10 are arranged in the arrow-Y direction with the second region A2 interposed therebetween. That is, a plurality of pixels 10 is arranged in a matrix to thus construct the pixel region (a light reception region).

It is to be noted that, in the 1-1st embodiment, the planar shape of the first region A1 is formed in an octagonal shape or a regular octagonal shape. In other words, a plurality of first regions A1 is arranged adjacent to each other without the second region A2 interposed therebetween in an oblique direction at an angle of 45° or 135° toward the arrow-Y direction with respect to the arrow-X direction.

It is to be noted that the number of pixels 10 arranged is not particularly limited.

### (4) Configurations of Light-blocking Film 108 and Optical Lens 109

A light-blocking film 108 is provided on the first surface 101A of the first base 101. The light-blocking film 108 is configured to block light incident on the photodetector 1. The light-blocking film 108 includes, for example, a metal material such as W.

The light-blocking film 108 has an opening 108H in a region corresponding to the pixel 10, that is, the first region A1. The opening 108H is configured to let light incident from the arrow-Z direction in the SPAD 11.

An optical lens 109 is provided on the first surface 101A of the first base 101 with the light-blocking film 108 interposed therebetween. A surface on the side of the arrow-Z direction of the optical lens 109 is formed in a shape that curves toward a side opposite to the arrow-Z direction for each pixel 10 in a side view. That is, the optical lens 109 condenses incident light. The light condensed by the optical lens 109 is received by the SPAD 11 through the opening 108H.

The optical lens 109 includes, for example, a transparent resin material. Here, the optical lens 109 is formed as an on-chip lens (On Chip Lens).

### (5) Configuration of Wiring Layer 111

As illustrated in FIG. 2, the wiring layer 111 is provided on the second surface 101B of the first base 101. The wiring layer 111 includes a coupling hole wiring 112, a wiring 113, and an insulator 115. The wiring layer 111 is configured to allow for electrical coupling, for example, between the photodetector 1 and the circuit device 5, between the SPAD 11 of the photodetector 1 and the first protective circuit 21, and between the first protective circuit 21 and the second protective circuit 22 of the circuit device 5.

Here, a plurality of the wirings 113 is formed. The wirings 113 each include, for example, a wiring material having superior electrical conductivity such as copper (Cu) or aluminum (Al)—Cu. An uppermost wiring 113 on a side opposite to the arrow Z-direction in the wiring layer 111 is used as a terminal 113P. The terminal 113P is formed as an external terminal that is electrically and mechanically coupled to the circuit device 5.

The coupling hole wiring 112 is configured to allow for electrical coupling, for example, between the SPAD 11 and the wiring 113 and between the wirings 113. The coupling hole wiring 112 includes, for example, a wiring material such as W.

In actuality, the insulator 115 is formed by a plurality of insulating films. The insulator 115 is configured, for example, to electrically isolate the wirings 113 from each other and protect the wirings 113. The insulator 115 includes, for example, an insulating material such as SiO₂.

### (6) Configuration of First Protective Circuit 21

As illustrated in FIGS. 2 to 4, the first protective circuit 21 of the protective circuit 2 includes the resistor element R as described above. The resistor element R is provided in the second region A2 adjacent to the first region A1 in the plane direction (in the arrow-X direction or the arrow-Y direction) of the first surface 101A of the first base 101. The second region A2 is provided on the first region A1 (the pixel 10) with the insulating isolator 102 interposed therebetween. Here, the second region A2 of the first base 101 is formed by a p-type semiconductor region 107.

As illustrated in FIG. 4, the second region A2 is surrounded by a total of four first regions A1 including two first regions A1 provided adjacent in the arrow-X direction and two first regions A1 provided adjacent in the arrow-Y direction. The second region A2 has four sides each having the same length as a length of one side of a corresponding one of the four first regions A1 in a plan view. That is, a planar shape of the second region A2 is formed in a rectangular shape, in this case, in a quadrilateral shape or a square shape.

In other words, the planar shape of the first region A1 is formed in a polygonal shape as described above; therefore, the second region A2 is surrounded by three or more first regions A1.

The resistor element R is provided on the second surface 101B of the first base 101 in the second region A2. To describe this in detail, the resistor element R is provided closest to the side of the second surface 101B in the wiring layer 111. The resistor element R includes, for example, a polycrystalline Si doped with an impurity. The impurity reduces a resistance value.

As illustrated in FIG. 2, a planar shape of the resistor element R is formed in a Meander pattern (Meander pattern) that alternately extends in the arrow-X direction and a direction opposite to the arrow-X direction toward the arrow-Y direction. The resistor element R formed in such a planar shape is adjusted to have a resistance value of several kQ, for example.

### (7) Configuration of Circuit Device 5

As illustrated in FIG. 2, the circuit device 5 is constructed on a second base 501 as a base. The second base 501 is provided on the side of the second surface 101B of the first base 101. In other words, the photodetector 1 is stacked on the circuit device 5 on the side of the arrow-Z direction in a side view. In the 1-1st embodiment, the second base 501 is formed by, for example, a monocrystalline Si substrate, as with the first base 101.

An element (see FIG. 1) that constructs each of the second protective circuit 22 of the protective circuit 2, the readout circuit 3, and the time measurement circuit 4 is provided in the second base 501, although a detailed configuration and description thereof are omitted.

### (8) Configuration of Wiring Layer 511

A wiring layer 511 is provided on the second base 501 on the side of the second surface 101B of the first base 101. The wiring layer 511 includes a coupling hole wiring 512, wirings 513, and an insulator 515, as with the wiring layer 111 on the side of the first base 101.

An uppermost wiring 513 on the side of the arrow Z direction of the wiring layer 511 is used as a terminal 513P. The terminal 513P is electrically and mechanically coupled to the terminal 113P of the photodetector 1. For example, Cu-Cu bonding is used for this coupling.

### [Workings and Effects]

As described above, the photodetector 1 according to the 1-1st embodiment includes the SPAD 11, one or more elements different from the SPAD 11, and the insulating isolator 102, as illustrated in FIGS. 1 to 4.

The SPAD 11 is provided in the first region A1 of the first base 101, and amplifies a carrier generated by an incident photon. The one or more elements are provided in the second region A2 adjacent to the first region A1 of the first base 101 in the plane direction of the first base 101. Here, the one or more elements includes the resistor element R that constructs the first protective circuit 21 of the protective circuit 2.

Moreover, the insulating isolator 102 is provided between the first region A1 and the second region A2, and at least electrically isolates the SPAD 11 and the one or more elements from each other.

In the photodetector 1 having such a configuration, the insulating isolator 102 is provided between the SPAD 11 and the one or more elements; which makes it possible for the one or more elements to effectively reduce or prevent an influence of an electrical field effect from the SPAD 11. In addition, it is possible to insulate and isolate the SPAD 11 and the one or more elements from each other with use of the insulating isolator 102 that surrounds the pixel 10 provided with the SPAD 11.

In addition, no element is provided in the same first region A1 in which the SPAD 11 is provided; therefore, a thick insulator for insulating and isolating them from each other is not necessary. Accordingly, it is possible to reduce a thickness in the arrow-Z direction of the photodetector 1.

In addition, in the photodetector 1, as illustrated in FIG. 1, the one or more elements construct the protective circuit 2. To describe this in detail, the one or more elements include the resistor element R of the first protective circuit 21 of the protective circuit 2. The protective circuit 2 reduces an overcurrent from the SPAD 11.

It is thus possible to reduce the overcurrent by the protective circuit 2, which makes it possible to construct the photodetector 1 having superior overcurrent resistance of the readout circuit 3.

In addition, in the photodetector 1, as illustrated in FIGS. 2 and 3, the resistor element R of the first protective circuit 21 includes Si (a polycrystalline Si film). Si has a track record in semiconductor-manufacturing technology, and allows for easy fabrication. This makes it possible to easily fabricate the first protective circuit 21, and to construct the photodetector 1 having superior overcurrent resistance.

In addition, in the photodetector 1, as illustrated in FIG. 1, the SPAD 11 is electrically coupled to the readout circuit 3 via the protective circuit 2. The readout circuit 3 reads the carrier amplified by the SPAD 11. Here, the second protective circuit 22 of the protective circuit 2, and the readout circuit 3 are provided in the circuit device 5. Moreover, as illustrated in FIG. 2, the distance measurement system 6 includes the second base 501 stacked on the first base 101 in the thickness direction of the first base 101, and the readout circuit 3 is provided in the second base 501.

It is thus possible for the protective circuit 2 to reduce the overcurrent from the SPAD 11, which makes it possible to construct the photodetector 1 having superior overcurrent resistance of the readout circuit 3.

In addition, in the photodetector 1, as illustrated in FIGS. 3 and 4, the planar shape of the first region A1 is formed in a triangular or more polygonal shape as viewed in a photon incident direction (in a plan view). Moreover, the second region A2 is surrounded by three or more first regions A1 in the plane direction of the first base 101. In the 1-1st embodiment, the planar shape of the first region A1 in which the pixel 10 is provided is formed in an octagonal shape or a regular octagonal shape, and the second region A2 in which the resistor element R is provided is surrounded by four first regions A1.

It is thus possible to efficiently dispose the resistor element R in an empty region between the pixels 10 while the plurality of pixels 10 is arranged adjacently and densely. This makes it possible to improve packing efficiency of the pixels 10 in the photodetector 1. In other words, in the photodetector 1, it is possible to improve light condensing efficiency.

It is to be noted that, in the present technology, the planar shape of the pixel 10, i.e., the first region A1, may be formed in each of a triangular shape, a polygonal shape with four (refer to the 1-8th embodiment) or more to seven or less sides, a polygonal shape with more than eight sides. Moreover, the planar shape of the first region A1 may be formed in a circular shape, an elliptical shape, or a slit shape.

In addition, in the photodetector 1, as illustrated in FIG. 2, the insulating isolator 102 includes the isolation trench 102A that is provided in the thickness direction of the first base 101, and the embedded member 102B that is embedded inside the isolation trench 102A.

Thus, the SPAD 11 and the resistor element R are electrically and physically isolated from each other. This makes it possible for the resistor element R to more effectively reduce or prevent the influence of the electrical field effect from the SPAD 11.

In addition, the embedded member 102B of the insulating isolator 102 may include the insulator that is provided along the inner wall of the isolation trench 102A, and the metallic body that is embedded inside the isolation trench 102A with the insulator interposed therebetween. At this time, the metallic body is preferably electrically coupled to the fixed power supply. An electrical shielding effect is generated in the metallic body having such a configuration, which makes it possible for the resistor element R to more effectively reduce or prevent the influence of the electrical field effect from the SPAD 11.

As illustrated in FIGS. 1 to 4, the distance measurement system 6 according to the 1-1st embodiment includes the photodetector 1 and the circuit device 5.

The photodetector 1 includes the SPAD 11, the first protective circuit 21 of the protective circuit 2, and the insulating isolator 102. The SPAD 11 is provided in the first region A1 of the first base 101, and amplifies a carrier generated by an incident photon. The first protective circuit 21 is provided in the second region A2 adjacent to the first region A1 of the first base 101 in the plane direction of the first base 101, and includes one or more elements that reduce the overcurrent from the SPAD 11. The insulating isolator 102 is provided between the first region A1 and the second region A2, and at least electrically isolates the SPAD 11 and the one or more elements from each other.

The circuit device 5 includes the readout circuit 3 and the time measurement circuit 4. The readout circuit 3 is electrically coupled to the SPAD 11 via the first protective circuit 21 (and the second protective circuit 22), and reads out the amplified carrier. The time measurement circuit 4 is electrically coupled to the readout circuit 3, and measures time of flight of light.

In the distance measurement system 6 having such a configuration, the insulating isolator 102 is provided between the SPAD 11 and the one or more elements in the photodetector 1, which makes it possible to effectively reduce or prevent the influence of the electrical field effect from the SPAD 11. In addition, it is possible to reduce the overcurrent by the first protective circuit 21 (and the second protective circuit 22) of the protective circuit 2. This makes it possible to construct the distance measurement system 6 having superior overcurrent resistance of the readout circuit 3.

In addition, as illustrated in FIG. 2, the distance measurement system 6 includes the second base 501 that is stacked on the first base 101 in the thickness direction of the first base 101, and the readout circuit 3 is provided in the second base 501.

Accordingly, the photodetector 1 and the circuit device 5 are fabricated separately, and are stacked on each other, thereby making it possible to easily construct the distance measurement system 6.

Moreover, as illustrated in FIG. 2, the distance measurement system 6 includes the second base 501 that is stacked on the first base 101 in the thickness direction of the first base 101, and the time measurement circuit 4 is provided in the second base 501.

Accordingly, the photodetector 1 and the circuit device 5 are fabricated separately, and are stacked on each other, thereby making it possible to easily construct the distance measurement system 6.

### 2. 1-2nd Embodiment

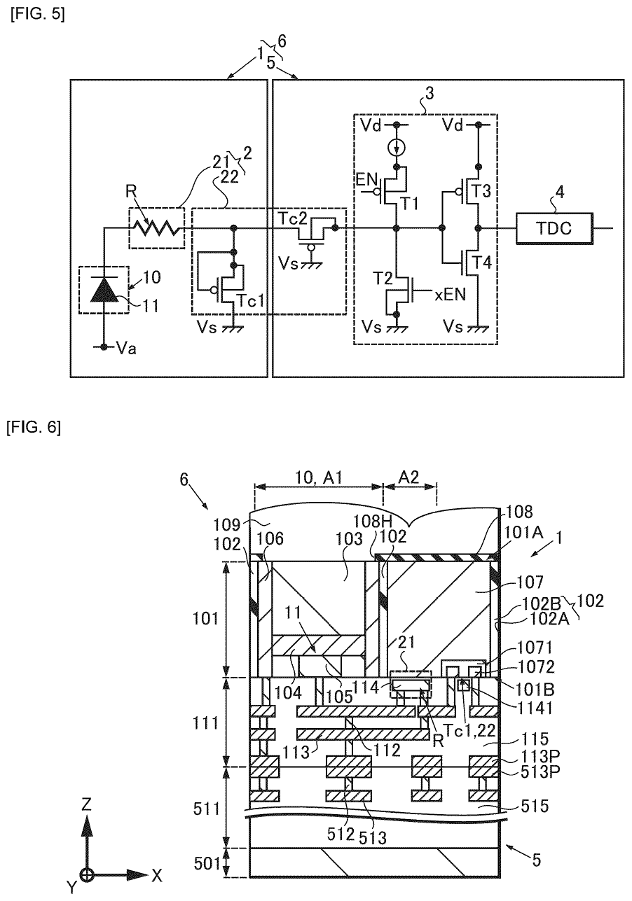

Description is given of the photodetector 1 and the distance measurement system 6 according to the 1-2nd embodiment of the present disclosure with reference to FIGS. 5 to 7. The photodetector 1 and the distance measurement system 6 according to the 1-2nd embodiment are an example in which the configuration of the second protective circuit 22 is changed in the photodetector 1 and the distance measurement system 6 according to the 1-1st embodiment.

It is to be noted that, in the 1-2nd embodiment and the subsequent embodiments, components the same or substantially the same as the components of the photodetector 1 and the distance measurement system 6 according to the 1-1st embodiment are denoted by the same reference numerals, and redundant descriptions are omitted.

### [1. Circuit Configurations of Photodetector 1 and Distance Measurement System 6]

FIG. 5 illustrates an example of circuit configurations of the photodetector 1 and the distance measurement system 6 according to the 1-2nd embodiment.

As illustrated in FIG. 5, the photodetector 1 includes the first clamp element Tc1 of the second protective circuit 22. The circuit device 5 includes the second clamp element Tc2 of the second protective circuit 22.

In other words, the first clamp element Tc1 and the second clamp element Tc2 of the second protective circuit 22 are divided, and distributed respectively to the photodetector 1 and the circuit device 5.

### [2. Device Configurations of Photodetector 1 and Distance Measurement System 6]

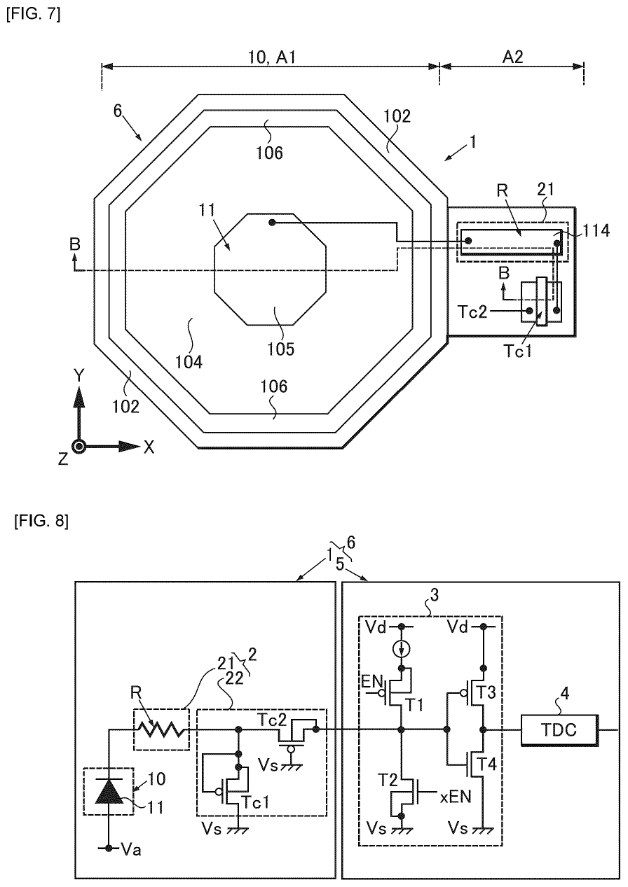

FIG. 6 illustrates an example of a longitudinal cross-sectional configuration of one pixel 10 of the photodetector 1 illustrated in FIG. 5. FIG. 7 illustrates an example of a planar configuration of the one pixel 10 of the photodetector 1 illustrated in FIG. 6.

### (1) Configuration of First Protective Circuit 21

As illustrated in FIGS. 6 and 7, the first protective circuit 21 of the protective circuit 2 includes the resistor element R, as with the photodetector 1 according to the 1-1st embodiment. The resistor element R is provided in the second region A2 adjacent to the first region A1 with the insulating isolator 102 interposed therebetween in the plane direction of the first surface 101A of the first base 101.

Here, the planar shape of the resistor element R is formed in a rectangular shape elongated in the arrow-X direction.

### (2) Configurations of First Clamp Element Tc1 of Second Protective Circuit 22

The first clamp element Tc1 of the second protective circuit 22 is provided in the second region A2 in common with the resistor element R of the first protective circuit 21. In the second region A2, an n-type semiconductor region (an n-type well region) 1071 is provided in the p-type semiconductor region 107 on the side of the second surface 101B.

The first clamp element Tc1 includes p-type semiconductor regions 1072 as a pair of main electrodes that are provided in the n-type semiconductor region 1071, a gate insulating film with no reference numeral, and a gate electrode 1141 that is provided in the gate insulating film. Here, the gate electrode 1141 is formed in the same electrically conductive layer in which the resistor element R is provided, and includes the same electrically conductive material as that of the resistor element R.

In the 1-2nd embodiment, the first clamp element Tel is provided relative to the resistor element R on a side opposite to the arrow-Y direction in a plan view. Moreover, the wiring 113 that is coupled to a side of the other end of the resistor element R and extends in the arrow-X direction is turned to a side opposite to the arrow-X direction so as to be coupled to the first clamp element Tc1.

Components other than the above-described components are the same or substantially the same as the components of the photodetector 1 and the distance measurement system 6 according to the 1-1st embodiment, and redundant descriptions are therefore omitted.

### [Workings and Effects]

As described above, in the photodetector 1 and the distance measurement system 6 according to the 1-2nd embodiment, it is possible to obtain workings and effects similar to the workings and effects obtained by the photodetector 1 and the distance measurement system 6 according to the 1-1st embodiment.

In addition, as illustrated in FIGS. 5 to 7, the photodetector 1 includes the SPAD 11, one or more elements different from the SPAD 11, and the insulating isolator 102. The one or more elements are provided in the second region A2 adjacent to the first region A1 of the first base 101 in the plane direction of the first base 101. Here, the one or more elements include the resistor element R that constructs the first protective circuit 21 of the protective circuit 2, and the first clamp element Tc1 that constructs the second protective circuit 22 of the protective circuit 2.

Moreover, the insulating isolator 102 is provided between the first region A1 and the second region A2, and at least electrically isolates the SPAD 11 and the first clamp element Tc1 from each other.

In the photodetector 1 having such a configuration, the insulating isolator 102 is provided between the SPAD 11 that is provided in the first region A1, and the first clamp element Tc1 that is provided in the second region A2.

Accordingly, the n-type semiconductor region (the n-type well region) 103 and the n-type semiconductor region (the n-type well region) 1071 that are to be supplied with different electric powers (potentials) are electrically and reliably isolated from each other, which makes it possible to provide the first clamp element Tc1 in the second region.

### 3. 1-3rd Embodiment

Description is given of the photodetector 1 and the distance measurement system 6 according to the 1-3rd embodiment of the present disclosure with reference to FIGS. 8 to 10. The photodetector 1 and the distance measurement system 6 according to the 1-3rd embodiment are an example in which the configuration of the second protective circuit 22 is changed in the photodetector 1 and the distance measurement system 6 according to the 1-2nd embodiment.

### [1. Circuit Configurations of Photodetector 1 and Distance Measurement System 6]

FIG. 8 illustrates an example of circuit configurations of the photodetector 1 and the distance measurement system 6 according to the 1-3rd embodiment.

As illustrated in FIG. 8, the photodetector 1 includes the first clamp element Tc1 and the second clamp element Tc2 of the second protective circuit 22. The circuit device 5 does not include the second protective circuit 22.

In other words, the first clamp element Tc1 and the second clamp element Tc2 of the second protective circuit 22 are not provided in the circuit device 5, but are provided in the photodetector 1.

### [2. Device Configurations of Photodetector 1 and Distance Measurement System 6]

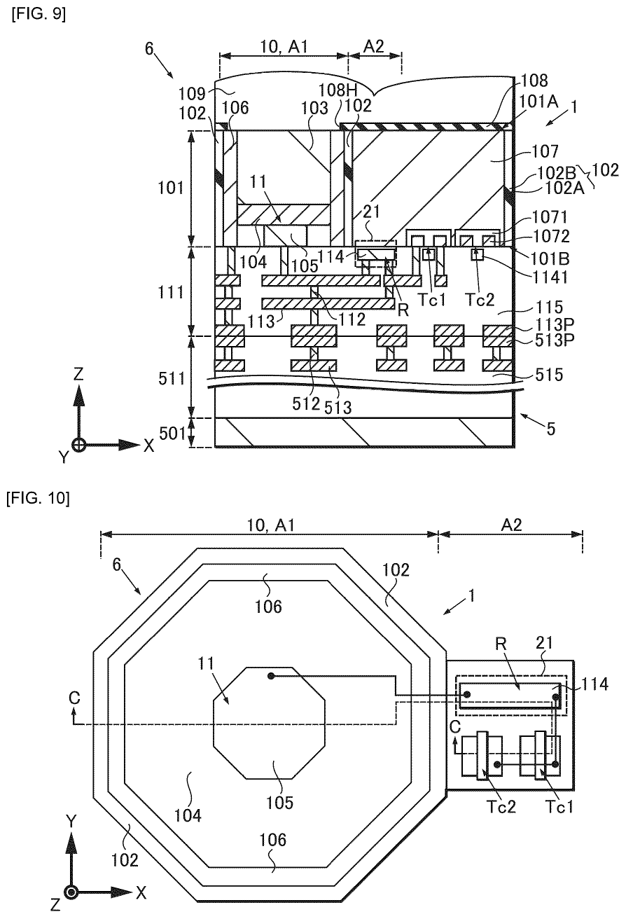

FIG. 9 illustrates an example of a longitudinal cross-sectional configuration of one pixel 10 of the photodetector 1 illustrated in FIG. 8. FIG. 10 illustrates an example of a planar configuration of the one pixel 10 of the photodetector 1 illustrated in FIG. 9.

### (1) Configuration of First Protective Circuit 21

As illustrated in FIGS. 9 and 10, the first protective circuit 21 of the protective circuit 2 includes the resistor element R, as with the photodetector 1 according to the 1-1st embodiment. The resistor element R is provided in the second region A2 adjacent to the first region A1 with the insulating isolator 102 interposed therebetween in the plane direction of the first surface 101A of the first base 101.

Here, the planar shape of the resistor element R is formed in a rectangular shape elongated in the arrow-X direction, as with the photodetector 1 according to the 1-2nd embodiment.

### (2) Configurations of First Clamp Element Tc1 and Second Clamp Element Tc2 of Second Protective Circuit 22

The first clamp element Tc1 and the second clamp element Tc2 of the second protective circuit 22 are provided in the second region A in common with the resistor element R of the first protective circuit 21.

Moreover, the second clamp element Tc2 has a configuration similar to the configuration of the first clamp element Tc1, as with the photodetector 1 according to the 1-2nd embodiment. That is, in the second region A2, the n-type semiconductor region (the n-type well region) 1071 is provided in the p-type semiconductor region 107 on the side of the second surface 101B.

The second clamp element Tc2 includes the p-type semiconductor regions 1072 as a pair of main electrodes that are provided in the n-type semiconductor region 1071, a gate insulating film with no reference numeral, and the gate electrode 1141 that is provided in the gate insulating film. Here, the gate electrode 1141 is formed in the same electrically conductive layer in which the gate electrode 1141 of the first clamp element Tc1 is provided, and includes the same electrically conductive material as that of the gate electrode 1141 of the first clamp element Tc1.

In the 1-3rd embodiment, the second clamp element Tc2 is provided adjacent to the first clamp element Tc1 on the side opposite to the arrow-X direction in a plan view.

Components other than the above-described components are the same or substantially the same as the components of the photodetector 1 and the distance measurement system 6 according to the 1-2nd embodiment, and redundant descriptions are therefore omitted.

### [Workings and Effects]

As described above, in the photodetector 1 and the distance measurement system 6 according to the 1-3rd embodiment, it is possible to obtain workings and effects similar to the workings and effects obtained by the photodetector 1 and the distance measurement system 6 according to the 1-2nd embodiment.

In addition, as illustrated in FIGS. 8 to 10, the photodetector 1 includes the SAPD 11, one or more elements different from the SPAD 11, and the insulating isolator 102. The one or more elements are provided in the second region A2 adjacent to the first region A1 of the first base 101 in the plane direction of the first base 101. Here, the one or more elements include the resistor element R that constructs the first protective circuit 21 of the protective circuit 2, and the first clamp element Tc1 and the second clamp element Tc2 that construct the second protective circuit 22 of the protective circuit 2.

Moreover, the insulating isolator 102 is provided between the first region A1 and the second region A2, and at least electrically isolates the SPAD 11 and each of the first clamp element Tc1 and the second clamp element Tc2 from each other.

In the photodetector 1 having such a configuration, the insulating isolator 102 is provided between the SPAD 11 that is provided in the first region A1, and the first clamp element Tc1 and the second clamp element Tc2 that are provided in the second region A2.

Accordingly, the n-type semiconductor region (the n-type well region) 103 and the n-type semiconductor region (the n-type well region) 1071 that are to be supplied with different electric powers (potentials) are electrically and reliably isolated from each other, which makes it possible to provide the first clamp element Tc1 and the second clamp element Tc2 in the second region.

### 4. 1-4th Embodiment

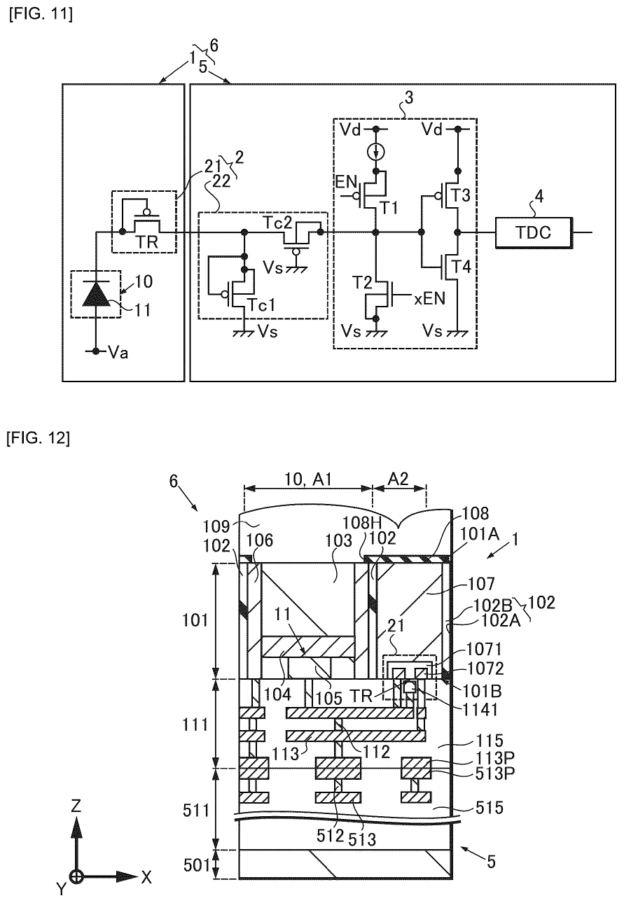

Description is given of the photodetector 1 and the distance measurement system 6 according to the 1-4th embodiment of the present disclosure with reference to FIGS. 11 to 13. The photodetector 1 and the distance measurement system 6 according to the 1-4th embodiment is an example in which the configuration of the first protective circuit 21 is changed in the photodetector 1 and the distance measurement system 6 according to the 1-1st embodiment.

### [1. Circuit Configurations of Photodetector 1 and Distance Measurement System 6]

FIG. 11 illustrates an example of circuit configurations of the photodetector 1 and the distance measurement system 6 according to the 1-4th embodiment.

As illustrated in FIG. 11, the photodetector 1 includes a transistor resistor element TR in place of the resistor element R of the first protective circuit 21. Here, the transistor resistor element TR includes a p-type IGFET.

Detailed description is given. One of a pair of main electrodes of the transistor resistor element TR and a gate electrode of the transistor resistor element TR are coupled to the cathode electrode of the SPAD 11. Another main electrode of the transistor resistor element TR is coupled to the readout circuit 3 with the second protective circuit 22 interposed therebetween.

### [2. Device Configurations of Photodetector 1 and Distance Measurement System 6]

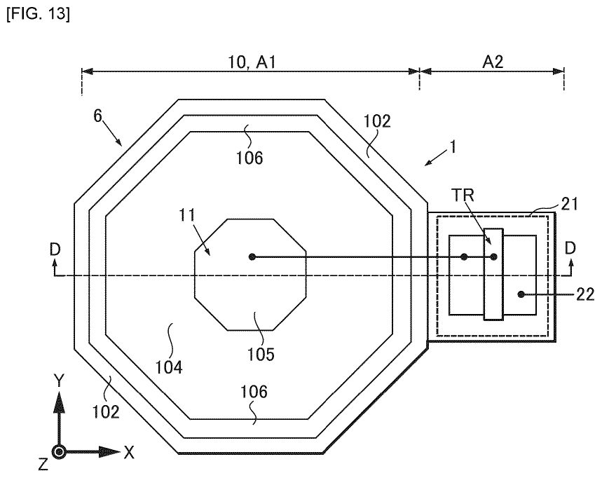

FIG. 12 illustrates an example of a longitudinal cross-sectional configuration of one pixel 10 of the photodetector 1 illustrated in FIG. 11. FIG. 13 illustrates an example of a planar configuration of the one pixel 10 of the photodetector 1 illustrated in FIG. 12.

### (1) Configuration of First Protective Circuit 21

As illustrated in FIGS. 12 and 13, the first protective circuit 21 of the protective circuit 2 is provided in the second region A2, as with the first clamp element Tc1 of the second protective circuit 22 of the 1-2nd embodiment. In the second region A2, the n-type semiconductor region (the n-type well region) 1071 is provided in the p-type semiconductor region 107 on the side of the second surface 101B.

The transistor resistor element TR includes the p-type semiconductor regions 1072 as a pair of main electrodes that are provided in the n-type semiconductor region 1071, a gate insulating film with no reference numeral, and the gate electrode 1141 that is provided in the gate insulating film.

### (2) Configuration of Second Protective Circuit 22

The second protective circuit 22 is configured similarly to the second protective circuit 22 of the photodetector 1 according to the 1-1st embodiment.

Components other than the above-described components are the same or substantially the same as the components of the photodetector 1 and the distance measurement system 6 according to the 1-1st embodiment, and redundant descriptions are therefore omitted.

### [Workings and Effects]

As described above, in the photodetector 1 and the distance measurement system 6 according to the 1-4th embodiment, it is possible to obtain workings and effects similar to the workings and effects obtained by the photodetector 1 and the distance measurement system 6 according to the 1-1st embodiment.

In addition, as illustrated in FIGS. 11 to 13, the photodetector 1 includes the SPAD 11, one or more elements different from the SPAD 11, and the insulating isolator 102. The one or more elements are provided in the second region A2 adjacent to the first region A1 of the first base 101 in the plane direction of the first base 101. Here, the one or more elements include the transistor resistor element TR that constructs the first protective circuit 21 of the protective circuit 2.

Moreover, the insulating isolator 102 is provided between the first region A1 and the second region A2, and at least electrically isolates the SPAD 11 and the transistor resistor element TR from each other.

In the photodetector 1 having such a configuration, the insulating isolator 102 is provided between the SPAD 11 that is provided in the first region A1, and the transistor resistor element TR that is provided in the second region A2.

Accordingly, the n-type semiconductor region (the n-type well region) 103 and the n-type semiconductor region (the n-type well region) 1071 that are to be supplied with different electric powers (potentials) are electrically and reliably isolated from each other, which makes it possible to provide the transistor resistor element TR in the second region.

### 5. 1-5th Embodiment

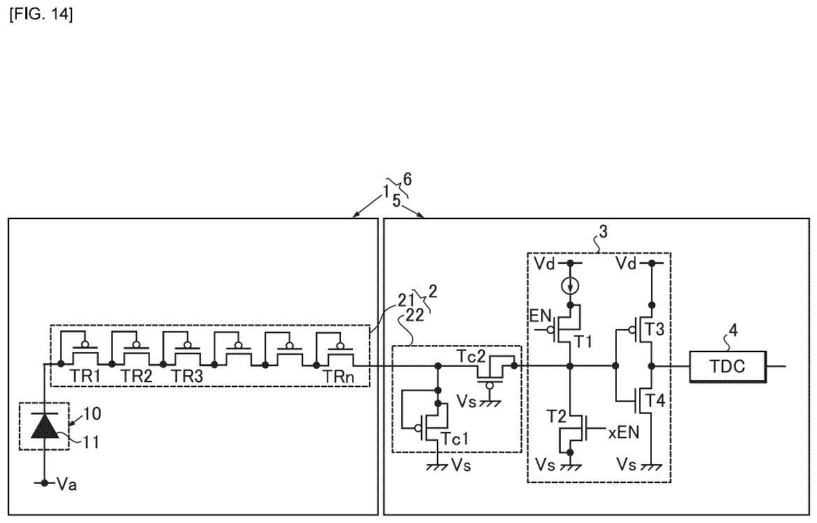

Description is given of the photodetector 1 and the distance measurement system 6 according to the 1-5th embodiment of the present disclosure with reference to FIGS. 14 to 16. The photodetector 1 and the distance measurement system 6 according to the 1-5th embodiment are an example in which the configuration of the first protective circuit 21 is changed in the photodetector 1 and the distance measurement system 6 according to the 1-4th embodiment.

### [1. Circuit Configurations of Photodetector 1 and Distance Measurement System 6]

FIG. 14 illustrates an example of circuit configurations of the photodetector 1 and the distance measurement system 6 according to the 1-5th embodiment.

As illustrated in FIG. 14, the photodetector 1 includes, in the first protective circuit 21, a plurality of transistor resistor elements TR1, TR2, . . . , TRn electrically coupled in series. The transistor resistor element TR1 to the transistor resistor element TRn each include a p-type IGFET. Here, a total of six transistor resistor elements TR1 to TRn (where n=6) are arranged, although the number of transistor resistor elements arranged is not limited thereto.

One of a pair of main electrodes of the transistor resistor element TR1 in a first arrangement stage is coupled to the cathode electrode of the SPAD 11. Another main electrode of the transistor resistor element TRn in a last arrangement stage is coupled to the readout circuit 3 with the second protective circuit 22 interposed therebetween.

### [2. Device Configurations of Photodetector 1 and Distance Measurement System 6]

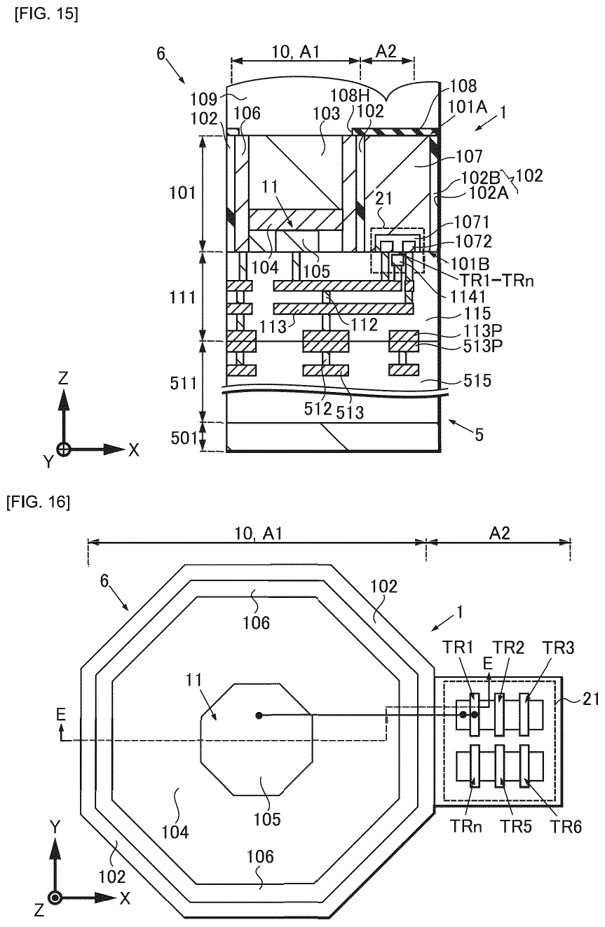

FIG. 15 illustrates an example of a longitudinal cross-sectional configuration of one pixel 10 of the photodetector 1 illustrated in FIG. 14. FIG. 16 illustrates an example of a planar configuration of the one pixel 10 of the photodetector 1 illustrated in FIG. 15.

### (1) Configuration of First Protective Circuit 21

As illustrated in FIGS. 15 and 16, the first protective circuit 21 of the protective circuit 2 is provided in the second region A2, as with the resistor element R of the first protective circuit 21 of the 1-1st embodiment. In the second region A2, the n-type semiconductor region (the n-type well region) 1071 is provided in the p-type semiconductor region 107 on the side of the second surface 101B, as with the transistor resistor element TRn of the photodetector 1 according to the 1-4th embodiment.

The n-type semiconductor region 1071 is provided for each or every two or more of the transistor resistor element TR1 to the transistor resistor element TRn, or is provided to be shared by all of the transistor resistor element TR1 to the transistor resistor element TRn. Here, the n-type semiconductor region 1071 shared by the transistor resistor element TR1 to the transistor resistor element TR3, and the n-type semiconductor region 1071 shared by the transistor resistor element TR4 to the transistor resistor element TRn are provided.

The transistor resistor element TR1 to the transistor resistor element TRn each include the p-type semiconductor regions 1072 as a pair of main electrodes that are provided in the n-type semiconductor region 1071, a gate insulating film with no reference numeral, and the gate electrode 1141 that is provided in the gate insulating film.

The respective transistor resistor elements TR1 to TR3 are sequentially arranged in the arrow-X direction in a plan view. The respective transistor resistor element TR4 to TRn are sequentially arranged in the direction opposite to the arrow-X direction, with an arrangement direction being turned around.

### (2) Configuration of Second Protective Circuit 22

The second protective circuit 22 is configured similarly to the second protective circuit 22 of the photodetector 1 according to the 1-1st embodiment.

Components other than the above-described components are the same or substantially the same as the components of the photodetector 1 and the distance measurement system 6 according to the 1-4th embodiment, and redundant descriptions are therefore omitted.

### [Workings and Effects]

As described above, in the photodetector 1 and the distance measurement system 6 according to the 1-5th embodiment, it is possible to obtain workings and effects similar to the workings and effects obtained by the photodetector 1 and the distance measurement system 6 according to the 1-4th embodiment.

In addition, as illustrated in FIGS. 14 to 16, the photodetector 1 includes the SAPD 11, one or more elements different from the SPAD 11, and the insulating isolator 102. The one or more elements are provided in the second region A2 adjacent to the first region A1 of the first base 101 in the plane direction of the first base 101. Here, the one or more elements include the transistor resistor element TR1 to the transistor resistor element TRn that construct the first protective circuit 21 of the protective circuit 2.

In the photodetector 1 having such a configuration, the first protective circuit 21 of the protective circuit 2 includes the plurality of transistor resistor elements TR1 to TRn. Accordingly, it is possible to use a current-voltage characteristic of each of the transistor resistor element TR1 to the transistor resistor element TRn in a linear region.

### 6. 1-6th Embodiment

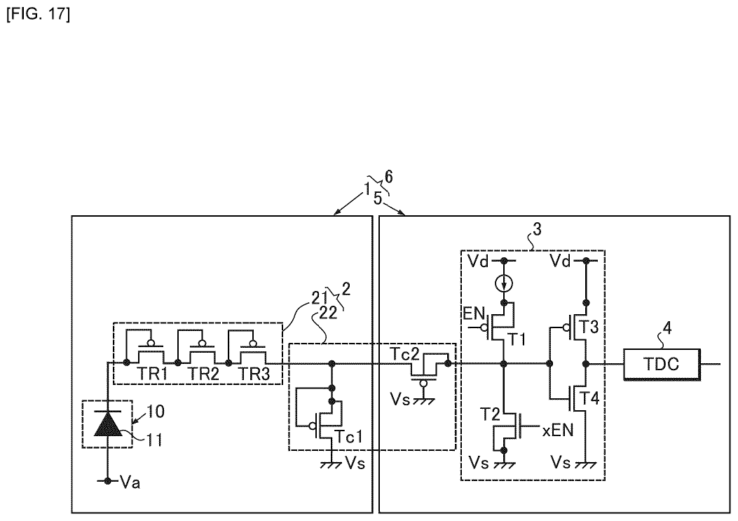

Description is given of the photodetector 1 and the distance measurement system 6 according to the 1-6th embodiment of the present disclosure with reference to FIGS. 17 to 19. The photodetector 1 and the distance measurement system 6 according to the 1-6th embodiment are an example in which the photodetector 1 and the distance measurement system 6 according to the 1-2nd embodiment are respectively combined with the photodetector 1 and the distance measurement system 6 according to the 1-5th embodiment.

### [1. Circuit Configurations of Photodetector 1 and Distance Measurement System 6]

FIG. 17 illustrates an example of circuit configurations of the photodetector 1 and the distance measurement system 6 according to the 1-6th embodiment.

As illustrated in FIG. 17, the photodetector 1 includes, in the first protective circuit 21, a plurality of transistor resistor elements TR1 to TRn electrically coupled in series. Here, a total of three transistor resistor elements TR1 to TRn (where n=3) are arranged.

The photodetector 1 includes the first clamp element Tc1 of the second protective circuit 22, as with the photodetector 1 according to the 1-2nd embodiment. The circuit device 5 includes the second clamp element Tc2 of the second protective circuit 22.

### [2. Device Configurations of Photodetector 1 and Distance Measurement System 6]

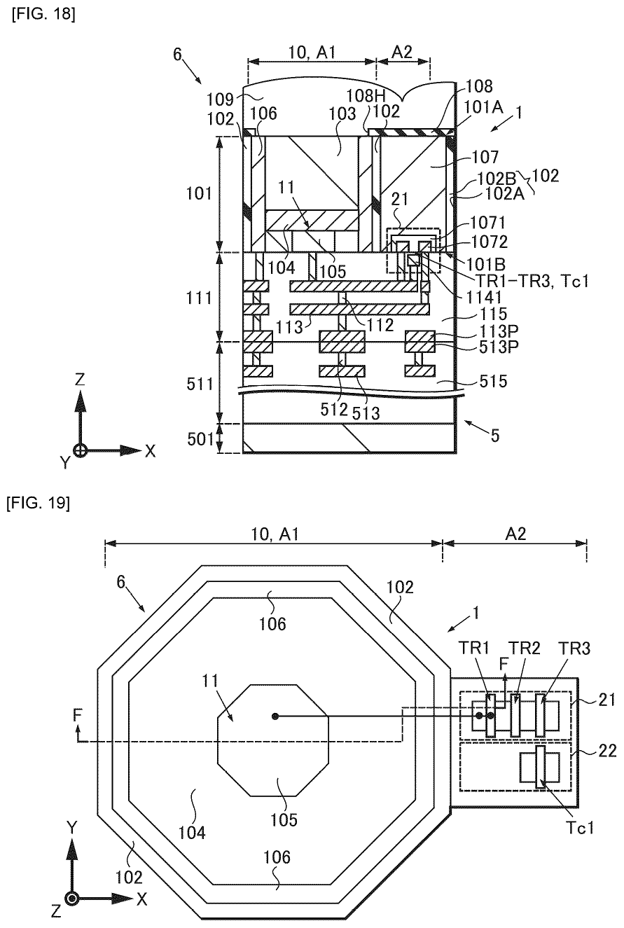

FIG. 18 illustrates an example of a longitudinal cross-sectional configuration of one pixel 10 of the photodetector 1 illustrated in FIG. 17. FIG. 19 illustrates an example of a planar configuration of the one pixel 10 of the photodetector 1 illustrated in FIG. 18.

### (1) Configuration of First Protective Circuit 21

As illustrated in FIGS. 18 and 19, the first protective circuit 21 of the protective circuit 2 is provided in the second region A2, as with the transistor resistor element TR1 to the transistor resistor element TRn of the first protective circuit 21 of the 1-5th embodiment. In the second region A2, the n-type semiconductor region (then n-type well region) 1071 is provided in the p-type semiconductor region 107 on the side of the second surface 101B.

The n-type semiconductor region 1071 is provided to be shared by all of the transistor resistor element TR1 to the transistor resistor element TR3. The transistor resistor element TR1 to the transistor resistor element TR3 each include the p-type semiconductor regions 1072 as a pair of main electrodes that are provided in the n-type semiconductor region 1071, a gate insulating film with no reference numeral, and the gate electrode 1141 that is provided in the gate insulating film.

The transistor resistor element TR1 to the transistor resistor element TR3 are sequentially arranged in the arrow-X direction in a plan view.

### (2) Configuration of Second Protective Circuit 22

The second protective circuit 22 is configured similarly to the second protective circuit 22 of the photodetector 1 according to the 1-2nd embodiment. That is, the first clamp element Tc1 is provided in the second region A2.

Here, the second clamp element Tc2 is provided relative to each of the transistor resistor element TR1 to the transistor resistor element TR3 on the side opposite to the arrow-Y direction in a plan view.

Components other than the above-described components are the same or substantially the same as the components of the photodetector 1 and the distance measurement system 6 according to each of the 1-2nd embodiment and the 1-5th embodiment, and redundant descriptions are therefore omitted.

### [Workings and Effects]

As described above, in the photodetector 1 and the distance measurement system 6 according to the 1-6th embodiment, it is possible to obtain workings and effects including a combination of the workings and effects obtained by the photodetector 1 and the distance measurement system 6 according to the 1-2nd embodiment and the workings and effects obtained by the photodetector 1 and the distance measurement system 6 according to the 1-5th embodiment.

### 7. 1-7th Embodiment

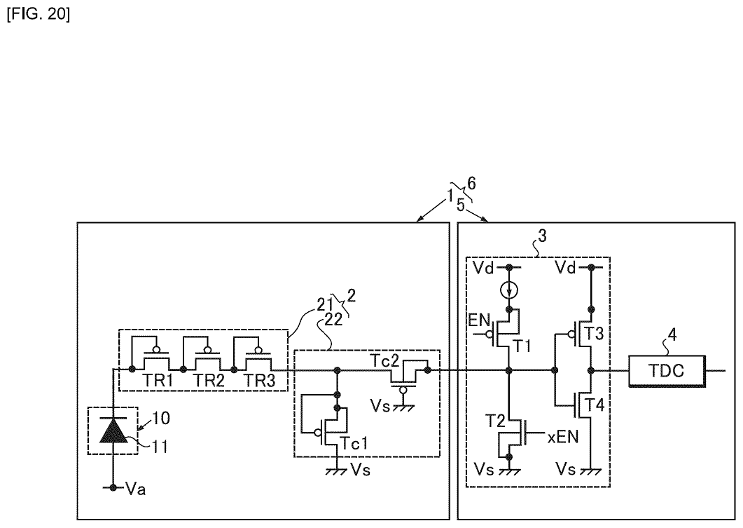

Description is given of the photodetector 1 and the distance measurement system 6 according to the 1-7th embodiment of the present disclosure with reference to FIGS. 20 to 22. The photodetector 1 and the distance measurement system 6 according to the 1-7th embodiment are an example in which the photodetector 1 and the distance measurement system 6 according to the 1-3rd embodiment are respectively combined with the photodetector 1 and the distance measurement system 6 according to the 1-5th embodiment.

### [1. Circuit Configurations of Photodetector 1 and Distance Measurement System 6]

FIG. 20 illustrates an example of circuit configurations of the photodetector 1 and the distance measurement system 6 according to the 1-7th embodiment.

As illustrated in FIG. 20, the photodetector 1 includes, in the first protective circuit 21, a plurality of transistor resistor elements TR1 to TRn electrically coupled in series. Here, a total of three transistor resistor elements TR1 to TRn (where n=3) are arranged.

The photodetector 1 includes the first clamp element Tc1 and the second clamp element Tc2 of the second protective circuit 22, as with the photodetector 1 according to the 1-3rd embodiment. The circuit device 5 includes no second protective circuit 22.

### [2. Device Configurations of Photodetector 1 and Distance Measurement System 6]

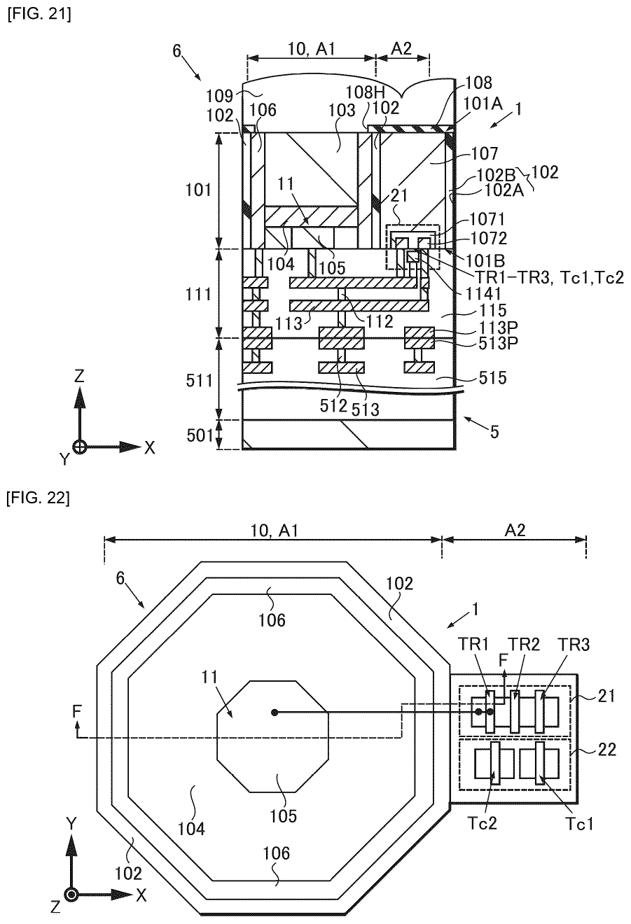

FIG. 21 illustrates an example of a longitudinal cross-sectional configuration of one pixel 10 of the photodetector 1 illustrated in FIG. 20. FIG. 22 illustrates an example of a planar configuration of the one pixel 10 of the photodetector 1 illustrated in FIG. 21.

### (1) Configuration of First Protective Circuit 21

As illustrated in FIGS. 21 and 22, the first protective circuit 21 of the protective circuit 2 is provided in the second region A2, as with the transistor resistor element TR1 to the transistor resistor element TRn of the first protective circuit 21 of the 1-5th embodiment. In the second region A2, the n-type semiconductor region (the n-type well region) 1071 is provided in the p-type semiconductor region 107 on the side of the second surface 101B.

The n-type semiconductor region 1071 is provided to be shared by all of the transistor resistor element TR1 to the transistor resistor element TR3. The transistor resistor element TR1 to the transistor resistor element TR3 each include the p-type semiconductor regions 1072 as a pair of main electrodes that are provided in the n-type semiconductor region 1071, a gate insulating film with no reference numeral, and the gate electrode 1141 that is provided in the gate insulating film.

The transistor resistor element TR1 to the transistor resistor element TR3 are sequentially arranged in the arrow-X direction in a plan view.

### (2) Configuration of Second Protective Circuit 22

The second protective circuit 22 is configured similarly to the second protective circuit 22 of the photodetector 1 according to the 1-3rd embodiment. That is, the first clamp element Tc1 and the second clamp element Tc2 are provided in the second region A2.

Here, the first clamp element Tc1 and the second clamp element Tc2 are each provided on the side opposite to the arrow-X direction in a plan view. In addition, the first clamp element Tc1 and the second clamp element Tc2 are provided relative to each of the transistor resistor element TR1 to the transistor resistor element TR3 on the side opposite to the arrow-Y direction.

Components other than the above-described components are the same or substantially the same as the components of the photodetector 1 and the distance measurement system 6 according to each of the 1-3rd embodiment and the 1-5th embodiment, and redundant descriptions are therefore omitted.

### [Workings and Effects]

As described above, in the photodetector 1 and the distance measurement system 6 according to the 1-7th embodiment, it is possible to obtain workings and effects including a combination of the workings and effects obtained by the photodetector 1 and the distance measurement system 6 according to the 1-3rd embodiment and the workings and effects obtained by the photodetector 1 and the distance measurement system 6 according to the 1-5th embodiment.

### 8. 1-8th Embodiment

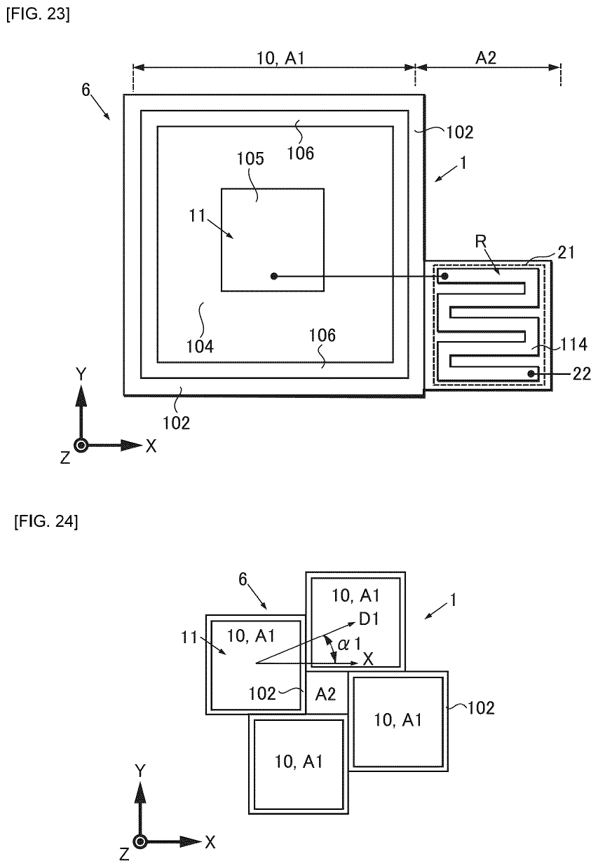

Description is given of the photodetector 1 and the distance measurement system 6 according to the 1-8th embodiment of the present disclosure with reference to FIGS. 23 to 26. The photodetector 1 and the distance measurement system 6 according to the 1-8th embodiment is an example in which the planar configuration of the pixel 10 is changed in the photodetector 1 and the distance measurement system 6 according to the 1-1st embodiment.

### [Device Configurations of Photodetector 1 and Distance Measurement System 6]

### (1) Configuration of Pixel 10

FIG. 23 illustrates an example of a planar configuration of one pixel 10 in the photodetector 1 and the distance measurement system 6 according to the 1-8th embodiment. FIG. 24 illustrates an example of a planar configuration of the photodetector 1 in which a plurality of pixels 10 illustrated in FIG. 23 is arranged.

As illustrated in FIG. 23, a planar shape of the insulating isolator 102 is formed in a rectangular shape that is a polygonal shape in a plan view. Here, the planar shape of the insulating isolator 102 is formed in a quadrilateral shape or a square shape. The pixel 10 is surrounded by the insulating isolator 102. Accordingly, the planar shape of the pixel 10 is formed in a rectangular shape, as with the planar shape of the insulating isolator 102. That is, the planar shape of the anode region 104 of the SPAD 11 is formed in a rectangular shape. Moreover, the planar shape of the cathode region 105 is formed in a rectangular shape that is smaller in size than the planar shape of the anode region 104.

Here, the planar shape of the first region A1 is formed in a rectangular shape, as with the planar shape of the pixel 10.

As illustrated in FIG. 24, the plurality of pixels 10 is arranged in the arrow-X direction and the arrow-Y direction. To describe this in detail, relative to one pixel 10, another pixel 10 adjacent in the arrow-X direction is provided to be shifted in the arrow-Y direction by a length less than or equal to about half a length of one side of the pixel 10. In other words, the pixels 10 are arranged in an oblique direction D1 relative to the arrow-X direction at a predetermined angle al on the side of the arrow-Y direction.

### (2) Configuration of First Protective Circuit 21 of Protective Circuit 2

As illustrated in FIG. 23 and FIG. 24, the second region A2 is surrounded by a total of four first regions A1 including two first regions A1 provided adjacent in the arrow-X direction and two first regions A1 provided adjacent in the arrow-X direction and adjacent in the arrow-Y direction. The second region A2 has four sides each having a length less than or equal to about half a length of one side of a corresponding one of the four first regions A1 in a plan view. That is, the planar shape of the second region A2 is formed in a rectangular shape, in this case, in a quadrilateral shape or a square shape.

In other words, the planar shape of the first region A1 is formed in a polygonal shape as described above; therefore, the second region A2 is surrounded by three or more first regions A1.

The first protective circuit 21 is provided in the second region A2, as with the photodetector 1 according to the 1-1st embodiment. The first protective circuit 21 includes the resistor element R.

Components other than the above-described components are the same or substantially the same as the components of the photodetector 1 and the distance measurement system 6 according to the 1-1st embodiment, and redundant descriptions are therefore omitted.

### [Workings and Effects]

As described above, in the photodetector 1 and the distance measurement system 6 according to the 1-8th embodiment, it is possible to obtain workings and effects similar to the workings and effects obtained by the photodetector 1 and the distance measurement system 6 according to the 1-1st embodiment.

### [First Modification Example]

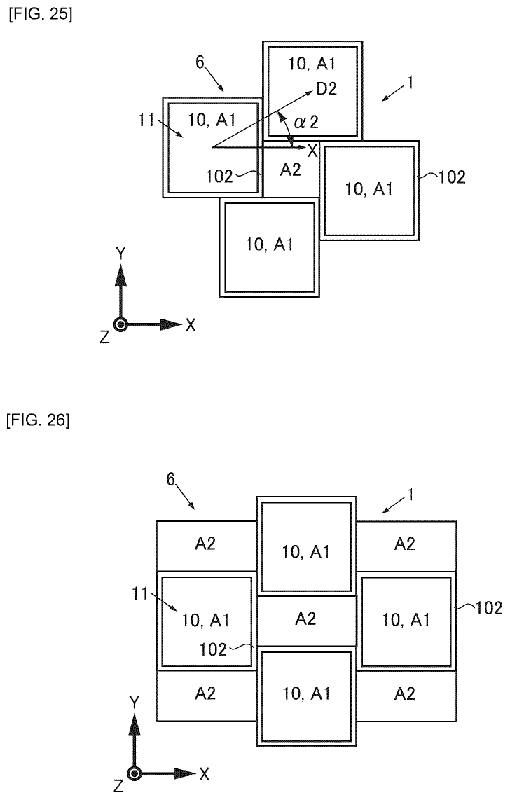

Description is given of the photodetector 1 and the distance measurement system 6 according to a first modification example of the 1-8th embodiment of the present disclosure with reference to FIG. 25.

FIG. 25 illustrates an example of a planar configuration of the photodetector 1 in which a plurality of pixels 10 is arranged in the photodetector 1 and the distance measurement system 6 according to the first modification example of the 1-8th embodiment.

### (1) Configuration of Pixel 10

As illustrated in FIG. 25, the plurality of pixels 10 is arranged in the arrow-X direction and the arrow-Y direction, as with the photodetector 1 according to the 1-8th embodiment. To describe this in detail, relative to one pixel 10, another pixel 10 adjacent in the arrow-X direction is provided to be shifted in the arrow-Y direction by a length longer than or equal to about half the length of one side of the pixel 10. In other words, the pixels 10 are arranged in an oblique direction D2 relative to the arrow-X direction at a predetermined angle 2 on the side of the arrow-Y direction. In the photodetector 1 according to the first modification example, the angle a2 of the oblique direction D2 is larger than the angle al (see FIG. 24) of the oblique direction D1 in the photodetector 1 according to the 1-8th embodiment.

### (2) Configuration of First Protective Circuit 21 of Protective Circuit 2

As with the photodetector 1 according to the 1-8th embodiment, the second region A2 is surrounded by a total of four first regions A1 including two first regions A1 provided adjacent in the arrow-X direction and two first regions A1 provided adjacent in the arrow-X direction and adjacent in the arrow-Y direction. The second region A2 has four sides each having a length longer than or equal to about half the length of one side of a corresponding one of the four first regions A1 in a plan view. That is, the planar shape of the second region A2 is formed in a rectangular shape, in this case, in a quadrilateral shape or a square shape.

In other words, the planar shape of the first region A1 is formed in a polygonal shape as described above; therefore, the second region A2 is surrounded by three or more first regions A1.

Components other than the above-described components are the same or substantially the same as the components of the photodetector 1 and the distance measurement system 6 according to the 1-8th embodiment, and redundant descriptions are therefore omitted.

### [Workings and Effects]

As described above, in the photodetector 1 and the distance measurement system 6 according to the first modification example, it is possible to obtain workings and effects similar to the workings and effects obtained by the photodetector 1 and the distance measurement system 6 according to the 1-8th embodiment.

In addition, in the photodetector 1 according to the first modification example, as illustrated in FIG. 25, the angle a2 of the oblique direction D2 of the pixel 10 is large. That is, the second region A2 has a length longer than or equal to about half the length of one side of the first region A1 that is provided with the pixel 10 and formed in a rectangular shape, and is surrounded by the plurality of first regions A1.

It is thus possible to make a planar area of the second region A2 larger than an area of the second region A2 of the photodetector 1 according to the 1-8th embodiment. In a case where the area of the second region A2 is made large, it is possible to easily dispose the first protective circuit 21.

[second Modification Example]

Description is given of the photodetector 1 and the distance measurement system 6 according to a second modification example of the 1-8th embodiment of the present disclosure with reference to FIG. 26.

FIG. 26 illustrates an example of a planar configuration of the photodetector 1 in which a plurality of pixels 10 is arranged in the photodetector 1 and the distance measurement system 6 according to the second modification example of the 1-8th embodiment.

### (1) Configuration of Pixel 10

As illustrated in FIG. 26, the pixel 10 is formed in a rectangular shape in a plan view, as with the photodetector 1 according to the 1-8th embodiment. Moreover, the plurality of pixels 10 is arranged in the arrow-X direction and the arrow-Y direction.

To describe this in detail, relative to one pixel 10, another pixel 10 adjacent in the arrow-X direction is provided to be shifted by a length equal to the length of one side of the one pixel 10. In addition, relative to the one pixel 10, another pixel 10 adjacent in the arrow-Y direction is provided to be shifted by a length shorter than the length of one side of the one pixel 10.

### (2) Configuration of First Protective Circuit 21 of Protective Circuit 2

As with the photodetector 1 according to the 1-8th embodiment, the second region A2 is surrounded by a total of four first regions A1 including two first regions A1 provided adjacent in the arrow-X direction and two first regions A1 provided adjacent in the arrow-Y direction. The second region A2 is formed in a rectangular shape having a longer side in the arrow-X direction and a shorter side in the arrow-Y direction in a plan view.

Components other than the above-described components are the same or substantially the same as the components of the photodetector 1 and the distance measurement system 6 according to the 1-8th embodiment, and redundant descriptions are therefore omitted.

[workings and Effects]

As described above, in the photodetector 1 and the distance measurement system 6 according to the first modification example, it is possible to obtain workings and effects similar to the workings and effects obtained by the photodetector 1 and the distance measurement system 6 according to the 1-8th embodiment.

In addition, in the photodetector 1 according to the second modification example, as illustrated in FIG. 26, an arrangement pitch in the arrow-Y direction of the pixel 10 is shorter than an arrangement pitch in the arrow-X direction of the pixel 10. That is, the second region A2 is surrounded by the plurality of first regions A1 that are each provided with the pixel 10 and formed in a rectangular shape, and the planar shape of the second region is formed in a rectangular shape.

It is thus possible to make the planar area of the second region A2 larger than the area of the second region A2 of the photodetector 1 according to the first modification example. In a case where the area of the second region A2 is made large, it is possible to easily dispose the first protective circuit 21.

### 9. 1-9th Embodiment

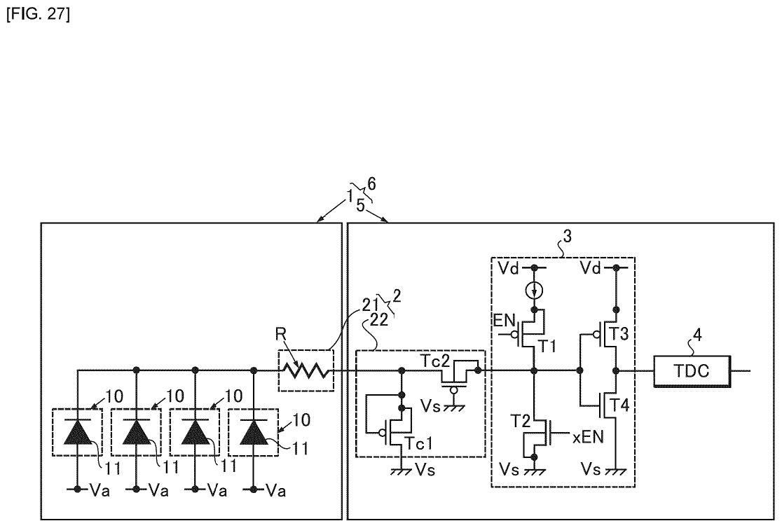

Description is given of the photodetector 1 and the distance measurement system 6 according to the 1-9th embodiment of the present disclosure with reference to FIGS. 27 to 29. The photodetector 1 and the distance measurement system 6 according to the 1-9th embodiment are an example in which the configuration of the pixel 10 is changed in the photodetector 1 and the distance measurement system 6 according to the 1-1st embodiment.

### [1. Circuit Configurations of Photodetector 1 and Distance Measurement System 6]

FIG. 27 illustrates an example of circuit configurations of the photodetector 1 and the distance measurement system 6 according to the 1-9th embodiment.

As illustrated in FIG. 27, in the photodetector 1, the first protective circuit 21 of one protective circuit 2 is provided for a plurality of pixels 10. One readout circuit 3 and one time measurement circuit 4 are each provided for the first protective circuit 21 with one second protective circuit 22 interposed therebetween.

To describe this in detail, four pixels 10 are provided here as the plurality of pixels 10. Each of the pixels 10 includes the SPAD 11, and a total of four SPADs 11 construct a unit pixel including four pixels 10. The respective cathode regions 105 of the four SPADs 11 are electrically coupled in parallel.

It is to be noted that the number of pixels 10 in the unit pixel is not particularly limited, and may be two or more.

The configurations of the first protective circuit 21, the second protective circuit 22, and the like are basically similar to those in the configurations of the photodetector 1 and the distance measurement system 6 according to the 1-1st embodiment.

### [2. Device Configurations of Photodetector 1 and Distance Measurement System 6]

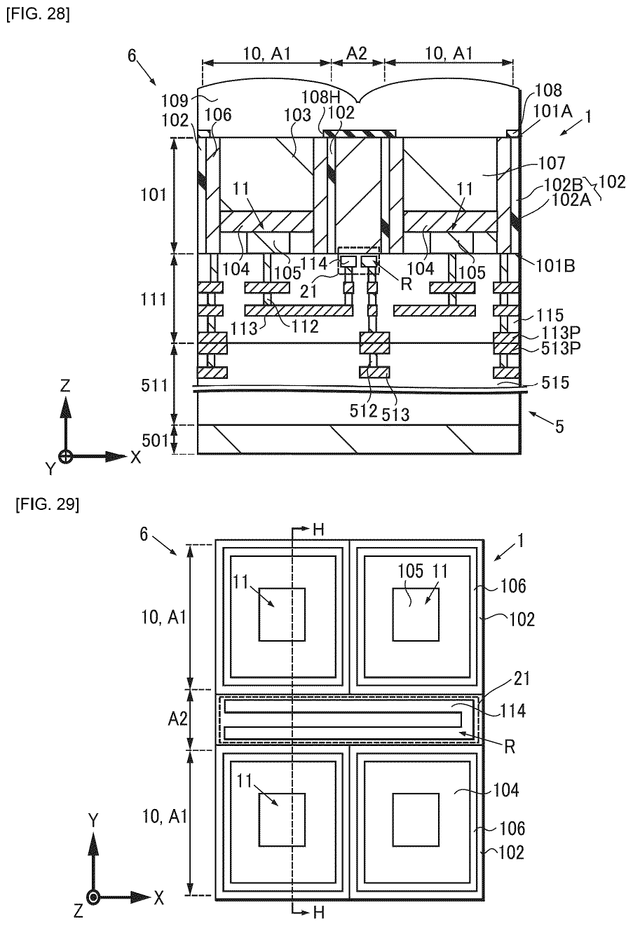

FIG. 28 illustrates an example of longitudinal cross-sectional configurations of a plurality of pixels 10 of the photodetector 1 illustrated in FIG. 27. FIG. 29 illustrates an example of planar configurations of the plurality of pixels 10 of the photodetector 1 illustrated in FIG. 28.

### (1) Configuration of Pixel 10

As illustrated in FIGS. 28 and 29, the pixel 10 is formed similarly to the pixel 10 of the photodetector 1 according to the 1-8th embodiment described above. That is, the pixel 10 is surrounded by the insulating isolator 102, and is formed in a rectangular shape in a plan view.

Relative to one pixel 10, another pixel 10 adjacent in the arrow-X direction is provided adjacent to the one pixel 10 with the insulating isolator 102 interposed therebetween. Moreover, two pixels 10 are provided relative to these two pixels 10 in the arrow-Y direction with the second region A2 interposed therebetween. The two pixels 10 are provided adjacent in the arrow-X direction with the insulating isolator 102 interposed therebetween.

### (2) Configuration of First Protective Circuit 21

The first protective circuit 21 is formed by the resistor element R, as with the first protective circuit 21 of the photodetector 1 according to the 1-1st embodiment.

Here, the planar shape of the second region A2 is formed in a rectangular shape having a longer side in the arrow-X direction and a shorter side in the arrow-Y direction in a plan view. A length on the longer side of the second region A2 corresponds to a length of two pixels 10.

The resistor element R of the first protective circuit 21 is provided in the second region A2. In the second region A2, the resistor element R extends in the arrow-X direction, and is turned around and extends to the side opposite to the arrow-X direction. The resistor element R is formed in a U-shape in a plan view.

Components other than the above-described components are the same or substantially the same as the components of the photodetector 1 and the distance measurement system 6 according to the 1-1st embodiment, and redundant descriptions are therefore omitted.

### [Workings and Effects]

As described above, in the photodetector 1 and the distance measurement system 6 according to the 1-9th embodiment, it is possible to obtain workings and effects similar to the workings and effects obtained by the photodetector 1 and the distance measurement system 6 according to the 1-1st embodiment.

In addition, in the photodetector 1, as illustrated in FIGS. 27 to 29, one first protective circuit 21 is provided for the plurality of pixels 10. In the circuit device 5, one combination of the second protective circuit 22, the readout circuit 3, and the time measurement circuit 4 is similarly provided for the plurality of pixels 10.

This makes it possible to reduce the number of circuits mounted on the circuit device 5, which makes it possible to achieve miniaturization of the distance measurement system 6.

### 10. 1-10th Embodiment

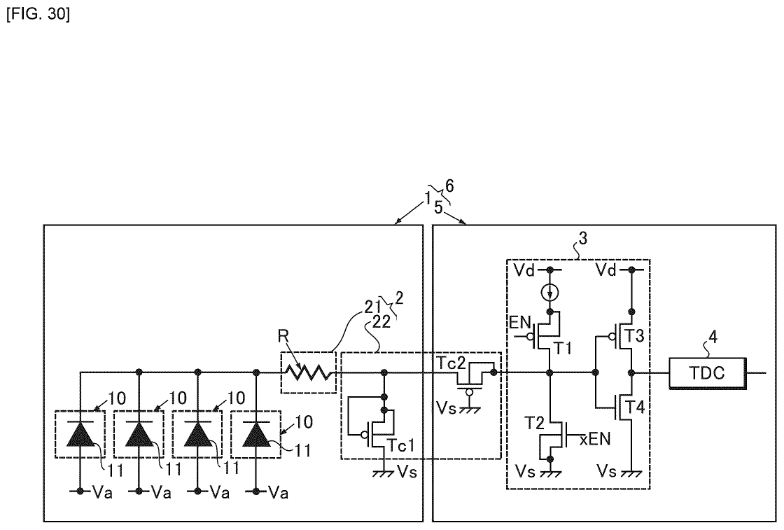

Description is given of the photodetector 1 and the distance measurement system 6 according to the 1-10th embodiment of the present disclosure with reference to FIGS. 30 to 32. The photodetector 1 and the distance measurement system 6 according to the 1-10th embodiment are an example in which the photodetector 1 and the distance measurement system 6 according to the 1-2nd embodiment are respectively combined with the photodetector 1 and the distance measurement system 6 according to the 1-9th embodiment.

### [1. Circuit Configurations of Photodetector 1 and Distance Measurement System 6]

FIG. 30 illustrates an example of circuit configurations of the photodetector 1 and the distance measurement system 6 according to the 1-10th embodiment.

As illustrated in FIG. 30, in the photodetector 1, the first protective circuit 21 and a portion of the second protective circuit 22 in one protective circuit 2 are provided for a plurality of pixels 10, as with the photodetector 1 according to the 1-9th embodiment. One readout circuit 3 and one time measurement circuit 4 are each provided for the portion of the second protective circuit 22 with another portion of the second protective circuit 22 interposed therebetween.

Four pixels 10 are provided as the plurality of pixels 10, as with the photodetector 1 according to the 1-9th embodiment.

The configurations of the first protective circuit 21 and the second protective circuit 22 are basically similar to those in the configurations of the photodetector 1 and the distance measurement system 6 according to the 1-2nd embodiment.

### [2. Device Configurations of Photodetector 1 and Distance Measurement System 6]

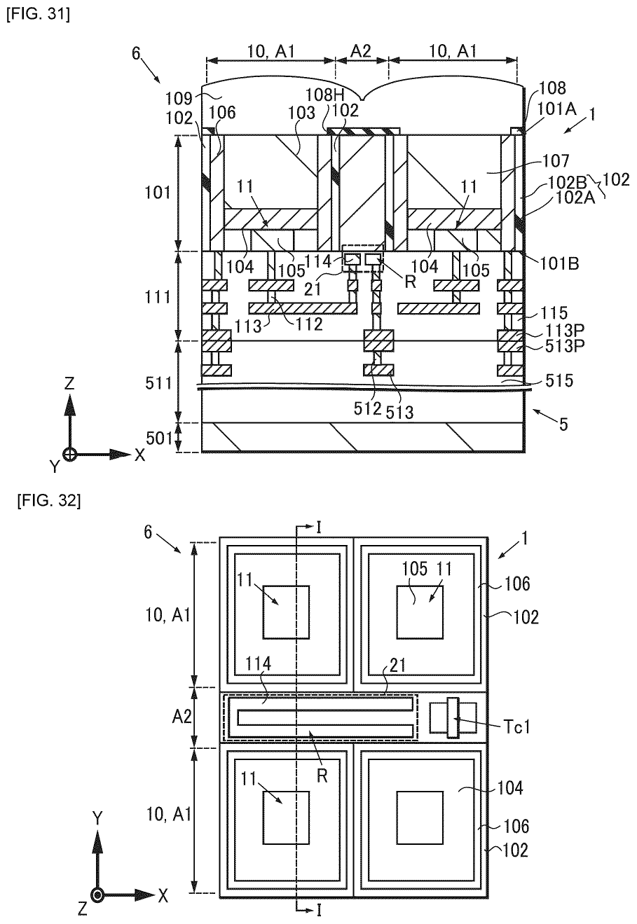

FIG. 31 illustrates an example of a longitudinal cross-sectional configuration of the plurality of pixels 10 of the photodetector 1 illustrated in FIG. 30. FIG. 32 illustrates an example of planar configurations of the plurality of pixels 10 of the photodetector 1 illustrated in FIG. 31.

### (1) Configuration of Pixel 10

As illustrated in FIGS. 31 and 32, the pixel 10 is formed similarly to the pixel 10 of the photodetector 1 according to the 1-9th embodiment described above. That is, the pixel 10 is formed in a rectangular shape in a plan view.

Moreover, the second region A2 is provided between two pixels 10 adjacent in the arrow-X direction and two pixels 10 provided in the arrow-Y direction and being adjacent in the arrow-X direction.

### (2) Configuration of First Protective Circuit 21

The first protective circuit 21 includes the resistor element R, as with the first protective circuit 21 of the photodetector 1 according to the 1-1st embodiment. The resistor element R is provided in the second region A2, as with the photodetector 1 according to the 1-9th embodiment.

### (3) Configuration of Second Protective Circuit 22

A portion of the second protective circuit 22 includes the first clamp element Tc1. The first clamp element Tel is provided together with the resistor element R in the second region A2. The configuration of the first clamp element Tel is similar to the configuration of the first clamp element Tc1 of the photodetector 1 according to the 1-2nd embodiment, and description thereof is therefore omitted here.

Components other than the above-described components are the same or substantially the same as the components of the photodetector 1 and the distance measurement system 6 according to each of the 1-2nd embodiment and the 1-9th embodiment, and redundant descriptions are therefore omitted.

### [Workings and Effects]

As described above, in the photodetector 1 and the distance measurement system 6 according to the 1-10th embodiment, it is possible to obtain workings and effects including a combination of the workings and effects obtained by the photodetector 1 and the distance measurement system 6 according to the 1-2nd embodiment and the workings and effects obtained by the photodetector 1 and the distance measurement system 6 according to the 1-9th embodiment.

### 11. 1-11th Embodiment

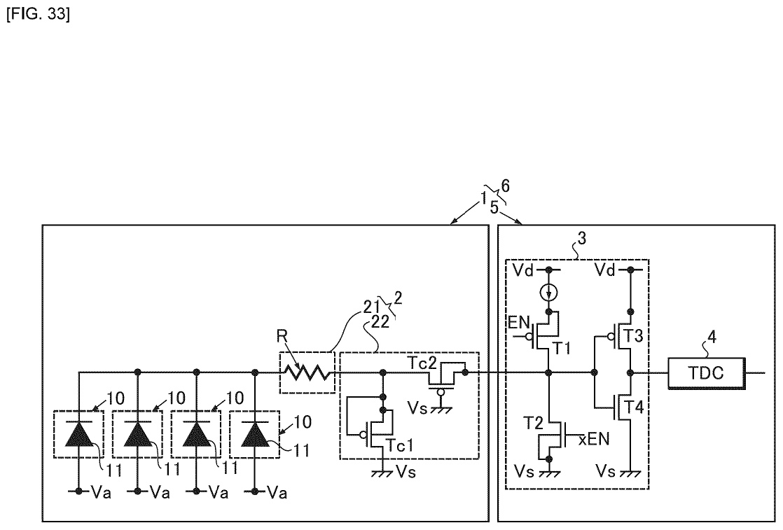

Description is given of the photodetector 1 and the distance measurement system 6 according to the 1-11th embodiment of the present disclosure with reference to FIGS. 33 to 35. The photodetector 1 and the distance measurement system 6 according to the 1-11th embodiment are an example in which the photodetector 1 and the distance measurement system 6 according to the 1-3rd embodiment are respectively combined with the photodetector 1 and the distance measurement system 6 according to the 1-9th embodiment.

### [1. Circuit Configurations of Photodetector 1 and Distance Measurement System 6]

FIG. 33 illustrates an example of circuit configurations of the photodetector 1 and the distance measurement system 6 according to the 1-11th embodiment.

As illustrated in FIG. 33, in the photodetector 1, one protective circuit 2 is provided for a plurality of pixels 10, as with the photodetector 1 according to the 1-9th embodiment. One readout circuit 3 and one time measurement circuit 4 are each provided for the protective circuit 2.

Four pixels 10 are provided as the plurality of pixels 10, as with the photodetector 1 according to the 1-9th embodiment.

The configurations of the first protective circuit 21, the second protective circuit 22, and the like are basically similar to those in the configurations of the photodetector 1 and the distance measurement system 6 according to the 1-3rd embodiment.

### [2. Device Configurations of Photodetector 1 and Distance Measurement System 6]

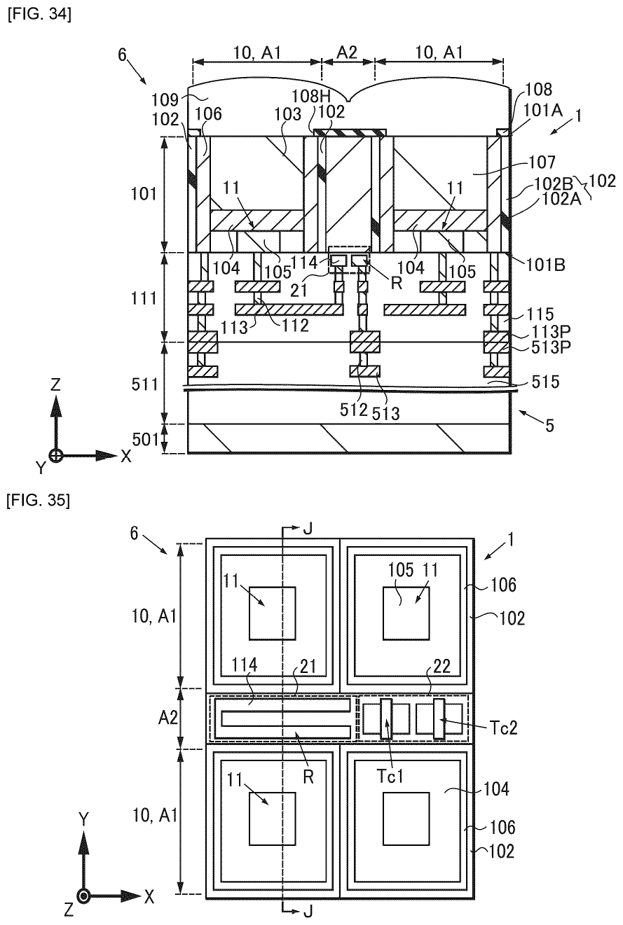

FIG. 34 illustrates an example of longitudinal cross-sectional configurations of a plurality of pixels 10 of the photodetector 1 illustrated in FIG. 33. FIG. 35 illustrates an example of planar configurations of the plurality of pixels 10 of the photodetector 1 illustrated in FIG. 34.

### (1) Configuration of Pixel 10

As illustrated in FIGS. 34 and 35, the pixel 10 is formed similarly to the pixel 10 of the photodetector 1 according to the 1-9th embodiment described above. That is, the pixel 10 is formed in a rectangular shape in a plan view.

Moreover, the second region A2 is provided between two pixels 10 adjacent in the arrow-X direction and two pixels 10 provided in the arrow-Y direction and being adjacent in the arrow-X direction.

### (2) Configuration of First Protective Circuit 21

The first protective circuit 21 is formed by the resistor element R, as with the first protective circuit 21 of the photodetector 1 according to the 1-1st embodiment. The resistor element R is provided in the second region A2, as with the photodetector 1 according to the 1-9th embodiment.

### (3) Configuration of Second Protective Circuit 22

The second protective circuit 22 includes the first clamp element Tel and the second clamp element Tc2. The first clamp element Tc1 and the second clamp element Tc2 are provided together with the resistor element R in the second region A2, as with the photodetector 1 according to the 1-3rd embodiment. The configurations of the first clamp element Tc1 and the second clamp element Tc2 are similar to the configurations of the first clamp element Tc1 and the second clamp element Tc2 of the photodetector 1 according to the 1-3rd embodiment, and description thereof is therefore omitted here.

Components other than the above-described components are the same or substantially the same as the components of the photodetector 1 and the distance measurement system 6 according to each of the 1-3rd embodiment and the 1-9th embodiment, and redundant descriptions are therefore omitted.

### [Workings and Effects]

As described above, in the photodetector 1 and the distance measurement system 6 according to the 1-11th embodiment, it is possible to obtain workings and effects including a combination of the workings and effects obtained by the photodetector 1 and the distance measurement system 6 according to the 1-3rd embodiment and the workings and effects obtained by the photodetector 1 and the distance measurement system 6 according to the 1-9th embodiment.

### 12. 1-12th Embodiment

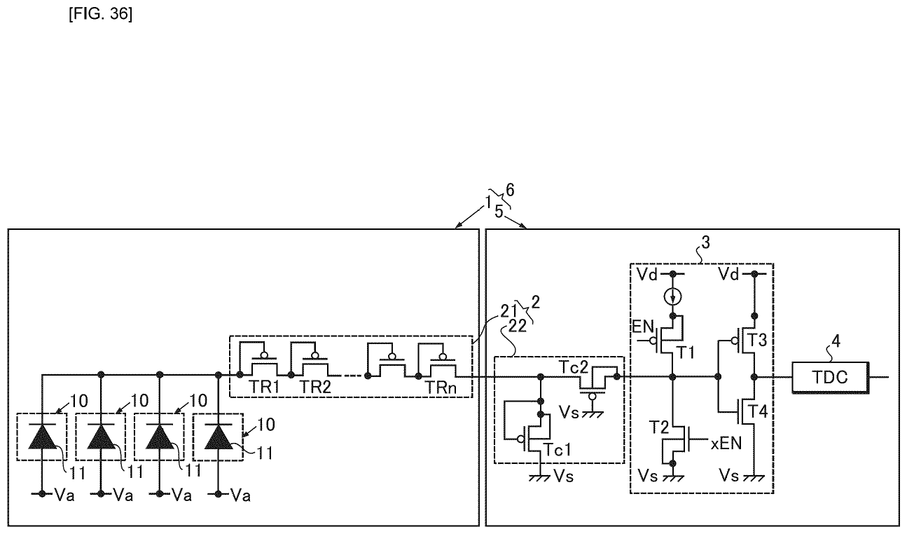

Description is given of the photodetector 1 and the distance measurement system 6 according to the 1-12th embodiment of the present disclosure with reference to FIGS. 36 to 38. The photodetector 1 and the distance measurement system 6 according to the 1-12th embodiment are an example in which the photodetector 1 and the distance measurement system 6 according to the 1-5th embodiment are respectively combined with the photodetector 1 and the distance measurement system 6 according to the 1-9th embodiment.

### [1. Circuit Configurations of Photodetector 1 and Distance Measurement System 6]

FIG. 36 illustrates an example of circuit configurations of the photodetector 1 and the distance measurement system 6 according to the 1-12th embodiment.

As illustrated in FIG. 36, in the photodetector 1, one first protective circuit 21 is provided for a plurality of pixels 10, as with the photodetector 1 according to the 1-9th embodiment. Four pixels 10 are provided as the plurality of pixels 10, as with the photodetector 1 according to the 1-9th embodiment.

The first protective circuit 21 includes a plurality of transistor resistor elements TR1 to TRn electrically coupled in series, as with the first protective circuit 21 of the photodetector 1 according to the 1-5th embodiment.

One readout circuit 3 and one time measurement circuit 4 are each provided for the first protective circuit 21 with one second protective circuit 22 interposed therebetween.

The configurations of the second protective circuit 22 and the like are basically similar to those in the configurations of the photodetector 1 and the distance measurement system 6 according to the 1-5th embodiment.

### [2. Device Configurations of Photodetector 1 and Distance Measurement System 6]

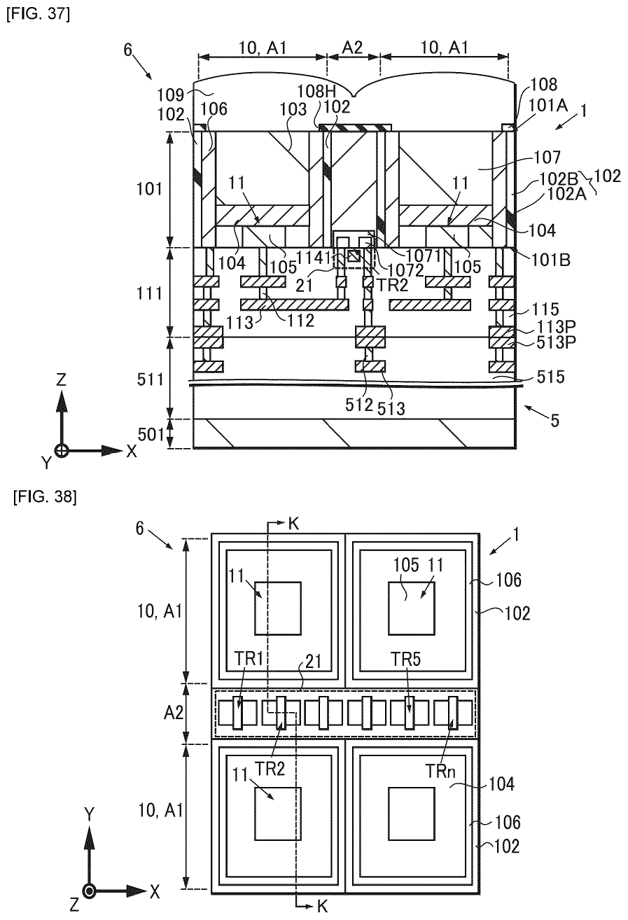

FIG. 37 illustrates an example of a longitudinal cross-sectional configuration of the plurality of pixels 10 of the photodetector 1 illustrated in FIG. 36. FIG. 38 illustrates an example of planar configurations of the plurality of pixels 10 of the photodetector 1 illustrated in FIG. 37.

### (1) Configuration of Pixel 10

As illustrated in FIGS. 37 and 38, the pixel 10 is formed similarly to the pixel 10 of the photodetector 1 according to the 1-9th embodiment described above. That is, the pixel 10 is formed in a rectangular shape in a plan view.

Moreover, the second region A2 is provided between two pixels 10 adjacent in the arrow-X direction and two pixels 10 provided in the arrow-Y direction and being adjacent in the arrow-X direction.

### (2) Configuration of First Protective Circuit 21

The first protective circuit 21 includes the plurality of transistor resistor elements TR1 to TRn, as with the first protective circuit 21 of the photodetector 1 according to the 1-5th embodiment. The transistor resistor element TR1 to the transistor resistor element TRn are provided in the second region A2, as with the photodetector 1 according to the 1-9th embodiment.

The configurations of the transistor resistor element TR1 to the transistor resistor element TRn are similar to the configurations of the transistor resistor element TR1 to the transistor resistor element TRn of the photodetector 1 according to the 1-5th embodiment, and description thereof is therefore omitted here.

Components other than the above-described components are the same or substantially the same as the components of the photodetector 1 and the distance measurement system 6 according to each of the 1-5th embodiment and the 1-9th embodiment, and redundant descriptions are therefore omitted.

### [Workings and Effects]

As described above, in the photodetector 1 and the distance measurement system 6 according to the 1-12th embodiment, it is possible to obtain workings and effects including a combination of the workings and effects obtained by the photodetector 1 and the distance measurement system 6 according to the 1-5th embodiment and the workings and effects obtained by the photodetector 1 and the distance measurement system 6 according to the 1-9th embodiment.

### 13. 1-13th Embodiment

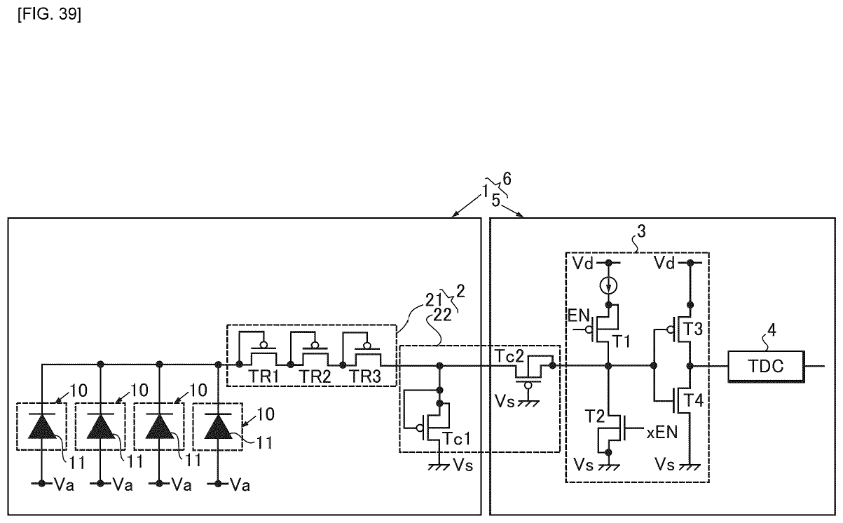

Description is given of the photodetector 1 and the distance measurement system 6 according to the 1-13th embodiment of the present disclosure with reference to FIGS. 39 to 41. The photodetector 1 and the distance measurement system 6 according to the 1-13th embodiment are an example in which the photodetector 1 and the distance measurement system 6 according to the 1-6th embodiment are respectively combined with the photodetector 1 and the distance measurement system 6 according to the 1-12th embodiment.

### [1. Circuit Configurations of Photodetector 1 and Distance Measurement System 6]

FIG. 39 illustrates an example of circuit configurations of the photodetector 1 and the distance measurement system 6 according to the 1-13th embodiment.

As illustrated in FIG. 39, in the photodetector 1, one first protective circuit 21 and a portion of the second protective circuit 22 are provided for a plurality of pixels 10, as with the photodetector 1 according to the 1-12th embodiment. One readout circuit 3 and one time measurement circuit 4 are each provided for the portion of the second protective circuit 22 with another portion of the second protective circuit 22 interposed therebetween.

Four pixels 10 are provided here as the plurality of pixels 10.

The first protective circuit 21 includes a plurality of transistor resistor elements TR1 to TRn electrically coupled in series, as with the first protective circuit 21 of the photodetector 1 according to the 1-12th embodiment. Here, the first protective circuit 21 includes three transistor resistor elements TR1 to TR3.

A portion of the second protective circuit 22 includes the first clamp element Tc1.

The configurations of the second protective circuit 22 and the like are basically similar to those in the configurations of the photodetector 1 and the distance measurement system 6 according to the 1-6th embodiment.

### [2. Device Configurations of Photodetector 1 and Distance Measurement System 6]

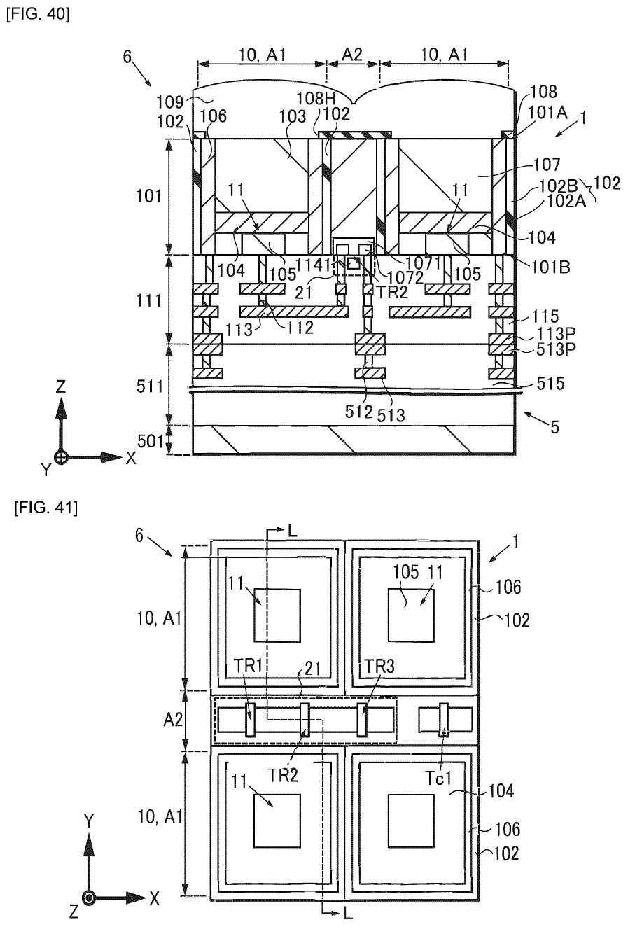

FIG. 40 illustrates an example of longitudinal cross-sectional configurations of a plurality of pixels 10 of the photodetector 1 illustrated in FIG. 39. FIG. 41 illustrates an example of planar configurations of the plurality of pixels 10 of the photodetector 1 illustrated in FIG. 40.

### (1) Configuration of Pixel 10

As illustrated in FIGS. 40 and 41, the pixel 10 is formed similarly to the pixel 10 of the photodetector 1 according to the 1-9th embodiment described above. That is, the pixel 10 is formed in a rectangular shape in a plan view.

Moreover, the second region A2 is provided between two pixels 10 adjacent in the arrow-X direction and two pixels 10 provided in the arrow-Y direction and being adjacent in the arrow-X direction.

### (2) Configuration of First Protective Circuit 21

The first protective circuit 21 includes the plurality of transistor resistor elements TR1 to TRn, as with the first protective circuit 21 of the photodetector 1 according to the 1-6th embodiment. The transistor resistor element TR1 to the transistor resistor element TRn are provided in the second region A2, as with the photodetector 1 according to the 1-12th embodiment.

The configurations of the transistor resistor element TR1 to the transistor resistor element TRn are similar to the configurations of the transistor resistor element TR1 to the transistor resistor element TRn of the photodetector 1 according to the 1-6th embodiment, and description thereof is therefore omitted here. (3) Configuration of Second Protective Circuit 22 The portion of the second protective circuit 22 includes the first clamp element Tc1. The first clamp element Tc1 is provided together with the plurality of transistor resistor elements TR1 to TRn in the second region A2. The configuration of the first clamp element Tc1 is similar to the configuration of the first clamp element Tc1 of the photodetector 1 according to the 1-6th embodiment, and description thereof is therefore omitted here.

Components other than the above-described components are the same or substantially the same as the components of the photodetector 1 and the distance measurement system 6 according to each of the 1-6th embodiment and the 1-12th embodiment, and redundant descriptions are therefore omitted.

### [Workings and Effects]

As described above, in the photodetector 1 and the distance measurement system 6 according to the 1-13th embodiment, it is possible to obtain workings and effects including a combination of the workings and effects obtained by the photodetector 1 and the distance measurement system 6 according to the 1-6th embodiment and the workings and effects obtained by the photodetector 1 and the distance measurement system 6 according to the 1-12th embodiment.

### 14. 1-14th Embodiment

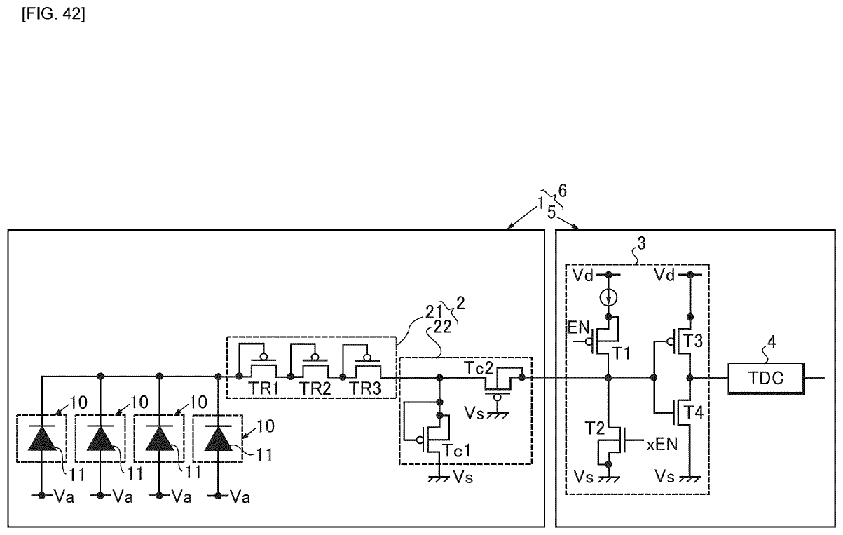

Description is given of the photodetector 1 and the distance measurement system 6 according to the 1-14th embodiment of the present disclosure with reference to FIGS. 42 to 44. The photodetector 1 and the distance measurement system 6 according to the 1-14th embodiment are an example in which the photodetector 1 and the distance measurement system 6 according to the 1-7th embodiment are respectively combined with the photodetector 1 and the distance measurement system 6 according to the 1-12th embodiment.

### [1. Circuit Configurations of Photodetector 1 and Distance Measurement System 6]

FIG. 42 illustrates an example of circuit configurations of the photodetector 1 and the distance measurement system 6 according to the 1-14th embodiment.

As illustrated in FIG. 42, in the photodetector 1, one first protective circuit 21 and one second protective circuit 22 are provided for a plurality of pixels 10, as with the photodetector 1 according to the 1-12th embodiment. One readout circuit 3 and one time measurement circuit 4 are each provided for the one second protective circuit 22.

Four pixels 10 are provided here as the plurality of pixels 10.

The first protective circuit 21 includes a plurality of transistor resistor elements TR1 to TRn electrically coupled in series, as with the first protective circuit 21 of the photodetector 1 according to the 1-12th embodiment. Here, the first protective circuit 21 includes three transistor resistor elements TR1 to TR3.

The second protective circuit 22 includes the first clamp element Tel and the second clamp element Tc2.

The configurations of the readout circuit 3 and the like are basically similar to those in the configurations of the photodetector 1 and the distance measurement system 6 according to the 1-7th embodiment.

### [2. Device Configurations of Photodetector 1 and Distance Measurement System 6]

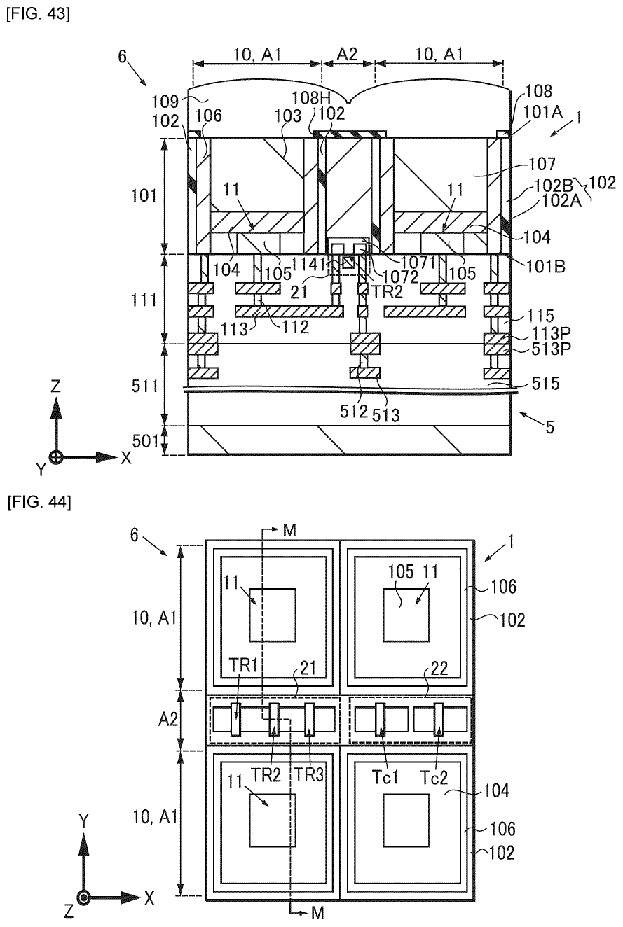

FIG. 43 illustrates an example of longitudinal cross-sectional configurations of the plurality of pixels 10 of the photodetector 1 illustrated in FIG. 42. FIG. 44 illustrates an example of planar configurations of the plurality of pixels 10 of the photodetector 1 illustrated in FIG. 43.

### (1) Configuration of Pixel 10

As illustrated in FIGS. 43 and 44, the pixel 10 is formed similarly to the pixel 10 of the photodetector 1 according to the 1-12th embodiment described above. That is, the pixel 10 is formed in a rectangular shape in a plan view.

Moreover, the second region A2 is provided between two pixels 10 adjacent in the arrow-X direction and two pixels 10 provided in the arrow-Y direction and being adjacent in the arrow-X direction.

### (2) Configuration of First Protective Circuit 21

The first protective circuit 21 includes the plurality of transistor resistor elements TR1 to TRn, as with the first protective circuit 21 of the photodetector 1 according to the 1-7th embodiment. The transistor resistor element TR1 to the transistor resistor element TRn are provided in the second region A2, as with the photodetector 1 according to the 1-12th embodiment. The configurations of the transistor resistor element TR1 to the transistor resistor element TRn are similar to the configurations of the transistor resistor element TR1 to the transistor resistor element TRn of the photodetector 1 according to the 1-7th embodiment, and description thereof is therefore omitted here.

### (3) Configuration of Second Protective Circuit 22

The second protective circuit 22 includes the first clamp element Tel and the second clamp element Tc2. The first clamp element Tc1 and the second clamp element Tc2 are provided together with the plurality of transistor resistor elements TR1 to TRn in the second region A2. The configurations of the first clamp element Tc1 and the second clamp element Tc2 are similar to the configurations of the first clamp element Tc1 and the second clamp element Tc2 of the photodetector 1 according to the 1-7th embodiment, and description thereof is therefore omitted here.

Components other than the above-described components are the same or substantially the same as the components of the photodetector 1 and the distance measurement system 6 according to each of the 1-7th embodiment and the 1-12th embodiment, and redundant descriptions are therefore omitted.

[workings and Effects]

As described above, in the photodetector 1 and the distance measurement system 6 according to the 1-14th embodiment, it is possible to obtain workings and effects including a combination of the workings and effects obtained by the photodetector 1 and the distance measurement system 6 according to the 1-7th embodiment and the workings and effects obtained by the photodetector 1 and the distance measurement system 6 according to the 1-12th embodiment.

### 15. 1-15th Embodiment

Description is given of the photodetector 1 and the distance measurement system 6 according to the 1-15th embodiment of the present disclosure with reference to FIG. 45. The photodetector 1 and the distance measurement system 6 according to the 1-15th embodiment are an example in which the planar shape of each of the first region A1 and the second region A2 is changed in the photodetector 1 and the distance measurement system 6 according to the 1-1st embodiment.

### [Device Configurations of Photodetector 1 and Distance Measurement System 6]

FIG. 45 illustrates an example of planar configurations of a plurality of pixels 10 of the photodetector 1 according to the 1-15th embodiment.

As illustrated in FIG. 45, the planar shape of each of the first region A1 and the second region A2 of the photodetector 1 is formed in a hexagonal shape or a regular hexagonal shape in a plan view. Accordingly, as illustrated schematically, the planar shape of the pixel 10 and the planar shape of the first protective circuit 21 of the protective circuit 2 are respectively formed in a shape similar to the planar shape of the first region A1 and a shape similar to the planar shape of the second region A2.

The pixel 10 and the first protective circuit 21 are arranged alternately in the arrow-X direction. Relative to the pixel 10 and the first protective circuit 21, another pixel 10 and another first protective circuit 21 adjacent in the arrow-Y direction are arranged alternately in the arrow X direction similarly, and are provided to be shifted by a length equal to half a length of one pixel 10. In other words, the pixels 10 and the first protective circuits 21 are arranged in a honeycomb pattern.

It is to be noted that, here, the planar area of the first region A1 is the same as the planar area of the second region A2.

Components other than the above-described components are the same or substantially the same as the components of the photodetector 1 and the distance measurement system 6 according to the 1-1st embodiment, and redundant descriptions are therefore omitted.

### [Workings and Effects]

As described above, in the photodetector 1 and the distance measurement system 6 according to the 1-15th embodiment, it is possible to obtain workings and effects similar to the workings and effects obtained by the photodetector 1 and the distance measurement system 6 according to the 1-1st embodiment.

In addition, in the photodetector 1, as illustrated in FIG. 45, the planar shape of each of the first region A1 and the second region A2 is formed in a hexagonal shape or a regular hexagonal shape, which makes it possible to dispose the pixels 10 and the first protective circuits 21 without gaps. This makes it possible to improve packing efficiency of the pixels 10 and the first protective circuits 21.

### 16. 1-16th Embodiment

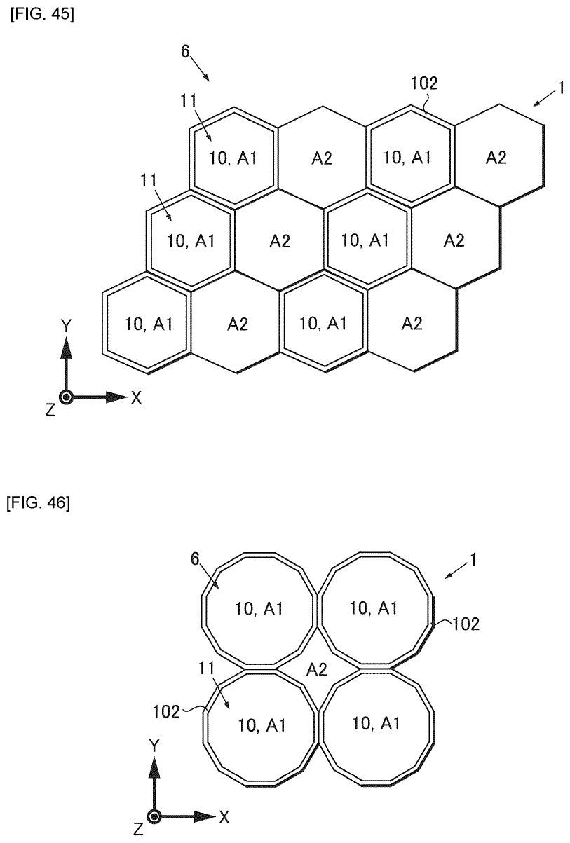

Description is given of the photodetector 1 and the distance measurement system 6 according to the 1-16th embodiment of the present disclosure with reference to FIG. 46. The photodetector 1 and the distance measurement system 6 according to the 1-16th embodiment are an example, in which the planar shape of each of the first region A1 and the second region A2 is changed in the photodetector 1 and the distance measurement system 6 according to the 1-1st embodiment.

### [Device Configurations of Photodetector 1 and Distance Measurement System 6]

FIG. 46 illustrates an example of planar configuration of a plurality of pixels 10 of the photodetector 1 according to the 1-16th embodiment.

As illustrated in FIG. 46, the planar shape of each of the first regions A1 of the photodetector 1 is formed in a dodecagonal shape or a regular dodecagonal shape in a plan view. Accordingly, as illustrated schematically, the planar shape of the pixel 10 is formed in a shape similar to the planar shape of the first region A1.

In addition, here, the second region A2 is formed to be surrounded by four first regions A1. The first protective circuit 21 is provided in the second region A2.

Components other than the above-described components are the same or substantially the same as the components of the photodetector 1 and the distance measurement system 6 according to the 1-1st embodiment, and redundant descriptions are therefore omitted.

### [Workings and Effects]

As described above, in the photodetector 1 and the distance measurement system 6 according to the 1-16th embodiment, it is possible to obtain workings and effects similar to the workings and effects obtained by the photodetector 1 and the distance measurement system 6 according to the 1-1st embodiment.

It is to be noted that in the present disclosure, the photodetectors 1 and the distance measurement systems 6 according to two or more embodiments, among the photodetectors 1 and the distance measurement systems 6 according to the 1-1st embodiment to the 1-16th embodiment described above, may be combined as appropriate.

### 17. 2-1st Embodiment

The photodetector 1 and the distance measurement system 6 according to the 2-1st embodiment of the present disclosure adopt a plurality of distance measurement methods, and enable distance measurement. Here, two measurement methods are adopted.

One of the distance measurement methods is a direct time of flight (dToF: direct Time of Flight) method. In the dToF method, resolution is low and power consumption is high, but the dToF method is suitable for measuring a long distance. Another distance measurement method is an indirect time of flight (iToF: indirect Time of Flight) method. In the iToF method, resolution is high and power consumption is low. The iToF method is suitable for measuring a short distance.

In the photodetector 1 and the distance measurement system 6 according to the 2-1st embodiment, the dToF method is implemented by the photodetector 1 and the distance measurement system 6 according to any of the 1-1st embodiment to the 1-16th embodiment described above. That is, distance measurement adopting the dToF method is implementable by including the pixel 10 that includes the SPAD 11, the readout circuit 3, and the time-measurement circuit 4.

Thus, in the 2-1st embodiment, description is given mainly of components that make it possible to implement distance measurement adopting the iToF method.

### [1. Circuit Configurations of Photodetector 1 and Distance Measurement System 6]

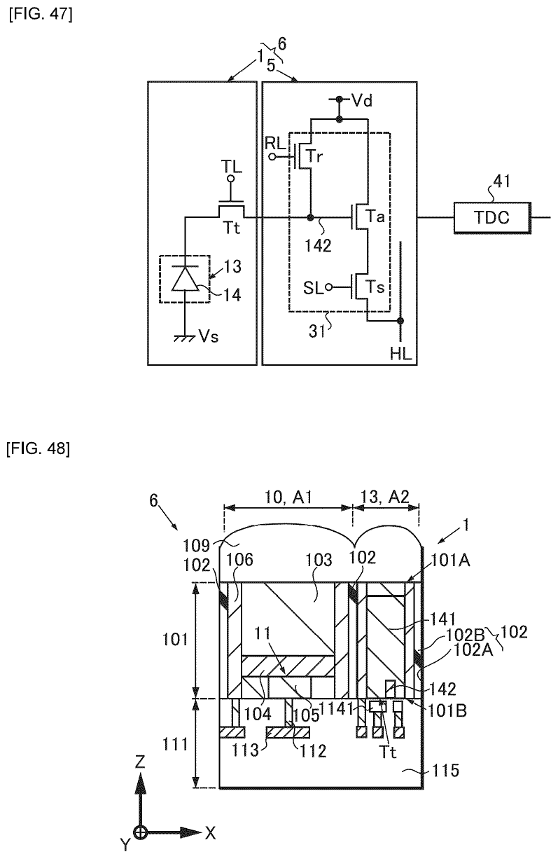

FIG. 47 illustrates an example of a circuit configuration of one pixel 13 in the photodetector 1 and the distance measurement system 6 according to the 2-1st embodiment.

### (1) Circuit Configuration of Photodetector 1

Here, the photodetector 1 includes the pixel 13 including a photodiode (PD: Photo Diode) 14 as a light-receiving element. FIG. 47 illustrates one pixel 13. In actuality, in the photodetector 1, a plurality of pixels 13 is arranged.

The PD 14 converts incident light into electric charge. An anode electrode of the PD 14 is electrically coupled to the reference power supply Vs. A cathode electrode of the PD 14 is electrically coupled to a readout circuit 31 via a transfer transistor Tt.

The transfer transistor Tt includes, for example, an n-type IGFET. One of a pair of main electrodes of the transfer transistor Tt is coupled to the cathode electrode of the PD 14, and another main electrode of the transfer transistor Tt is electrically coupled to the readout circuit 31 via a floating diffusion. A gate electrode of the transfer transistor Tt is electrically coupled to a transfer signal line TL.

The transfer transistor Tt here is mounted on the photodetector 1.

### (2) Circuit Configuration of Circuit Device 5

The circuit device 5 includes the readout circuit (a pixel circuit) 31 and a time measurement circuit 41. The readout circuit 31 and the time measurement circuit 41 are included together with, for example, the readout circuit 3 and the time measurement circuit 4 (that are not illustrated) in the photodetector 1 and the distance measurement system 6 according to the 1-1st embodiment described above.

The readout circuit 3 includes an amplification transistor Ta, a selection transistor Ts, and a reset transistor Tr. Here, these transistors including the amplification transistors Ta that construct the readout circuit 3 each include an n-type IGFET.

One of a pair of main electrodes of the amplification transistor Ta is electrically coupled to the operating power supply Vd. Another main electrode of the amplification transistor Ta is electrically coupled to one of a pair of main electrodes of the selection transistor Ts. A gate electrode of the amplification transistor Ta is electrically coupled to the other main electrode of the transfer transistor Tt via the floating diffusion.

Another main electrode of the selection transistor Ts is electrically coupled to a vertical signal line HL. A gate electrode of the selection transistor Ts is electrically coupled to a selection signal line SL.

One of a pair of main electrodes of the reset transistor Tr is electrically coupled to the floating diffusion. Another main electrode of the reset transistor Tr is electrically coupled to the operating power supply Vd. A gate electrode of the reset transistor Tr is electrically coupled to a reset signal line RL.

The time measurement circuit 41 is electrically coupled to the readout circuit 31.

### [2. Device Configurations of Photodetector 1 and Distance Measurement System 6]

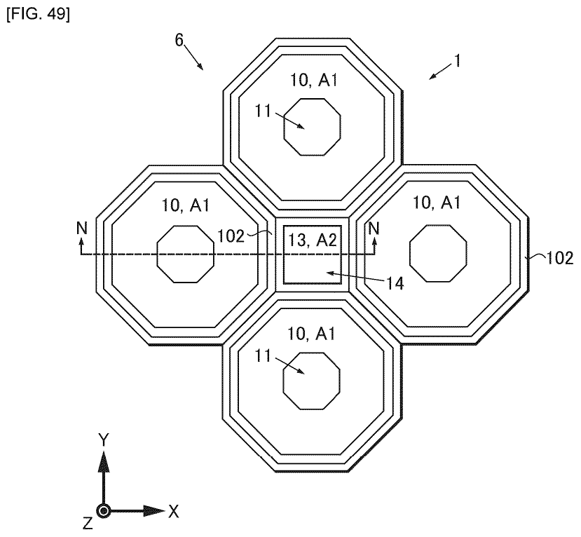

FIG. 48 illustrates an example of longitudinal cross-sectional configurations of a plurality of pixels 10 and the pixel 13 in the photodetector 1 illustrated in FIG. 47. FIG. 48 also illustrates an example of a longitudinal cross-sectional configuration of a portion of the circuit device 5 of the distance measurement system 6. FIG. 49 illustrates an example of planar configurations of the pixel 10 and the pixel 13 in the photodetector 1 illustrated in FIG. 48.

### (1) Device Configuration of Pixel 10 of Photodetector 1

As illustrated in FIGS. 48 and 49, the photodetector 1 includes the pixel 10 for implementing the dToF method, and the pixel 13 for implementing the iToF method.

The pixel 10 is provided in the first region A1 of the first base 101, for example, as with the pixel 10 of the photodetector 1 according to the 1-1st embodiment described above. The pixel 10 is provided to be surrounded by the insulating isolator 102. Moreover, the pixel 10 includes the SPAD 11.

The planar shape of the pixel 10 is formed in a polygonal shape, in this case, in an octagonal shape or a regular octagonal shape. Moreover, relative to one pixel 10, another pixel 10 adjacent in the arrow-X direction is provided with the second region A2 interposed therebetween. In addition, relative to the one pixel 10, another pixel 10 adjacent in the arrow-Y direction is provided with the second region A2 interposed therebetween. That is, the second region A2 is surrounded by four pixels 10, and is provided on the pixels 10 with the insulating isolator 102 interposed therebetween.

### (2) Device Configuration of Pixel 13 of Photodetector 1

The pixel 13 is provided in the second region A2 of the first base 101. The pixel 10 is surrounded by the insulating isolator 102; therefore, the second region A2 is at least electrically isolated from the first region A1 by the insulating isolator 102. Moreover, the pixel 13 includes the PD 14. The PD 14 is formed to include an n-type semiconductor region 141 provided in the first base 101.

Here, a planar shape of the pixel 13 is formed in a quadrilateral shape or a square shape.

In addition, the n-type semiconductor region 141 of the PD 14 is shared as one main electrode with the transfer transistor Tt. The other main electrode of the transfer transistor Tt is electrically coupled to a floating diffusion 142. A gate electrode 1141 of the transfer transistor Tt is formed in the wiring layer 111.

Components other than the above-described components are the same or substantially the same as the components of the photodetector 1 and the distance measurement system 6 according to the 1-1st embodiment, and redundant descriptions are therefore omitted.

### [Workings and Effects]

As described above, as illustrated in FIGS. 47 to 49, the photodetector 1 and the distance measurement system 6 according to the 2-1st embodiment include the SPAD 11, the light-receiving element, and the insulating isolator 102.

The SPAD 11 is provided in the first region A1 of the first base 101, and amplifies a carrier generated by an incident photon. The light-receiving element is the PD 14. The PD 14 is provided in the second region A2 adjacent to the first region A1 of the first base 101 in the plane direction of the first base 101. The PD 14 converts incident light into electric charge.

Moreover, the insulating isolator 102 is provided between the first region A1 and the second region A2, and at least electrically isolates the SPAD 11 and the PD 14 from each other. That is, the insulating isolator 102 electrically isolates the pixel 10 and the pixel 13 from each other.

In the photodetector 1 having such a configuration, the insulating isolator 102 is provided between the SPAD 11 and the PD 14, which makes it possible for the PD 14 to effectively reduce or prevent the influence of the electrical field effect from the SPAD 11. Accordingly, it is possible to provide the pixel 10 including the SPAD 11 and the pixel 13 including the PD 14 in the same first base 101.

Thus, in the distance measurement system 6, it is possible to implement both the distance measurement adopting the dToF method and the distance measurement adopting the iToF method.

Moreover, in the photodetector 1 and the distance measurement system 6 according to the 2-1st embodiment, it is possible to obtain workings and effects similar to the workings and effects obtained by, for example, the photodetector 1 and the distance measurement system 6 according to the 1-1st embodiment described above.

### 18. 2-2nd Embodiment

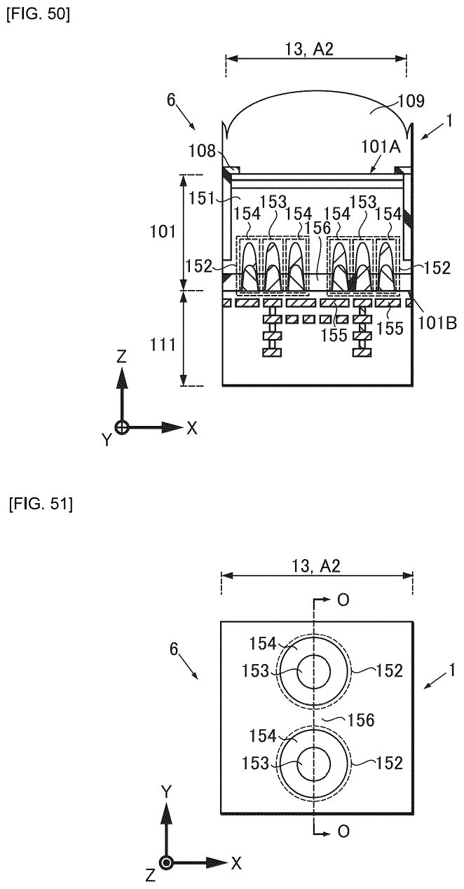

Description is given of the photodetector 1 and the distance measurement system 6 according to the 2-2nd embodiment of the present disclosure with reference to FIGS. 50 and 51. The photodetector 1 and the distance measurement system 6 according to the 2-2nd embodiment are an example in which the configuration of a light-receiving element 14 of the pixel 13 that implements the distance measurement adopting the iToF method is changed in the photodetector 1 and the distance measurement system 6 according to the 2-1st embodiment.

Here, a current assisted photonic demodulator (CAPD: Current Assisted Photonic Demodulator) method is used in which a voltage is applied directly to the first base 101 to generate a current in the first base 101, and a wide range inside the first base 101 is modulatable at high speed.

### [Device Configuration of Photodetector 1]

FIG. 50 illustrates an example of a longitudinal cross-sectional configuration of the pixel 13 of the photodetector 1 according to the 2-2nd embodiment. FIG. 51 illustrates an example of a planar configuration of the pixel 13.

The pixel 10 of the photodetector 1 includes the PD 14 as the light-receiving element. The PD 14 is provided in the second region A2. The PD 14 is formed in the p-type semiconductor region 151 provided in the first base 101. A pair of signal extractors 152 is provided on the side of the second surface 101B of the p-type semiconductor region 151 with an insulator 156 interposed therebetween. The signal extractors 152 each include a voltage applied section 153, and a charge detector 154.

Here, the insulator 156 includes, for example, SiO₂. In addition, the insulator 156 may also serve as a p-n junction separator.

The voltage applied section 153 is formed by sequentially providing a p-type semiconductor region with no reference numeral having a high impurity density and a p-type semiconductor region with no reference numeral having a low impurity density in the arrow-Y direction. The voltage applied section 153 distributes electric charge converted from light.

The charge detector 154 is provided around the voltage applied section 153. The charge detector 154 is formed by sequentially providing an n-type semiconductor region with no reference numeral having a high impurity density and an n-type semiconductor region with no reference numeral having a low impurity density in the arrow-Y direction. The charge detector 154 detects the electric charge distributed by the voltage applied section 153.

In addition, in the wiring layer 111, a reflection layer 155 is provided in a region corresponding to the charge detector 154. The reflection layer 155 reflects light having leaked from the PD 14 toward the PD 14. Including the reflection layer 155 makes it possible to increase an optical path length of light having a long wavelength such as infrared light, for example. As a result, it is possible to improve light-receiving sensitivity (quantum efficiency) Qe.

Components other than the above-described components are the same or substantially the same as the components of the photodetector 1 and the distance measurement system 6 according to the 2-1st embodiment, and redundant descriptions are therefore omitted.

### [Workings and Effects]

As described above, in the photodetector 1 and the distance measurement system 6 according to the 2-2nd embodiment, it is possible to obtain workings and effects similar to the workings and effects obtained by the photodetector 1 and the distance measurement system 6 according to the 2-1st embodiment.

In addition, as illustrated in FIG. 50 and FIG. 51, the photodetector 1 includes the voltage applied section 153 that distributes the electric charge converted from light, and the charge detector 154 that detects the distributed electric charge. This makes it possible to provide the photodetector 1 and the distance measurement system 6 that make it possible to implement the CAPD method.

### 19. 2-3rd Embodiment

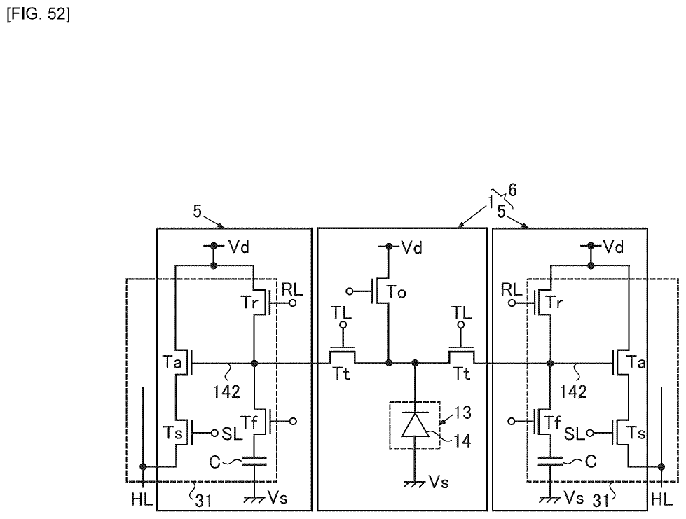

Description is given of the photodetector 1 and the distance measurement system 6 according to the 2-3rd embodiment of the present disclosure with reference to FIGS. 52 to 54. The photodetector 1 and the distance measurement system 6 according to the 2-3rd embodiment are an example in which the configuration of the light-receiving element 14 of the pixel 13 for implementing the distance measurement adopting the iToF method is changed in the photodetector 1 and the distance measurement system 6 according to the 2-1st embodiment.

Here, a gate (Gate) method is used.

### [1. Circuit Configurations of Photodetector 1 and Distance Measurement System 6]

FIG. 52 illustrates an example of circuit configurations of the pixel 13 and the readout circuit (the pixel circuit) 31 in the photodetector 1 and the distance measurement system 6 according to the 2-3rd embodiment.

In the photodetector 1 and the distance measurement system 6 according to the 2-3rd embodiment, the pixel 13 includes the FD 14 as the light-receiving element, as with the photodetector 1 and the distance measurement system 6 according to the 2-1st embodiment. A pair of readout circuits (pixel circuits) 31 is electrically coupled to the FD 14.

Each of the readout circuits 31 includes the amplification transistor Ta, the selection transistor Ts, and the reset transistor Tr, and further includes a floating diffusion switching transistor (hereinafter simply referred to as a “switching transistor”) Tf.

One of a pair of main electrodes of the switching transistor Tf is electrically coupled to the floating diffusion 142. Another main electrode of the switching transistor Tf is electrically coupled to the reference power supply Vs with a capacitor C interposed therebetween. A gate electrode of the switching transistor Tf is electrically coupled to a switching signal line.

In addition, one of a pair of main electrodes of a charge drain transistor To is electrically coupled to the floating diffusion 142. Another main electrode of the charge drain transistor To is electrically coupled to the operating power supply Vd. A gate electrode of the charge drain transistor To is electrically coupled to a charge drain signal line.

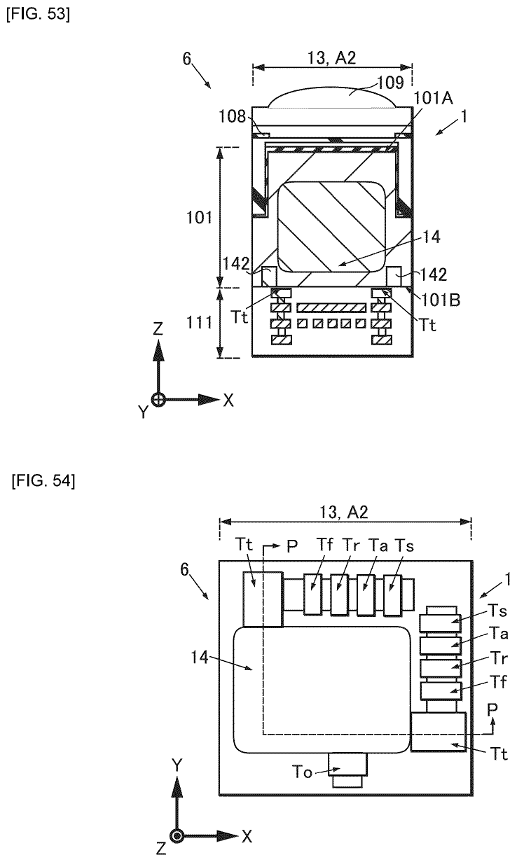

### [2. Device Configurations of Photodetector 1 and Distance Measurement System 6]

[pixel 10] FIG. 53 illustrates an example of a longitudinal cross-sectional configuration of the pixel 13 in the photodetector 1. FIG. 54 illustrates an example of a planar configuration of the pixel 13.

The pixel 10 of the photodetector 1 includes the PD 14 as the light-receiving element. The PD 14 is provided in the second region A2. The PD 14 is configured to include a p-type semiconductor region with no reference numeral and an n-type semiconductor region with no reference numeral that are provided in the first base 101.

The transfer transistor Tt is provided on the side of the second surface 101B of the first base 101. The transfer transistor Tt distributes electric charge that is generated from light by the PD 14.

In addition, the reflection layer 155 is provided in a region corresponding to the PD 14 in the wiring layer 111. The reflection layer 155 reflects light having leaked from the PD 14 toward the PD 14.

In addition, a wiring 157 that constitutes the capacitor C is provided in the wiring layer 111.

Components other than the above-described components are the same or substantially the same as the components of the photodetector 1 and the distance measurement system 6 according to the 2-1st embodiment or the 2-2nd embodiment, and redundant descriptions are therefore omitted.

### [Workings and Effects]

As described above, in the photodetector 1 and the distance measurement system 6 according to the 2-3rd embodiment, it is possible to obtain workings and effects similar to the workings and effects obtained by the photodetector 1 and the distance measurement system 6 according to the 2-1st embodiment or the 2-2nd embodiment.

### 20. 2-4th Embodiment

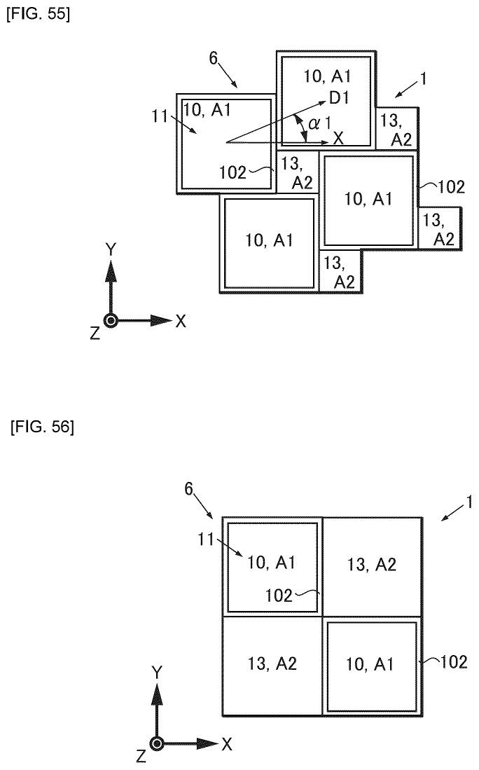

Description is given of the photodetector 1 and the distance measurement system 6 according to the 2-4th embodiment of the present disclosure with reference to FIG. 55. The photodetectors 1 and the distance measurement systems 6 according to the 2-4th embodiment to 2-7th embodiment are each an example in which the respective planar shapes and the respective arrangement shapes of the pixel 10 and the pixel 13 are changed.

### [Device Configurations of Photodetector 1 and Distance Measurement System 6]

FIG. 55 illustrates an example of planar configurations of the pixel 10 and the pixel 13 in the photodetector 1 according to the 2-4th embodiment.

### (1) Configuration of Pixel 10

As illustrated in FIG. 55, the planar shape of the pixel 10 is formed in a rectangular shape that is a polygonal shape, as with the photodetector 1 according to the 1-8th embodiment. Here, the planar shape of the pixel 10 is formed in a quadrilateral shape or a square shape. The pixel 10 is provided in the first region A1.

A plurality of pixels 10 is arranged in the arrow-X direction and the arrow-Y direction. To describe this in detail, relative to one pixel 10, another pixel 10 adjacent in the arrow-X direction is provided to be shifted in the arrow-Y direction by a length less than or equal to about half the length of one side of the pixel 10. In other words, the pixels 10 are arranged in the oblique direction D1 relative to the arrow-X direction at the predetermined angle al on the side of the arrow-Y direction.

### (2) Configuration of Pixel 13

The pixel 13 is provided in the second region A2. The second region A2 is surrounded by a total of four first regions A1 including two first regions A1 provided adjacent in the arrow-X direction and two first regions A1 provided adjacent in the arrow-X direction and adjacent in the arrow-Y direction. The second region A2 has four sides each having a length less than or equal to about half the length of one side of a corresponding one of the four first regions A1 in a plan view. That is, the planar shape of the second region A2 is formed in a rectangular shape, in this case, in a quadrilateral shape or a square shape.

Components other than the above-described components are the same or substantially the same as the components of the photodetector 1 and the distance measurement system 6 according to each of the 2-1st embodiment to the 2-3rd embodiment, and redundant descriptions are therefore omitted.

### [Workings and Effects]

As described above, in the photodetector 1 and the distance measurement system 6 according to the 2-4th embodiment, it is possible to obtain workings and effects similar to the workings and effects obtained by the photodetector 1 and the distance measurement system 6 according to any of the 2-1st embodiment to the 2-3rd embodiment.

### 21. 2-5th Embodiment

Description is given of the photodetector 1 and the distance measurement system 6 according to the 2-5th embodiment of the present disclosure with reference to FIG. 56.

### [Device Configurations of Photodetector 1 and Distance Measurement System 6]

FIG. 56 illustrates an example of planar configurations of the pixel 10 and the pixel 13 in the photodetector 1 according to the 2-5th embodiment.

As illustrated in FIG. 56, in the photodetector 1, the pixel 10 and the pixel 13 are formed in the same rectangular shape with the same planar area. A specific planar shape of each of the pixel 10 and the pixel 13 is formed in a quadrilateral shape or a square shape.

The pixel 10 and the pixel 13 are arranged alternately in the arrow-X direction. In addition, relative to the pixel 10 and the pixel 13, the pixel 10 and the pixel 13 adjacent in the arrow-Y direction are arranged alternately in the arrow X direction, and are provided to be shifted by a length equal to the length of one pixel 10.

Components other than the above-described components are the same or substantially the same as the components of the photodetector 1 and the distance measurement system 6 according to each of the 2-1st embodiment to the 2-3rd embodiment, and redundant descriptions are therefore omitted.

### [Workings and Effects]

As described above, in the photodetector 1 and the distance measurement system 6 according to the 2-5th embodiment, it is possible to obtain workings and effects similar to the workings and effects obtained by the photodetector 1 and the distance measurement system 6 according to any of the 2-1st embodiment to the 2-3rd embodiment.

### 22. 2-6th Embodiment

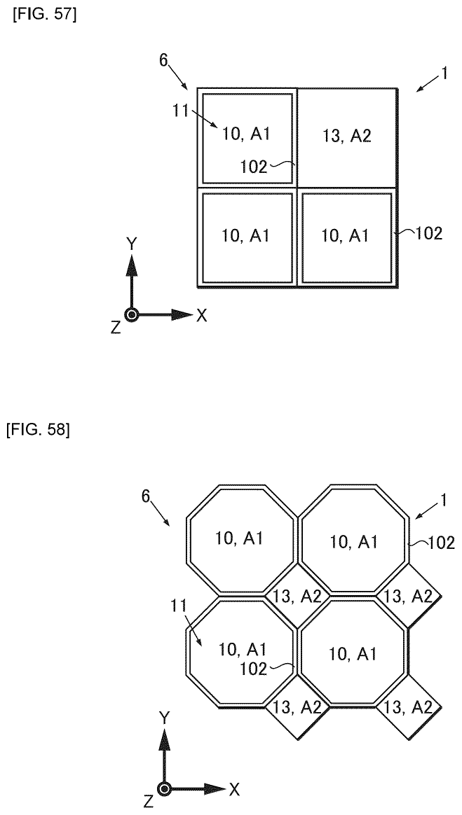

Description is given of the photodetector 1 and the distance measurement system 6 according to the 2-6th embodiment of the present disclosure with reference to FIG. 57.

### [Device Configurations of Photodetector 1 and Distance Measurement System 6]

FIG. 57 illustrates an example of planar configurations of the pixel 10 and the pixel 13 in the photodetector 1 according to the 2-6th embodiment.

As illustrated in FIG. 57, the pixel 10 and the pixel 13 in the photodetector 1 are formed in the same rectangular shape with the same planar area, as with the photodetector 1 according to the 2-5th embodiment.

Two pixels 10 are provided adjacent in the arrow-X direction. In addition, one pixel 10 is provided adjacent in the arrow-Y direction to one pixel 10 of the two pixels 10. Moreover, one pixel 13 is provided adjacent in the arrow-Y direction to another pixel 10 of the two pixels 10.

In other words, one pixel 13 is provided for three pixels 10, and they construct a unit pixel.

Components other than the above-described components are the same or substantially the same as the components of the photodetector 1 and the distance measurement system 6 according to each of the 2-1st embodiment to the 2-3rd embodiment, and redundant descriptions are therefore omitted.

### [Workings and Effects]

As described above, in the photodetector 1 and the distance measurement system 6 according to the 2-6th embodiment, it is possible to obtain workings and effects similar to the workings and effects obtained by the photodetector 1 and the distance measurement system 6 according to any of the 2-1st embodiment to the 2-3rd embodiment.

### 23. 2-7th Embodiment

Description is given of the photodetector 1 and the distance measurement system 6 according to the 2-7th embodiment of the present disclosure with reference to FIG. 58.

### [Device Configurations of Photodetector 1 and Distance Measurement System 6]

FIG. 58 illustrates an example of planar configurations of the pixel 10 and the pixel 13 in the photodetector 1 according to the 2-7th embodiment.

As illustrated in FIG. 58, the planar shape of the pixel 10 of the photodetector 1 is formed in a polygonal shape, as with the photodetector 1 according to the 1-1st embodiment. Specifically, the planar shape of the pixel 10 is formed in an octagonal shape or a regular octagonal shape. The planar shape of the first region A1 is the same as the planar shape of the pixel 10.

The pixels 10 are provided adjacent in each of the arrow-X direction and the arrow-Y direction.

The pixel 13 is provided in the second region A2. The second region A2 is surrounded by a total of four first regions A1 including two first regions A1 provided adjacent in the arrow-X direction and two first regions A1 provided adjacent in the arrow-X direction and adjacent in the arrow-Y direction. The planar shape of the second region A2 corresponds to a length of one side of each of the four first regions A1, and is formed in a quadrilateral shape or a square shape in a plan view.

Components other than the above-described components are the same or substantially the same as the components of the photodetector 1 and the distance measurement system 6 according to each of the 2-1st embodiment to the 2-3rd embodiment, and redundant descriptions are therefore omitted.

### [Workings and Effects]

As described above, in the photodetector 1 and the distance measurement system 6 according to the 2-7th embodiment, it is possible to obtain workings and effects similar to the workings and effects obtained by the photodetector 1 and the distance measurement system 6 according to any of the 2-1st embodiment to the 2-3rd embodiment.

### 24. 3-1st Embodiment

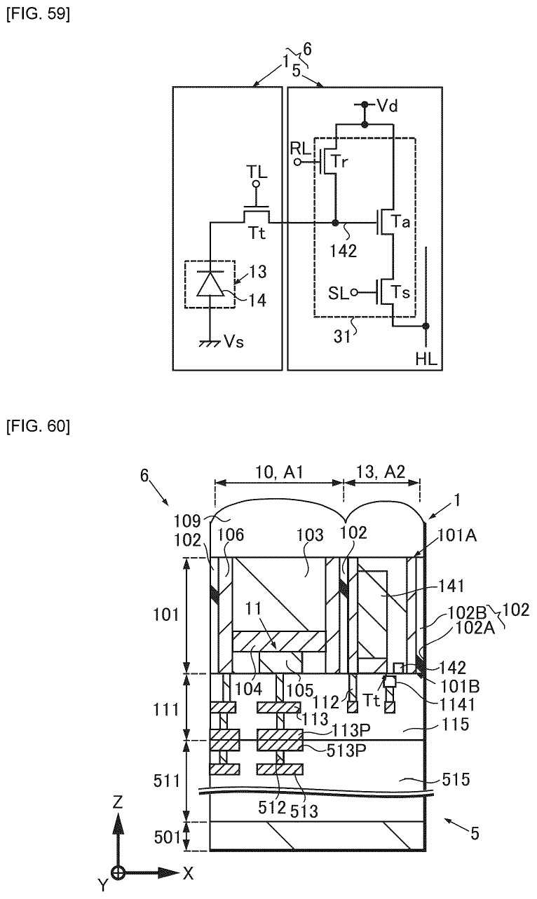

Description is given of the photodetector 1 and the distance measurement system 6 according to the 3-1st embodiment of the present disclosure with reference to FIGS. 59 to 70. The photodetector 1 and the distance measurement system 6 according to the 3-1st embodiment is an application example of the photodetector 1 and the distance measurement system 6 according to the 2-1st embodiment.

The SPAD 11 is an element that reacts to one photon. The SPAD 11 therefore has extremely high sensitivity. Over a complementary metal-oxide-semiconductor image sensor (CIS: Complementary Metal Oxide Semiconductor Image Sensor), the SPAD 11 is advantageous at low illumination, but is less advantageous at high illumination. One reason for this is that in the SPAD 11, dead time (Dead Time) in which the SPAD 11 does not operate occurs after one photon is detected.

In a case where a photon arrives at the SPAD 11 in the dead time, the photon is not detected. For this reason, a probability of photons arriving at the SPAD 11 during the dead time increases in a middle to high illumination region in which a photon arrival frequency becomes high, resulting in a decrease in a detection probability. As a result, a signal-to-noise ratio (SNR: Signal to Noise Ratio) gradually deteriorates, and a signal eventually saturates.

The dead time is an important parameter that determines highest illumination at which the SPAD 11 enables detection, and is a limiting factor of a dynamic range (Dynamic Range).

In the photodetector 1 and the distance measurement system 6 according to the 3-1st embodiment, the pixel 10 including the SPAD 11 obtains a high-sensitivity signal. In addition, the pixel 13 including a fine CIS is included, and the pixel 13 obtains a low-sensitivity signal. A combination of these obtained signals makes it possible to improve the dynamic range while effectively suppressing degradation in resolution.

### [1. Circuit Configurations of Photodetector 1 and Distance Measurement System 6]

FIG. 59 illustrates an example of a circuit configuration of one pixel 13 in the photodetector 1 and the distance measurement system 6 according to the 3-1st embodiment.

### (1) Circuit Configuration of Photodetector 1

Basic configurations of the photodetector 1 and the distance measurement system 6 according to the 3-1st embodiment are the same as those of the photodetector 1 and the distance measurement system 6 according to the 2-1st embodiment. That is, the photodetector 1 includes the pixel 13 including the charge storage type PD 14 as the light-receiving element, in addition to the unillustrated pixel 10 including the SPAD 11. FIG. 59 illustrates one pixel 13. In actuality, in the photodetector 1, a plurality of pixels 13 is arranged.

The PD 14 converts incident light into electric charge. The anode electrode of the PD 14 is electrically coupled to the reference power supply Vs. The cathode electrode of the PD 14 is electrically coupled to the readout circuit 31 via the transfer transistor Tt. The transfer transistor Tt incudes, for example, an n-type IGFET.

### (2) Circuit Configuration of Circuit Device 5

The circuit device 5 includes the readout circuit (the pixel circuit) 31. The readout circuit 3 includes the amplification transistor Ta, the selection transistor Ts, and the reset transistor Tr. Here, these transistors including the amplification transistors Ta that construct the readout circuit 3 each include an n-type IGFET.

### [2. Device Configurations of Photodetector 1 and Distance Measurement System 6]

FIG. 60 illustrates an example of longitudinal cross-sectional configurations of a plurality of pixels 10 and the pixel 13 in the photodetector 1 illustrated in FIG. 59. FIG. 61 illustrates an example of planar configurations of the pixels 10 and the pixel 13 in the photodetector 1 illustrated in FIG. 60.

### (1) Device Configuration of Pixel 10 of Photodetector 1

As illustrated in FIGS. 60 and 61, the pixel 10 of the photodetector 1 is provided in the first region A1 of the first base 101, for example, as with the pixel 10 of the photodetector 1 according to the 1-1st embodiment described above. The pixel 10 is provided to be surrounded by the insulating isolator 102. Moreover, the pixel 10 includes the SPAD 11.

The planar shape of the pixel 10 is formed in a polygonal shape, in this case, in an octagonal shape or a regular octagonal shape. Moreover, relative to one pixel 10, another pixel 10 adjacent in the arrow-X direction is provided with the second region A2 interposed therebetween. In addition, relative to the one pixel 10, another pixel 10 adjacent in the arrow-Y direction is provided with the second region A2 interposed therebetween. That is, the second region A2 is surrounded by four pixels 10, and is provided on the pixel 10 with the insulating isolator 102 interposed therebetween.

### (2) Device Configuration of Pixel 13 of Photodetector 1

The pixel 13 is provided in the second region A2 of the first base 101. The pixel 10 is surrounded by the insulating isolator 102; therefore, the second region A2 is at least electrically isolated from the first region A1 by the insulating isolator 102. Moreover, the pixel 13 includes the PD 14. The PD 14 is formed to include the n-type semiconductor region 141 provided in the first base 101.

Here, the planar shape of the pixel 13 is formed in a quadrilateral shape or a square shape.

In addition, the n-type semiconductor region 141 of the PD 14 is shared as one main electrode with the transfer transistor Tt. The other main electrode of the transfer transistor Tt is electrically coupled to the floating diffusion 142. The gate electrode 1141 of the transfer transistor Tt is formed in the wiring layer 111.

### [3. Manufacturing Method of Photodetector 1 and Distance Measurement System 6]

A manufacturing method of the photodetector 1 and the distance measurement system 6 according to the 3-1st embodiment is as described below.

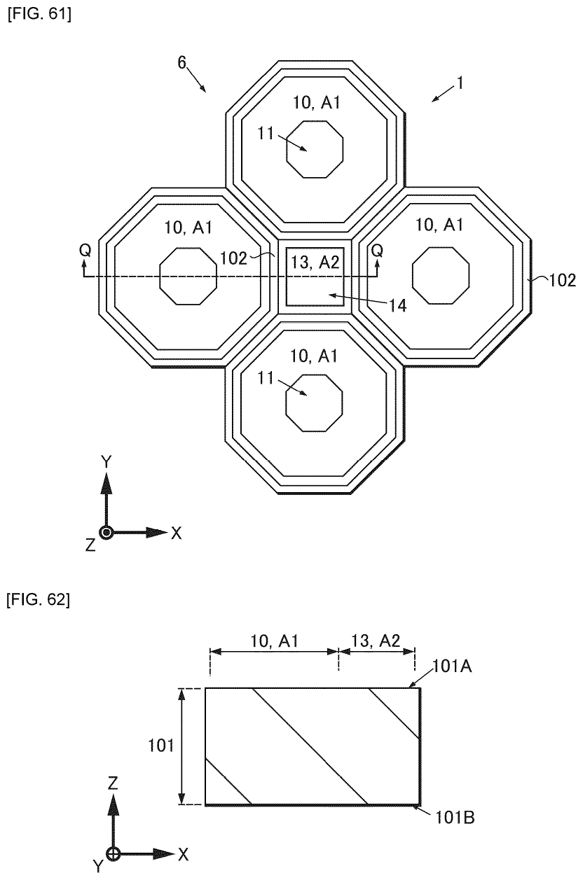

First, as illustrated in FIG. 62, the first base 101 is prepared. As the first base 101, for example, a monocrystalline Si substrate doped with an n-type impurity is used.

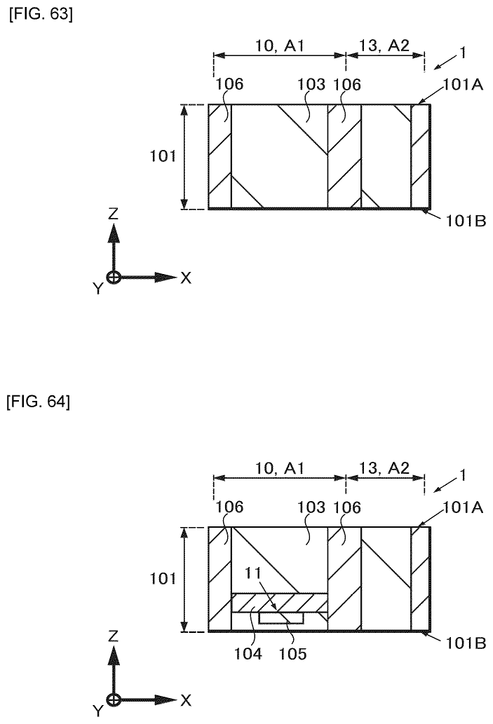

As illustrated in FIG. 63, the p-type semiconductor region 106 is formed in the first base 101 along each of the first region A1 and the second region A2. The p-type semiconductor region 106 is formed as a pinning region. The p-type semiconductor region 106 is formed by doping the first base 101 with a p-type impurity in the thickness direction by, for example, an ion implantation method.

As illustrated in FIG. 64, in the first region A1, the anode region 104 and the cathode region 105 are formed in a thickness-direction middle portion of the first base 101. The anode region 104 is formed by doping the first base 101 with a p-type impurity by the ion implantation method. Similarly, the cathode region 105 is formed by doping the first base 101 with an n-type impurity by the ion implantation method. The anode region 104 and the cathode region 105 are formed, thereby completing the SPAD 11.

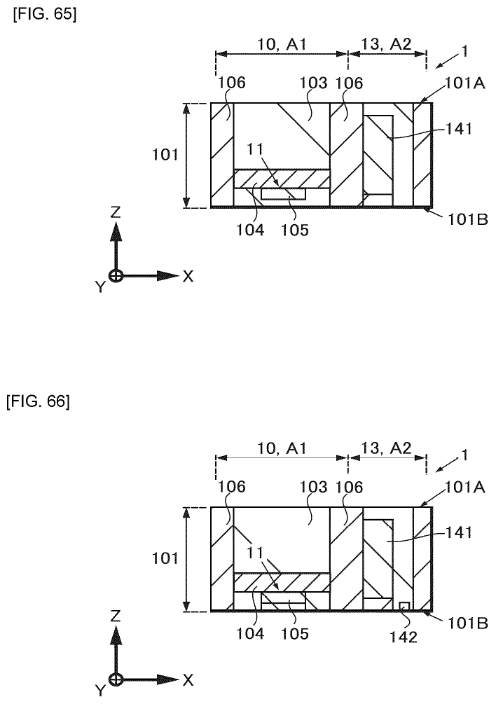

As illustrated in FIG. 65, in the second region A2, the n-type semiconductor region 141 and the like are formed in a thickness-direction middle portion of the first base 101. The n-type semiconductor region 141 is formed by doping the first base 101 with an n-type impurity by the ion implantation method. The n-type semiconductor region 141 is formed, thereby completing the PD 14.

As illustrated in FIG. 66, the floating diffusion 142 and contact regions (a p-type semiconductor region and an n-type semiconductor region) with no reference numeral are formed. The floating diffusion 142 and the contact regions are each formed by doping with an impurity by, for example, the ion implantation method.

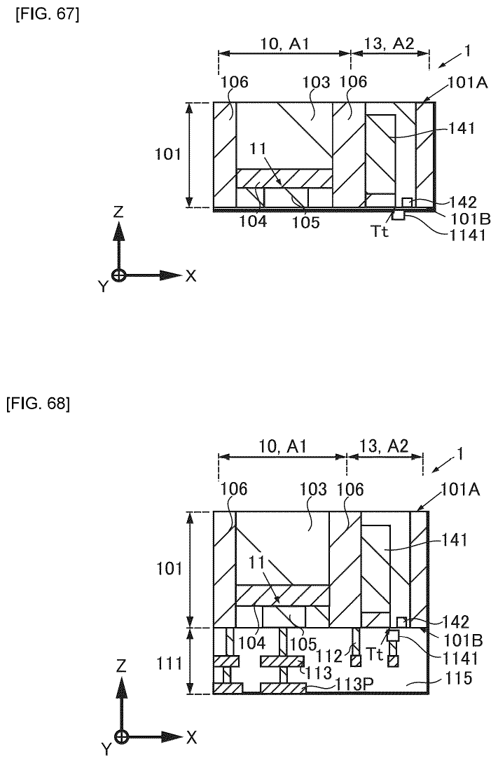

As illustrated in FIG. 67, in the second region A2, the gate electrode 1141 is formed on the second surface 101B of the first base 101 with a gate insulating film with no reference numeral interposed therebetween. The gate electrode 1141 is formed by, for example, polycrystalline Si deposited by a chemical vapor deposition (CVD: Chemical Vapor Deposition) method.

As illustrated in FIG. 68, the wiring layer 111 is formed on the first surface 101A of the first base 101. The wiring layer 111 includes a plurality of wirings 113, the terminal 113P, and the like. The wirings 113 each include, for example, Al—Cu. The terminal 113P includes, for example, Cu.

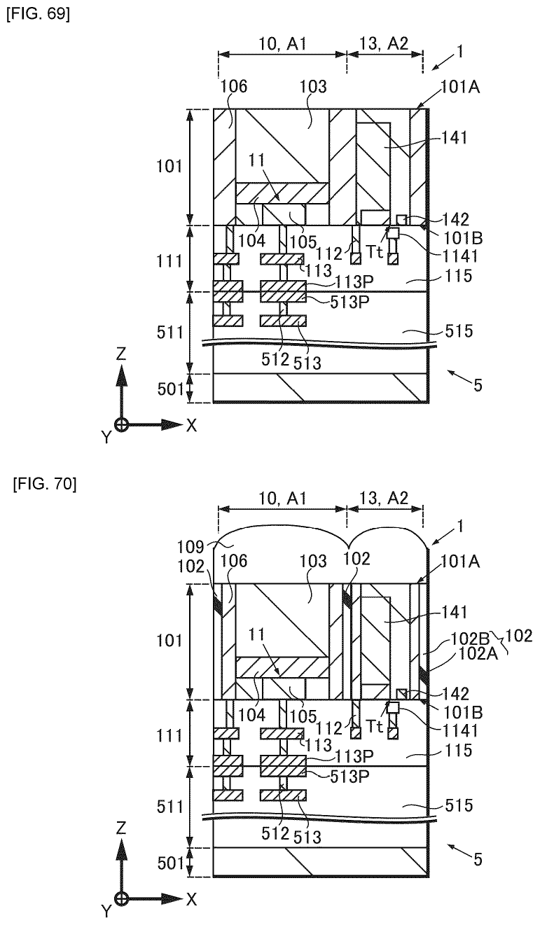

As illustrated in FIG. 69, the second base 501 is stacked on the first base 101. The readout circuit 3 and the like that construct the circuit device 5 are mounted on the second base 501. Upon the stacking, the terminal 113P of the first base 101 and the terminal 513P of the wiring layer 511 of the second base 501 are bonded to each other. In a case where the terminal 113P includes, for example, Cu and the terminal 513P includes, for example, Cu, bonding between the terminal 113P and the terminal 513P is Cu—Cu bonding.

Thereafter, the insulating isolator 102 that penetrates through the first base 101 in the thickness direction is formed around each of the first region A1 and the second region A2 in the first base 101. Here, the insulating isolator 102 is formed to penetrate the first base 101 in the thickness direction as described in the photodetector 1 and the distance measurement system 6 according to the 1-1st embodiment.

As illustrated in FIG. 70, the optical lens 109 is formed on the first surface 101A of the first base 101. The optical lens 109 is formed in each of the first region A1 and the second region A2.

The optical lens 109 is formed, thereby making it possible to complete the photodetector 1 and the distance measurement system 6 in which the pixel 10 including the SPAD 11 and the distance measurement system are mixed.

Components other than the above-described components are the same or substantially the same as the components of the photodetector 1 and the distance measurement system 6 according to the 1-1st embodiment, and redundant descriptions are therefore omitted.

[workings and Effects]

As described above, the photodetector 1 and the distance measurement system 6 according to the 3-1st embodiment each include the SPAD 11, the charge storage type PD 14, and the insulating isolator 102.

The SPAD 11 is provided in the first region A1 of the first base 101, and amplifies a carrier generated by an incident photon. The PD 14 is provided in the second region A2 adjacent to the first region A1 of the first base 101 in the plane direction of the first base 101, and converts incident light into electric charge. The insulating isolator 102 is provided between the first region A1 and the second region A2, and at least electrically isolates the SPAD 11 and the PD 14 from each other.

In the photodetector 1 having such a configuration, the insulating isolator 102 is provided between the SPAD 11 and the PD 14, which makes it possible for the PD 14 to effectively reduce or prevent the influence of the electrical field effect from the SPAD 11. It is thus possible to provide the pixel 10 including the SPAD 11 and the pixel 13 including the PD 14 in the same first base 101.

Thus, in the distance measurement system 6, it is possible to obtain the high-sensitivity signal by the pixel 10 and obtain the low-sensitivity signal by the pixel 13. A combination of these obtained signals makes it possible to improve the dynamic range while effectively suppressing degradation in resolution.

### 25.3-2nd Embodiment

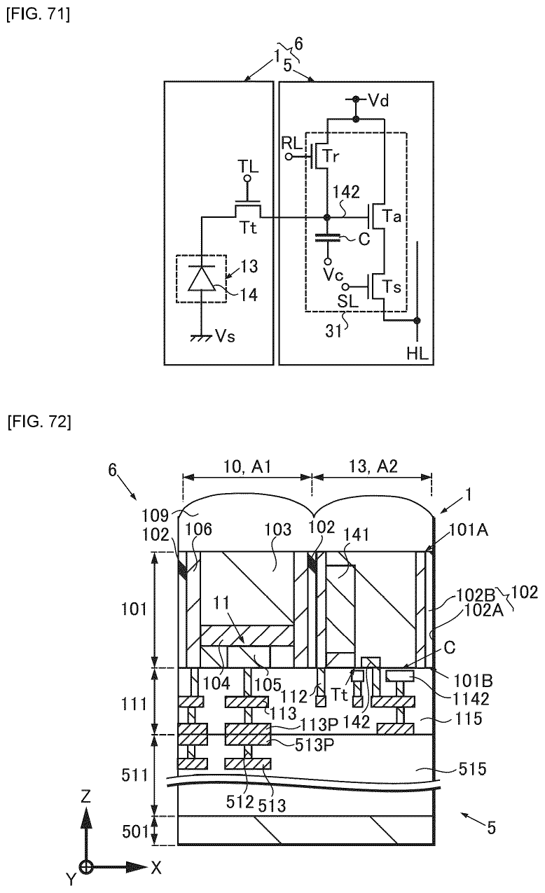

Description is given of the photodetector 1 and the distance measurement system 6 according to the 3-2nd embodiment of the present disclosure with reference to FIGS. 71 to 73. The photodetector 1 and the distance measurement system 6 according to the 3-2nd embodiment are an example in which the dynamic range is expanded in the photodetector 1 and the distance measurement system 6 according to the 3-1st embodiment.

### [1. Circuit Configurations of Photodetector 1 and Distance Measurement System 6]

FIG. 71 illustrates an example of a circuit configuration of one pixel 13 in the photodetector 1 and the distance measurement system 6 according to the 3-2nd embodiment.

As illustrated in FIG. 71, basic circuit configurations of the photodetector 1 and the distance measurement system 6 are similar to the circuit configurations of the photodetector 1 and the distance measurement system 6 according to the 3-1st embodiment. Here, a charge holding section 32 is electrically coupled to the floating diffusion 142 between the transfer transistor Tt and the readout circuit 31.

The charge holding section 32 here includes the capacitor C. One electrode of the capacitor C is electrically coupled to the floating diffusion 142. Another electrode of the capacitor C is electrically coupled to a capacity power supply Vc.

### [2. Device Configurations of Photodetector 1 and Distance Measurement System 6]

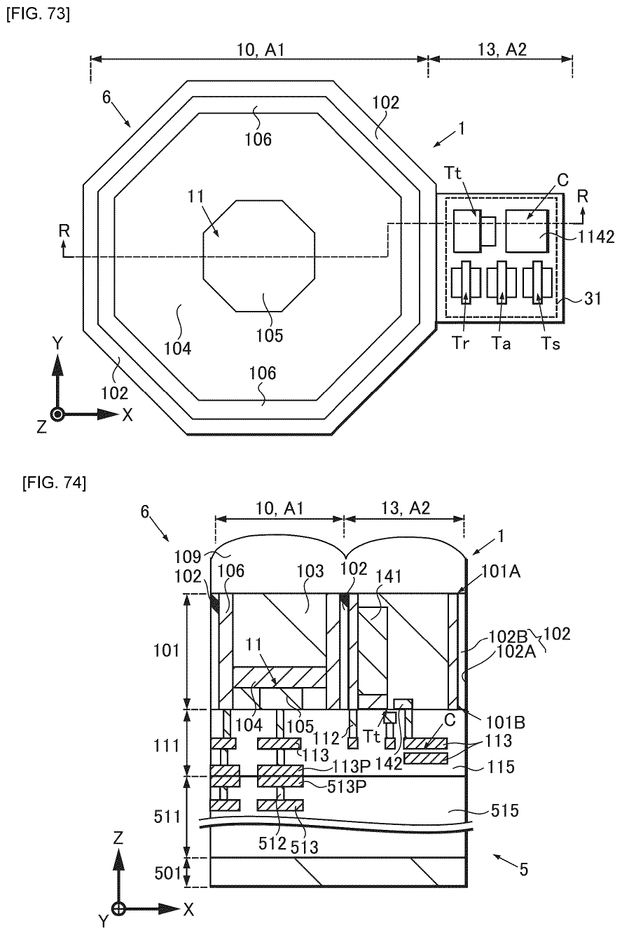

FIG. 72 illustrates an example of longitudinal cross-sectional configurations of a plurality of pixels 10 and the pixel 13 in the photodetector 1 illustrated in FIG. 71. FIG. 73 illustrates an example of planar configurations of the pixel 10 and the pixel 13 in the photodetector 1 illustrated in FIG. 72.

As illustrated in FIGS. 72 and 73, the charge holding section 32 is provided to overlap the PD 14 in the second region A2. The capacitor C that constructs the charge holding section 32 includes the first base 101, an insulator with no reference numeral, and an electrode 1142 provided in the wiring layer 111, and is formed by sequentially stacking them on the side opposite to the arrow-Y direction.

The first base 101 includes monocrystalline Si. For the insulator, for example, SiO2 is used. Moreover, the electrode 1142 is formed in the same electrically conductive layer in which the gate electrode 1141 of the transfer transistor Tt is provided, and includes the same electrically conductive material as that of the gate electrode 1141 of the transfer transistor Tt. That is, the capacitor C is a metal-insulator-semiconductor (MIS: Metal Insulator Semiconductor) capacitor element. The MIS capacitor element encompasses a metal-oxide-semiconductor (MOS: Metal Oxide Semiconductor) capacitor element.

It is to be noted that the transfer transistor Tt provided in the photodetector 1, and the amplification transistor Ta and the like that construct the readout circuit 31 of the circuit device 5 are illustrated in FIG. 73 in a transparent manner. These transistors including the transfer transistor Tt are electrically coupled to the pixel 13, and are provided in the second region A2.

Components other than the above-described components are the same or substantially the same as the components of the photodetector 1 and the distance measurement system 6 according to the 3-1st embodiment, and redundant descriptions are therefore omitted.

### [Workings and Effects]

As described above, in the photodetector 1 and the distance measurement system 6 according to the 3-2nd embodiment, it is possible to obtain workings and effects similar to the workings and effects obtained by the photodetector 1 and the distance measurement system 6 according to the 3-1st embodiment.

In addition, as illustrated in FIGS. 71 to 73, the photodetector 1 and the distance measurement system 6 each include the charge holding section 32 that is electrically coupled to the readout circuit 31. The charge holding section 32 includes the capacitor C.

Accordingly, it is possible to expand the dynamic range in the photodetector 1 and the distance measurement system 6.

### 26. 3-3rd Embodiment

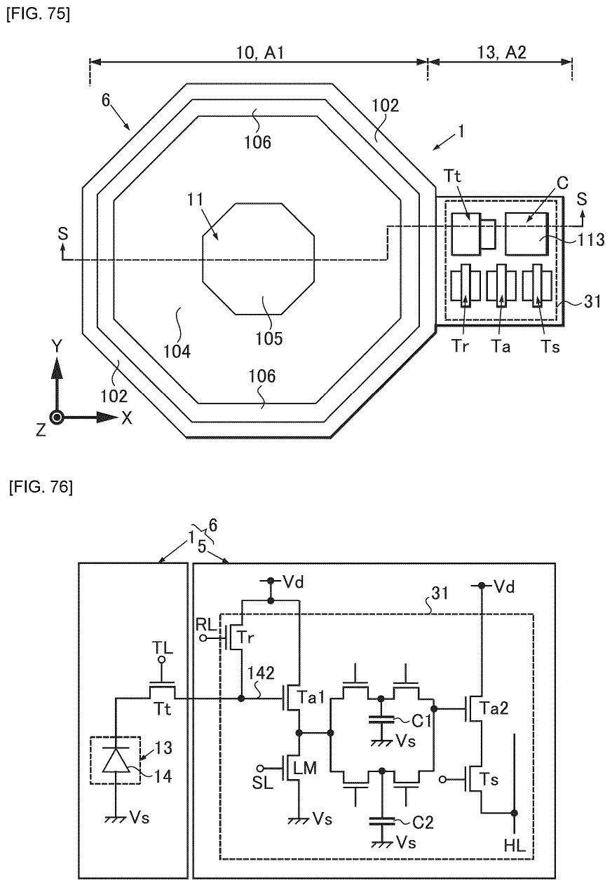

Description is given of the photodetector 1 and the distance measurement system 6 according to the 3-3rd embodiment of the present disclosure with reference to FIGS. 74 and 75. The photodetector 1 and the distance measurement system 6 according to the 3-3rd embodiment is an example in which the configuration of the charge holding section 32 is changed in the photodetector 1 and the distance measurement system 6 according to the 3-2nd embodiment.

### [Device Configurations of Photodetector 1 and Distance Measurement System 6]

FIG. 74 illustrates an example of longitudinal cross-sectional configurations of a plurality of pixels 10 and the pixel 13 in the photodetector 1 according to the 3-3rd embodiment. FIG. 75 illustrates an example of planar configurations of the pixel 10 and the pixel 13 in the photodetector 1 illustrated in FIG. 74.

As illustrated in FIG. 74 and FIG. 75, the charge holding section 32 is provided to overlap the PD 14 in the second region A2. The capacitor C that constructs the charge holding section 32 is formed to include two wirings 113 provided in the wiring layer 111, and the insulator 115 sandwiched between the two wirings 113.

That is, the capacitor C is a metal-insulator-metal (MIM: Metal Insulator Metal) capacitor element.

Components other than the above-described components are the same or substantially the same as the components of the photodetector 1 and the distance measurement system 6 according to the 3-2nd embodiment, and redundant descriptions are therefore omitted.

### [Workings and Effects]

As described above, in the photodetector 1 and the distance measurement system 6 according to the 3-3rd embodiment, it is possible to obtain workings and effects similar to the workings and effects obtained by the photodetector 1 and the distance measurement system 6 according to the 3-2nd embodiment.

### 27. 3-4th Embodiment

Description is given of the photodetector 1 and the distance measurement system 6 according to the 3-4th embodiment of the present disclosure with reference to FIG. 76. The photodetector 1 and the distance measurement system 6 according to the 3-4th embodiment is an example in which a global shutter (Global Shutter) method in which the PD 14 is a voltage domain (Voltage Domain) is adopted.

### [Circuit Configurations of Photodetector 1 and Distance Measurement System 6]

FIG. 76 illustrates an example of a circuit configuration of one pixel 13 in the photodetector 1 and the distance measurement system 6 according to the 3-4th embodiment.

As illustrated in FIG. 76, the readout circuit 31 adopts the global shatter method in which the PD 14 is the voltage domain. The readout circuit 31 further includes an amplification transistor Ta1, an amplification transistor Ta2, a signal-holding capacitor C1, and a signal-holding capacitor C2, although detailed description of configurations thereof is omitted.

Components other than the above-described components are the same or substantially the same as the components of the photodetector 1 and the distance measurement system 6 according to the 3-1st embodiment, and redundant descriptions are therefore omitted.

### [Workings and Effects]

As described above, in the photodetector 1 and the distance measurement system 6 according to the 3-4th embodiment, it is possible to obtain workings and effects similar to the workings and effects obtained by the photodetector 1 and the distance measurement system 6 according to the 3-1st embodiment.

In addition, in the photodetector 1 and the distance measurement system 6, as illustrated in FIG. 76, the global shutter method is adopted, which makes it possible to collectively read out readout signals from the readout circuit 31. Accordingly, for example, it is possible to obtain an advantage that even if a subject moves at high speed, occurrence of moving body distortion is suppressed, and a difference in brightness and darkness upon using a strobe light is hard to occur.

### 28. 3-5th Embodiment

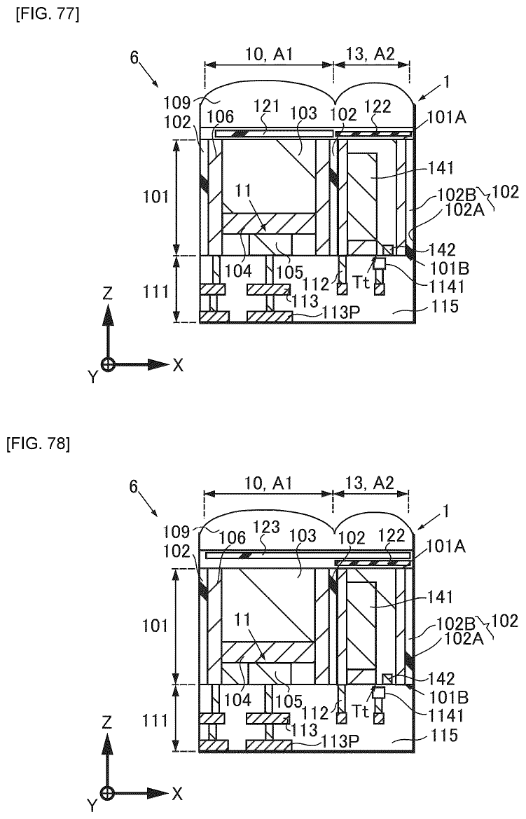

Description is given of the photodetector 1 and the distance measurement system 6 according to the 3-5th embodiment of the present disclosure with reference to FIGS. 77 to 80. The photodetector 1 and the distance measurement system 6 according to the 3-5th embodiment is an example in which the pixel 10 and the pixel 13 detect light of different wavelength bands.

### [Device Configurations of Photodetector 1 and Distance Measurement System 6]

FIG. 77 illustrates an example of longitudinal cross-sectional configurations of the pixel 10 and the pixel 13 in the photodetector 1 according to the 3-5th embodiment.

As illustrated in FIG. 77, in the photodetector 1, in the first region A1 in which the pixel 10 is provided, a near-infrared (NIR: Near infrared) bandpass filter 121 is provided between the SPAD 11 and the optical lens 109. To describe this in detail, the NIR bandpass filter 121 is provided between the first surface 101A of the first base 101 and the optical lens 109.

In contrast, in the second region A2 in which the pixel 13 is provided, a NIR cut filter 122 is provided between the PD 14 and the optical lens 109. The NIR cut filter 122 is provided between the first surface 101A of the first base 101 and the optical lens 109.

Components other than the above-described components are the same or substantially the same as the components of the photodetector 1 and the distance measurement system 6 according to the 3-1st embodiment, and redundant descriptions are therefore omitted.

### [Workings and Effects]

As described above, in the photodetector 1 and the distance measurement system 6 according to the 3-5th embodiment, it is possible to obtain workings and effects similar to the workings and effects obtained by the photodetector 1 and the distance measurement system 6 according to the 3-1st embodiment.

In addition, in the photodetector 1 and the distance measurement system 6, as illustrated in FIG. 77, the NIR bandpass filter 121 is provided for the pixel 10, and the NIR cut filter 122 is provided for the pixel 13.

Accordingly, in the SPAD 11 of the pixel 10, light of a NIR wavelength band is detectable, and in the PD 14 of the pixel 13, light of a visible light wavelength band is detectable.

### [First Modification Example]

FIG. 78 illustrates an example of longitudinal cross-sectional configurations of the pixel 10 and the pixel 13 in the photodetector 1 according to a first modification example of the 3-5th embodiment.

As illustrated in FIG. 78, in the photodetector 1, in the first region A1 in which the pixel 10 is provided, an optical filter 123 that allows a red wavelength band to pass therethrough is provided between the SPAD 11 and the optical lens 109.

In contrast, in the second region A2 in which the pixel 13 is provided, the optical filter 123 and the NIR cut filter 122 that overlaps the optical filter 123 are provided between the PD 14 and the optical lens 109.

Components other than the above-described components are the same or substantially the same as the components of the photodetector 1 and the distance measurement system 6 according to the 3-5th embodiment, and redundant descriptions are therefore omitted.

### [Workings and Effects]

As described above, in the photodetector 1 and the distance measurement system 6 according to first modification example, as illustrated in FIG. 78, the optical filter 123 is provided for the pixel 10, and the optical filter 123 and the NIR cut filter 122 are provided for the pixel 13.

Accordingly, in each of the SPAD 11 of the pixel 10 and the PD 14 of the pixel 13, light of the red wavelength band is detectable. In addition, in the PD 14 of the pixel 13, light of the NIR wavelength band is not detected.

### [Second Modification Example]

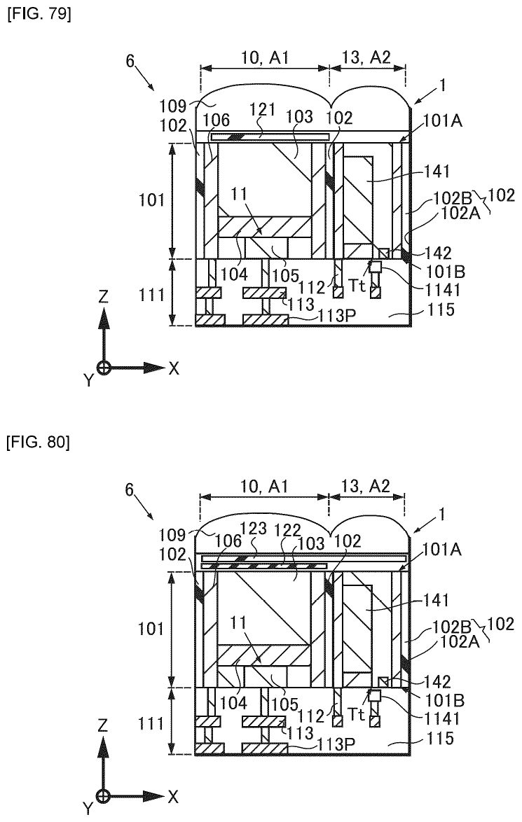

FIG. 79 illustrates an example of longitudinal cross-sectional configurations of the pixel 10 and the pixel 13 in the photodetector 1 according to a second modification example of the 3-5th embodiment.

As illustrated in FIG. 79, in the photodetector 1, in the first region A1 in which the pixel 10 is provided, the NIR bandpass filter 121 is provided between the SPAD 11 and the optical lens 109.

In contrast, in the second region A2 in which the pixel 13 is provided, no filter is provided between the PD 14 and the optical lens 109.

Components other than the above-described components are the same or substantially the same as the components of the photodetector 1 and the distance measurement system 6 according to the 3-5th embodiment, and redundant descriptions are therefore omitted.

### [Workings and Effects]

As described above, in the photodetector 1 and the distance measurement system 6 according to the first modification example, as illustrated in FIG. 79, the NIR bandpass filter 121 is provided for the pixel 10, and no filter is provided for the pixel 13.

Accordingly, in the SPAD 11 of the pixel 10, light of the NIR wavelength band is detectable, and in the PD 14 of the pixel 13, light in a wide range of wavelength bands is detectable.

### [Third Modification Example]

FIG. 80 illustrates an example of longitudinal cross-sectional configurations of the pixel 10 and the pixel 13 in the photodetector 1 according to a third modification example of the 3-5th embodiment.

As illustrated in FIG. 80, in the photodetector 1, in the first region A1 in which the pixel 10 is provided, the optical filter 123 that allows the red wavelength band to pass therethrough, and the NIR cut filter 122 that overlaps the optical filter 123 are provided between the SPAD 11 and the optical lens 109.

In contrast, in the second region A2 in which the pixel 13 is provided, the optical filter 123 is provided between the PD 14 and the optical lens 109.

Components other than the above-described components are the same or substantially the same as the components of the photodetector 1 and the distance measurement system 6 according to the 3-5th embodiment, and redundant descriptions are therefore omitted.

### [Workings and Effects]

As described above, in the photodetector 1 and the distance measurement system 6 according to the third modification example, as illustrated in FIG. 80, the optical filter 123 and the NIR cut filter 122 are provided for the pixel 10, and the optical filter 123 is provided for the pixel 13.

Accordingly, in each of the SPAD 11 of the pixel 10 and the PD 14 of the pixel 13, light of the red wavelength band is detectable. In addition, in the SPAD 11 of the pixel 10, light of the NIR wavelength band is not detected.

### 29. 3-6th Embodiment

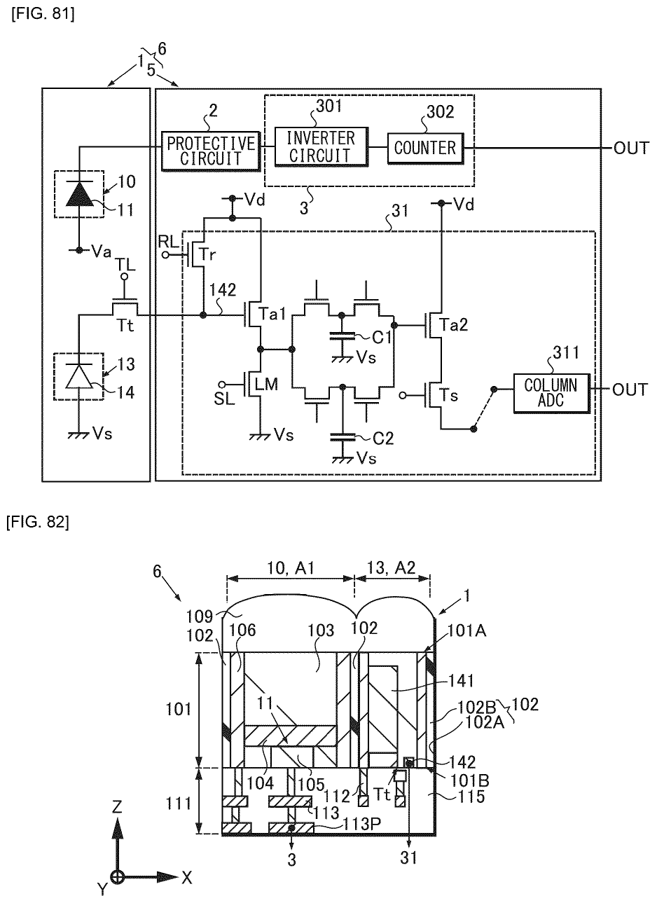

Description is given of the photodetector 1 and the distance measurement system 6 according to the 3-6th embodiment of the present disclosure with reference to FIGS. 81 and 82. The photodetector 1 and the distance measurement system 6 according to the 3-6th embodiment is an example in which an in-pixel counter 302 and a column analog-to-digital convertor circuit 311 are further included in the photodetector 1 and the distance measurement system 6 according to the 3-4th embodiment.

### [Circuit Configurations of Photodetector 1 and Distance Measurement System 6]

FIG. 81 illustrates an example of circuit configurations of the pixel 10 and the pixel 13 in the photodetector 1 and the distance measurement system 6 according to the 3-6th embodiment. As illustrated in FIG. 81, the SPAD 11 of the pixel 10 is electrically coupled to the readout circuit 3 via the protective circuit 2. The readout circuit 3 includes an inverter circuit 301 and the in-pixel counter 302.

The PD 14 of the pixel 13 is electrically coupled to the readout circuit 31 that adopts the global shutter method, as with the photodetector 1 and the distance measurement system 6 according to the 3-4th embodiment. In the readout circuit 31, Tsf represents a source-follower transistor, and a Tv represents a bias transistor.

Moreover, the column analog-to-digital convertor circuit 311 is electrically coupled to the selection transistor Ts. The column analog-to-digital convertor circuit 311 adjusts readout time of an output signal. The column analog-to-digital convertor circuit 311 is configured to include a comparator and an analog-to-digital converter.

### [Device Configurations of Photodetector 1 and Distance Measurement System 6]

FIG. 82 illustrates an example of longitudinal cross-sectional configurations of the pixel 10 and the pixel 13 in the photodetector 1 and the distance measurement system 6. As illustrated in FIG. 82, basic configurations of the pixel 10 and the pixel 13 in the photodetector 1 are similar to those in the photodetector 1 and the distance measurement system 6 according to the 3-1st embodiment.

Components other than the above-described components are the same or substantially the same as the components of the photodetector 1 and the distance measurement system 6 according to the 3-1st embodiment, and redundant descriptions are therefore omitted.

### [Workings and Effects]

As described above, in the photodetector 1 and the distance measurement system 6 according to the 3-6th embodiment, it is possible to obtain workings and effects similar to the workings and effects obtained by the photodetector 1 and the distance measurement system 6 according to the 3-1st embodiment.

### 30. 3-7th Embodiment

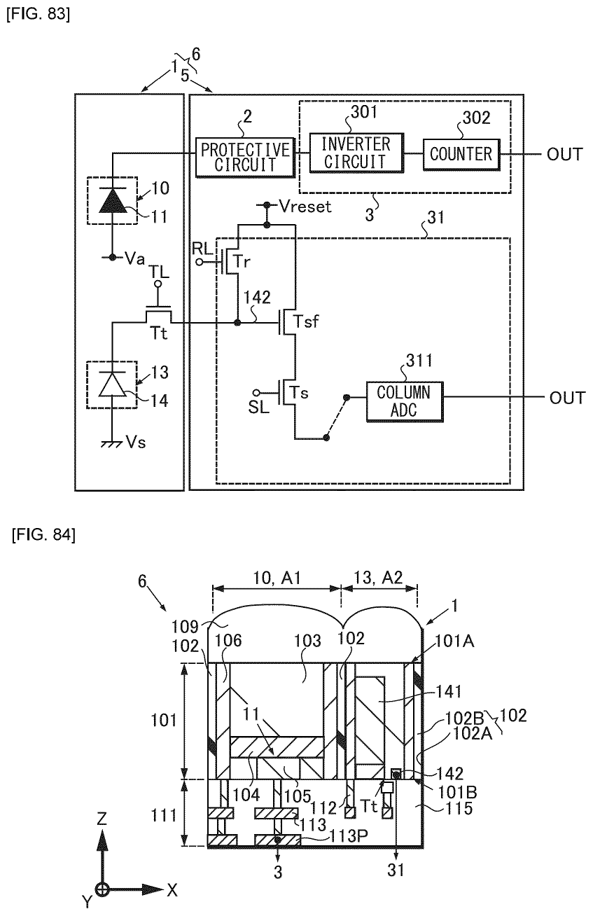

Description is given of the photodetector 1 and the distance measurement system 6 according to the 3-7th embodiment of the present disclosure with reference to FIGS. 83 and 84. The photodetector 1 and the distance measurement system 6 according to the 3-7th embodiment is an example in which a rolling shutter (Rolling shutter) method is adopted in the photodetector 1 and the distance measurement system 6 according to the 3-6th embodiment.

### [Circuit Configurations of Photodetector 1 and Distance Measurement System 6]

FIG. 83 illustrates an example of circuit configurations of the pixel 10 and the pixel 13 in the photodetector 1 and the distance measurement system 6 according to the 3-7th embodiment. As illustrated in FIG. 83, the SPAD 11 of the pixel 10 is electrically coupled to the readout circuit 3 via the protective circuit 2. The readout circuit 3 includes the inverter circuit 301 and the in-pixel counter 302.

The PD 14 of the pixel 13 is electrically coupled to the readout circuit 31 that adopts the rolling shutter method, as with the photodetector 1 and the distance measurement system 6 according to the 3-4th embodiment. In the readout circuit 31, Tsf represents a source-follower transistor.

Moreover, the column analog-to-digital convertor circuit 311 is electrically coupled to the selection transistor Ts. The column analog-to-digital convertor circuit 311 adjusts the readout time of the output signal.

### [Device Configurations of Photodetector 1 and Distance Measurement System 6]

FIG. 84 illustrates an example of longitudinal cross-sectional configurations of the pixel 10 and the pixel 13 in the photodetector 1 and the distance measurement system 6. As illustrated in FIG. 84, basic configurations of the pixel 10 and the pixel 13 in the photodetector 1 are similar to those in the photodetector 1 and the distance measurement system 6 according to the 3-1st embodiment.

Components other than the above-described components are the same or substantially the same as the components of the photodetector 1 and the distance measurement system 6 according to the 3-1st embodiment, and redundant descriptions are therefore omitted.

### [Workings and Effects]

As described above, in the photodetector 1 and the distance measurement system 6 according to the 3-7th embodiment, it is possible to obtain workings and effects similar to the workings and effects obtained by the photodetector 1 and the distance measurement system 6 according to the 3-1st embodiment.

In addition, in the photodetector 1 and the distance measurement system 6, as illustrated in FIG. 83 and FIG. 84, the rolling shutter method is adopted. The rolling shutter method is a capture method in which an entire frame is scanned in a vertical direction (or a horizontal direction) in a pixel region, and is a shutter control method. Accordingly, for example, an image detected in the vertical direction is contained in one frame; therefore, there is an advantage that there is a time difference in the image in the frame.

### 31. 3-8th Embodiment

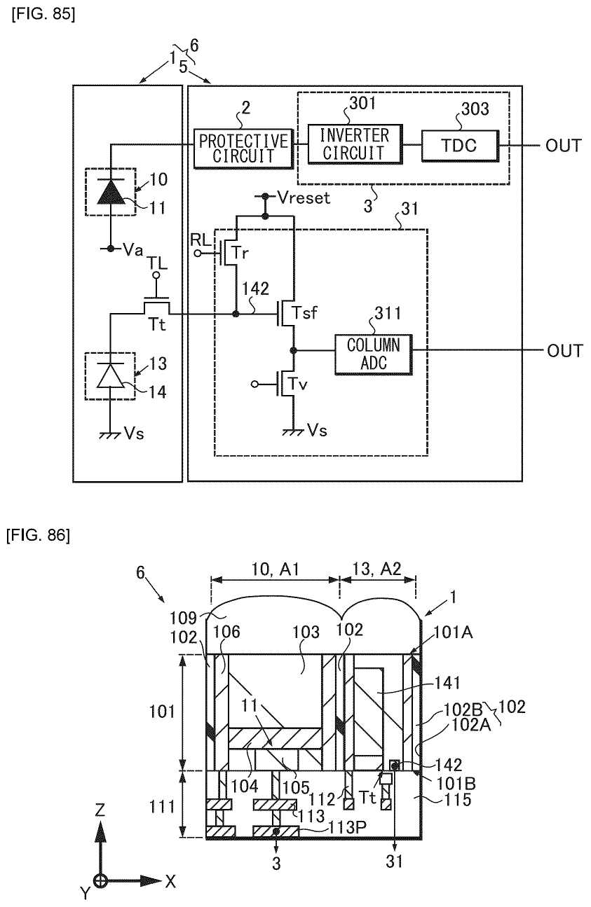

Description is given of the photodetector 1 and the distance measurement system 6 according to the 3-8th embodiment of the present disclosure with reference to FIGS. 85 and 86. The photodetector 1 and the distance measurement system 6 according to the 3-8th embodiment are a modification example of the photodetector 1 and the distance measurement system 6 according to the 3-7th embodiment.

### [Circuit Configurations of Photodetector 1 and Distance Measurement System 6]

FIG. 85 illustrates an example of circuit configurations of the pixel 10 and the pixel 13 in the photodetector 1 and the distance measurement system 6 according to the 3-8th embodiment.

As illustrated in FIG. 85, the SPAD 11 of the pixel 10 is electrically coupled to the readout circuit 3 via the protective circuit 2. The readout circuit 3 includes the inverter circuit 301 and a time-to-digital converter (Time to Digital Convertor) circuit 303.

The PD 14 of the pixel 13 is electrically coupled to the column analog-to-digital convertor circuit 311 via the readout circuit 31. In the readout circuit 31, Tsf represents a source-follower transistor. Tv represents a bias transistor.

### [Device Configurations of Photodetector 1 and Distance Measurement System 6]

FIG. 86 illustrates an example of longitudinal cross-sectional configurations of the pixel 10 and the pixel 13 in the photodetector 1 and the distance measurement system 6. As illustrated in FIG. 86, basic configurations of the pixel 10 and the pixel 13 in the photodetector 1 are similar to those in the photodetector 1 and the distance measurement system 6 according to the 3-1st embodiment.

Components other than the above-described components are the same or substantially the same as the components of the photodetector 1 and the distance measurement system 6 according to the 3-1st embodiment, and redundant descriptions are therefore omitted.

### [Workings and Effects]

As described above, in the photodetector 1 and the distance measurement system 6 according to the 3-8th embodiment, it is possible to obtain workings and effects similar to the workings and effects obtained by the photodetector 1 and the distance measurement system 6 according to the 3-1st embodiment.

In addition, in the photodetector 1 and the distance measurement system 6, as illustrated in FIG. 85 and FIG. 86, the time-to-digital converter circuit 303 is provided. Accordingly, it is possible to obtain an output of the SPAD 11 of the pixel 10 and an output of the PD 14 of the pixel 13 at the same time.

### 32. 3-9th Embodiment

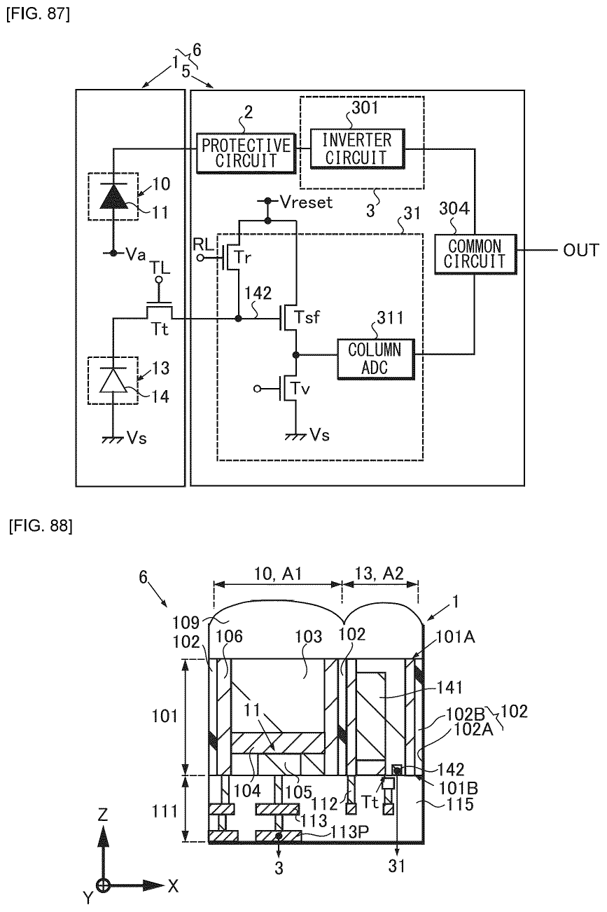

Description is given of the photodetector 1 and the distance measurement system 6 according to the 3-9th embodiment of the present disclosure with reference to FIGS. 87 and 88. The photodetector 1 and the distance measurement system 6 according to the 3-9th embodiment are a modification example of the photodetector 1 and the distance measurement system 6 according to the 3-8th embodiment.

### [Circuit Configurations of Photodetector 1 and Distance Measurement System 6]

FIG. 87 illustrates an example of circuit configurations of the pixel 10 and the pixel 13 in the photodetector 1 and the distance measurement system 6 according to the 3-9th embodiment.

As illustrated in FIG. 87, the SPAD 11 of the pixel 10 is electrically coupled to the readout circuit 3 via the protective circuit 2. The readout circuit 3 includes the inverter circuit 301, and the inverter circuit 301 is electrically coupled to a common circuit 304. The common circuit 304 has a function corresponding to the time-to-digital converter circuit 303 in the photodetector 1 and the distance measurement system 6 according to the 3-8th embodiment.

The PD 14 of the pixel 13 is electrically coupled to the column analog-to-digital convertor circuit 311 via the readout circuit 31. The column analog-to-digital convertor circuit 311 is electrically coupled to the common circuit 304.

### [Device Configurations of Photodetector 1 and Distance Measurement System 6]

FIG. 88 illustrates an example of longitudinal cross-sectional configurations of the pixel 10 and the pixel 13 in the photodetector 1 and the distance measurement system 6. As illustrated in FIG. 88, basic configurations of the pixel 10 and the pixel 13 in the photodetector 1 are similar to those in the photodetector 1 and the distance measurement system 6 according to the 3-1st embodiment.

Components other than the above-described components are the same or substantially the same as the components of the photodetector 1 and the distance measurement system 6 according to the 3-1st embodiment, and redundant descriptions are therefore omitted.

### [Workings and Effects]

As described above, in the photodetector 1 and the distance measurement system 6 according to the 3-9th embodiment, it is possible to obtain workings and effects similar to the workings and effects obtained by the photodetector 1 and the distance measurement system 6 according to the 3-1st embodiment.

In addition, in the photodetector 1 and the distance measurement system 6, as illustrated in FIGS. 87 and 88, the common circuit 304 is provided. Accordingly, it is possible to obtain an output with twofold gray-scale including an output of the SPAD 11 of the pixel 10 and an output of the PD 14 of the pixel 13.

### 33. 3-10th Embodiment

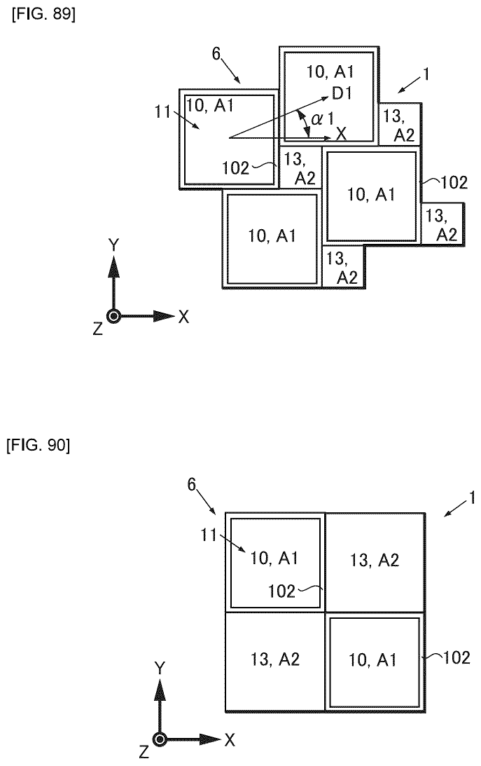

Description is given of the photodetector 1 and the distance measurement system 6 according to the 3-10th embodiment of the present disclosure with reference to FIG. 89. The photodetector 1 and the distance measurement system 6 according to the 3-10th embodiment is an example in which the respective planar shapes and the respective arrangement shapes of the pixel 10 and the pixel 13 are changed.

### [Device Configurations of Photodetector 1 and Distance Measurement System 6]

FIG. 89 illustrates an example of planar configurations of the pixel 10 and the pixel 13 in the photodetector 1 according to the 3-10th embodiment.

### (1) Configuration of Pixel 10

As illustrated in FIG. 89, the planar shape of the pixel 10 is formed in a rectangular shape that is a polygonal shape, as with the photodetector 1 according to the 2-4th embodiment described above. Here, the planar shape of the pixel 10 is formed in a quadrilateral shape or a square shape. The pixel 10 is provided in the first region A1.

A plurality of pixels 10 is arranged in the arrow-X direction and the arrow-Y direction. To describe this in detail, relative to one pixel 10, another pixel 10 adjacent in the arrow-X direction is provided to be shifted in the arrow-Y direction by a length less than or equal to about half the length of one side of the pixel 10. In other words, the pixels 10 are arranged in the oblique direction D1 relative to the arrow-X direction at the predetermined angle al on the side of the arrow-Y direction.

### (2) Configuration of Pixel 13

The pixel 13 is provided in the second region A2. The second region A2 is surrounded by a total of four first regions A1 including two first regions A1 provided adjacent in the arrow-X direction and two first regions A1 provided adjacent in the arrow-X direction and adjacent in the arrow-Y direction. The second region A2 has four sides each having a length less than or equal to about half the length of one side of a corresponding one of the four first regions A1 in a plan view. That is, the planar shape of the second region A2 is formed in a rectangular shape, in this case, in a quadrilateral shape or a square shape.

Components other than the above-described components are the same or substantially the same as the components of the photodetector 1 and the distance measurement system 6 according to each of the 3-1st embodiment to the 3-9th embodiment, and redundant descriptions are therefore omitted.

### [Workings and Effects]

As described above, in the photodetector 1 and the distance measurement system 6 according to the 3-10th embodiment, it is possible to obtain workings and effects similar to the workings and effects obtained by the photodetector 1 and the distance measurement system 6 according to any of the 3-1st embodiment to the 3-9th embodiment.

### [First Modification Example]

Description is given of the photodetector 1 and the distance measurement system 6 according to a first modification example of the 3-10th embodiment of the present disclosure with reference to FIG. 90.

FIG. 90 illustrates an example of planar configurations of the pixel 10 and the pixel 13 in the photodetector 1 according to the first modification example.

As illustrated in FIG. 90, in the photodetector 1, the pixel 10 and the pixel 13 are formed in the same rectangular shape with the same planar area. The specific planar shape of each of the pixel 10 and the pixel 13 is formed in a quadrilateral shape or a square shape.

The pixel 10 and the pixel 13 are arranged alternately in the arrow-X direction. In addition, relative to the pixel 10 and the pixel 13, the pixel 10 and the pixel 13 adjacent in the arrow-Y direction are arranged alternately in the arrow X direction, and are provided to be shifted by a length equal to the length of one pixel 10.

Components other than the above-described components are the same or substantially the same as the components of the photodetector 1 and the distance measurement system 6 according to each of the 3-1st embodiment to the 3-9th embodiment, and redundant descriptions are therefore omitted.

### [Workings and Effects]

As described above, in the photodetector 1 and the distance measurement system 6 according to the first modification example, it is possible to obtain workings and effects similar to the workings and effects obtained by the photodetector 1 and the distance measurement system 6 according to any of the 3-1st embodiment to the 3-9th embodiment.

### [Second Modification Example]

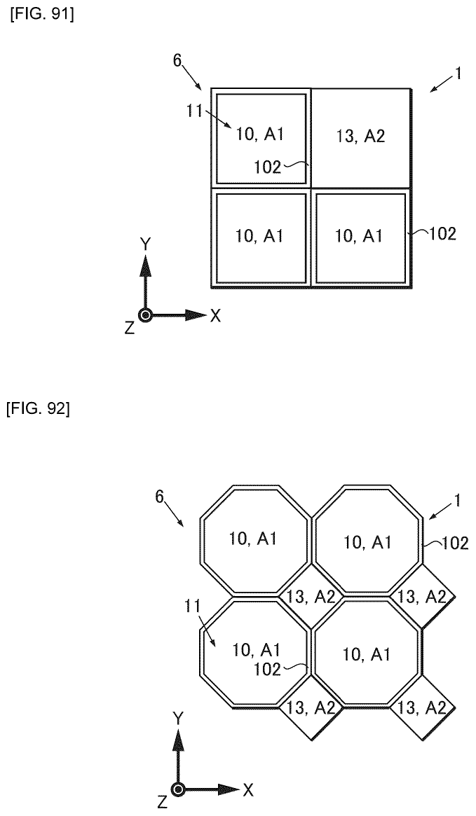

Description is given of the photodetector 1 and the distance measurement system 6 according to a second modification example of the 3-10th embodiment of the present disclosure with reference to FIG. 91.

FIG. 91 illustrates an example of planar configurations of the pixel 10 and the pixel 13 in the photodetector 1 according to the second modification example.

As illustrated in FIG. 91, the pixel 10 and the pixel 13 in the photodetector 1 are formed in the same rectangular shape with the same planar area, as with the photodetector 1 according to the first modification example.

Two pixels 10 are provided adjacent in the arrow-X direction. In addition, one pixel 10 is provided adjacent in the arrow-Y direction to one pixel 10 of the two pixels 10. Moreover, one pixel 13 is provided adjacent in the arrow-Y direction to another pixel 10 of the two pixels 10.

In other words, one pixel 13 is provided for three pixels 10, and they construct a unit pixel.

Components other than the above-described components are the same or substantially the same as the components of the photodetector 1 and the distance measurement system 6 according to each of the 3-1st embodiment to the 3-9th embodiment, and redundant descriptions are therefore omitted.

### [Workings and Effects]

As described above, in the photodetector 1 and the distance measurement system 6 according to the second modification example, it is possible to obtain workings and effects similar to the workings and effects obtained by the photodetector 1 and the distance measurement system 6 according to any of the 3-1st embodiment to the 3-9th embodiment.

### [Third Modification Example]

Description is given of the photodetector 1 and the distance measurement system 6 according to a third modification example of the 3-10th embodiment of the present disclosure with reference to FIG. 92.

FIG. 92 illustrates an example of planar configurations of the pixel 10 and the pixel 13 in the photodetector 1 according to the third modification example.

As illustrated in FIG. 92, the planar shape of the pixel 10 of the photodetector 1 is formed in a polygonal shape, as with the photodetector 1 according to the 1-1st embodiment, Specifically, the planar shape of the pixel 10 is formed in an octagonal shape or a regular octagonal shape. The planar shape of the first region A1 is the same as the planar shape of the pixel 10.

The pixels 10 are provided adjacent in each of the arrow-X direction and the arrow-Y direction.

The pixel 13 is provided in the second region A2. The second region A2 is surrounded by a total of four first regions A1 including two first regions A1 provided adjacent in the arrow-X direction and two first regions A1 provided adjacent in the arrow-X direction and adjacent in the arrow-Y direction. The planar shape of the second region A2 corresponds to a length of one side of each of the four first regions A1, and is formed in a quadrilateral shape or a square shape in a plan view.

Components other than the above-described components are the same or substantially the same as the components of the photodetector 1 and the distance measurement system 6 according to each of the 3-1st embodiment to the 3-9th embodiment, and redundant descriptions are therefore omitted.

### [Workings and Effects]

As described above, in the photodetector 1 and the distance measurement system 6 according to the third modification example, it is possible to obtain workings and effects similar to the workings and effects obtained by the photodetector 1 and the distance measurement system 6 according to any of the 3-1st embodiment to the 3-9th embodiment.

### [Fourth Modification Example]

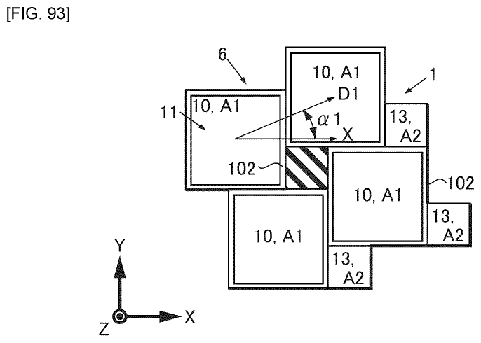

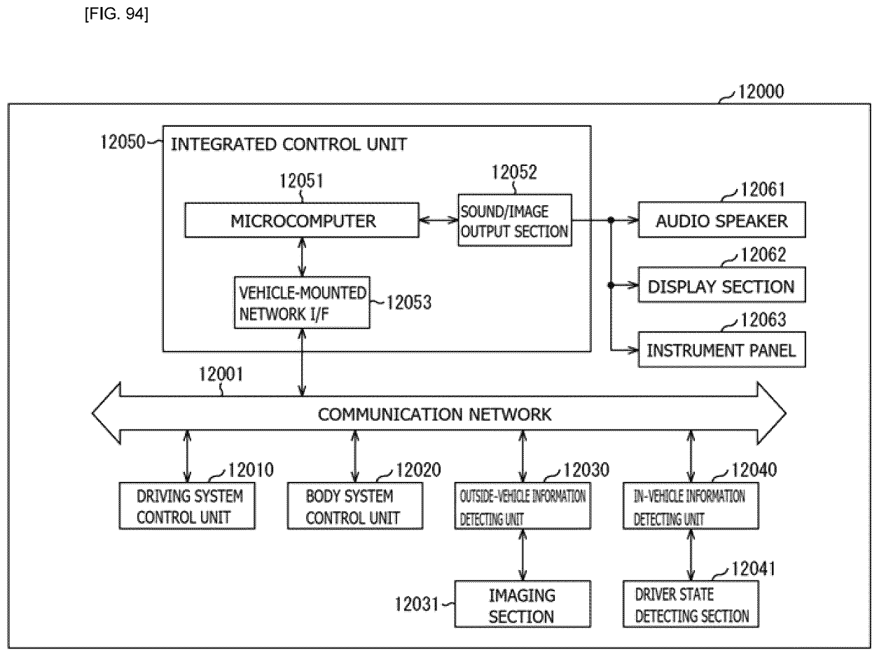

Description is given of the photodetector 1 and the distance measurement system 6 according to a fourth modification example of the 3-10th embodiment of the present disclosure with reference to FIG. 93.

FIG. 93 illustrates an example of planar configurations of the pixel 10 and the pixel 13 in the photodetector 1 according to the fourth modification example.

As illustrated in FIG. 93, the planar shape of each of the pixel 10 and the pixel 13 of the photodetector 1 is similar to that in the photodetector 1 according to the 3-10th embodiment. Here, an arrangement ratio of the pixel 13 is changed relative to an arrangement ratio of the pixel 10. For example, the arrangement number of pixels 10 is four, and the arrangement number of pixels 13 is three.

Components other than the above-described components are the same or substantially the same as the components of the photodetector 1 and the distance measurement system 6 according to each of the 3-1st embodiment to the 3-9th embodiment, and redundant descriptions are therefore omitted.

### [Workings and Effects]

As described above, in the photodetector 1 and the distance measurement system 6 according to the fourth modification example, it is possible to obtain workings and effects similar to the workings and effects obtained by the photodetector 1 and the distance measurement system 6 according to any of the 3-1st embodiment to the 3-9th embodiment.

### 34. Example of Application to Mobile Body

The technology (present technology) according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, and a robot.

FIG. 94 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 94, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 94, an audio speaker 12061, a display section 12062, and an instrument panel 12063 are illustrated as the output device. The display section 12062 may, for example, include at least one of an on-board display and a head-up display.

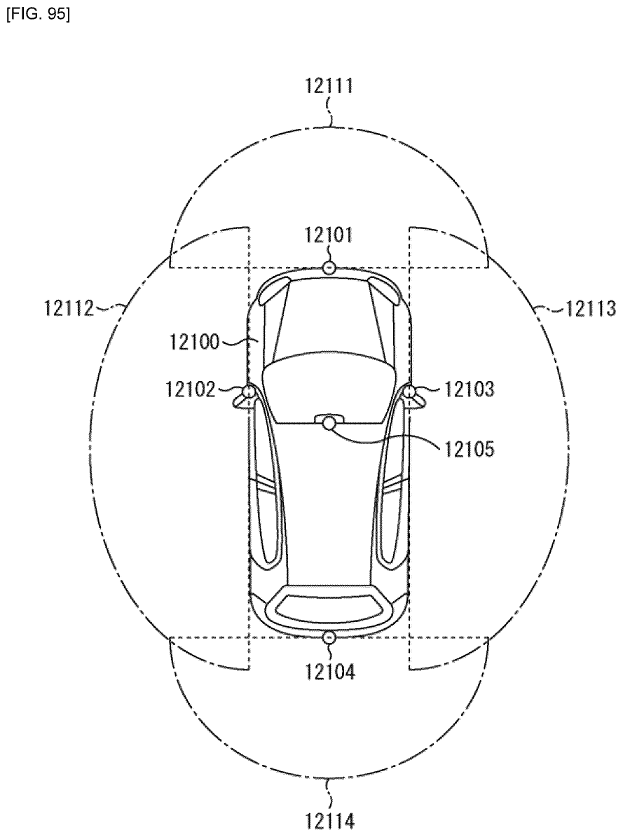

FIG. 95 is a diagram depicting an example of the installation position of the imaging section 12031.

In FIG. 95, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 95 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the vehicle control system, to which the technology according to the present disclosure may be applied. The technology according to the present disclosure may be applied to the imaging section 12031 among the configurations described above. The application of the technology according to the present disclosure to the imaging section 12031 makes it possible to construct a photodetector and a distance measurement system that reliably insulates and isolates pixels of different kinds from each other.

### 35. Other Embodiments

The present technology is not limited to the embodiments described above, and various modifications may be made without departing from the gist of the present technology.

For example, the photodetectors and the distance measurement systems according to two or more embodiment, among the photodetectors and the distance measurement systems according to the 1-1st embodiment to the 3-10th embodiment described above, may be combined.

A photodetector according to a first aspect of the present disclosure includes a SPAD, one or more elements different from the SPAD, and an insulating isolator.

The SPAD is provided in a first region of a first base, and amplifies a carrier generated by an incident photon. The one or more elements are provided in a second region adjacent to the first region of the first base in a plane direction of the first base. The insulating isolator is provided between the first region and the second region, and at least electrically isolates the SPAD and the one or more elements from each other.

Thus, in the photodetector, the insulating isolator is provided between the SPAD and the one or more elements, which makes it possible for the one or more elements to effectively reduce or prevent an influence of an electrical field effect from the SPAD.

A distance measurement system according to a second aspect of the present disclosure includes the photodetector according to the first aspect, and a circuit device.

The photodetector includes a SPAD, a protective circuit, and an insulating isolator. The SPAD is provided in a first region of a first base, and amplifies a carrier generated by an incident photon. The protective circuit is provided in a second region adjacent to the first region of the first base in a plane direction of the first base, and includes one or more elements that reduce an overcurrent from the SPAD. The insulating isolator is provided between the first region and the second region, and at least electrically isolates the SPAD and the one or more elements from each other.

The circuit device includes a readout circuit and a time measurement circuit. The readout circuit is electrically coupled to the SPAD via the protective circuit, and reads out the amplified carrier. The time measurement circuit is electrically coupled to the readout circuit, and measures time of flight of light.

Thus, it is possible for the protective circuit to reduce an overcurrent, which makes it possible to construct a distance measurement system having superior overcurrent resistance of the readout circuit.

A photodetector according to a third aspect of the present disclosure includes a SPAD, a light-receiving element, and an insulating isolator.

The SPAD is provided in a first region of a first base, and amplifies a carrier generated by an incident photon. The light-receiving element is provided in a second region adjacent to the first region of the first base in a plane direction of the first base, and converts incident light into electric charge. The insulating isolator is provided between the first region and the second region, and at least electrically isolates the SPAD and the light-receiving element from each other.

Thus, the insulating isolator is provided between the SPAD and the light-receiving element, which makes it possible for the light-receiving element to effectively reduce or prevent an influence of an electrical field effect from the SPAD. In addition, it is possible to provide a pixel including the SPAD and a pixel including the light-receiving element in the same first base.

A distance measurement system according to a fourth aspect of the present disclosure includes a photodetector, a first time measurement circuit, and a second time measurement circuit.

The photodetector includes an SPAD, a light-receiving element, and an insulating isolator. The SPAD is provided in a first region of a first base, and amplifies a carrier generated by an incident photon. The light-receiving element is provided in a second region adjacent to the first region of the first base in a plane direction of the first base, and converts incident light into electric charge. The insulating isolator is provided between the first region and the second region, and at least electrically isolates the SPAD and the light-receiving element from each other.

The first time measurement circuit is electrically coupled to the SPAD, and measures time of flight of light. The second time measurement circuit is electrically coupled to the light-receiving element, and measures time of flight of light at a shorter distance than the first time measurement circuit.

Thus, in the distance measurement system 6, it is possible to implement both distance measurement adopting the dToF method and distance measurement adopting the iToF.

A photodetector according to a fifth aspect of the present disclosure includes a SPAD, a charge storage type PD, and an insulating isolator.

The SPAD is provided in a first region of a first base, and amplifies a carrier generated by an incident photon. The PD is provided in a second region adjacent to the first region of the first base in a plane direction of the first base, and converts incident light into electric charge. The insulating isolator is provided between the first region and the second region, and at least electrically isolates the SPAD and the PD from each other.

Thus, the insulating isolator is provided between the SPAD and the PD, which makes it possible for the PD to effectively reduce or prevent an influence of an electrical field effect from the SPAD. As a result, it is possible to provide a pixel including the SPAD and a pixel including the PD in the same first base.

A distance measurement system according to a sixth aspect of the present disclosure includes a photodetector, a time measurement circuit, and an analog-to-digital convertor circuit. The photodetector includes a SPAD, a charge storage type PD, and an insulating isolator. The SPAD is provided in a first region of a first base, and amplifies a carrier generated by an incident photon. The PD is provided in a second region adjacent to the first region of the first base in a plane direction of the first base, and converts incident light into electric charge. The insulating isolator is provided between the first region and the second region, and at least electrically isolates the SPAD and the PD from each other.

The time measurement circuit is electrically coupled to the SPAD, and measures time of flight of light. The analog-to-digital convertor circuit is electrically coupled to the PD, and converts electric charge from an analog signal to a digital signal.

Thus, in the distance measurement system, it is possible to obtain a high-sensitivity signal by a pixel including the SPAD and obtain a low-sensitivity signal by a pixel including the PD. A combination of these obtained signals makes it possible to improve a dynamic range while effectively suppressing degradation of resolution.

### Configuration of Present Technology

The present technology has the following configurations. According to the present technology having the following configurations, in a photodetector and a distance measurement system, it is possible for an element to effectively reduce or prevent an influence of an electrical field effect from a SPAD.

(1-1)

A photodetector including:
an avalanche diode that is provided in a first region of a first base, and amplifies a carrier generated by an incident photon;
one or more elements that are provided in a second region adjacent to the first region of the first base in a plane direction of the first base, and are different from the avalanche diode; and
an insulating isolator that is provided between the first region and the second region, and at least electrically isolates the avalanche diode and the one or more elements from each other.
   (1-2)

The photodetector according to (1-1), in which the one or more elements construct a protective circuit that reduces an overcurrent from the avalanche diode.

(1-3)

The photodetector according to (1-1) or (1-2), in which the one or more elements include a resistor element.

(1-4)

The photodetector according to (1-3), in which the resistor element includes silicon.

(1-5)

The photodetector according to (1-3), in which the resistor element is formed by an insulated gate field effect transistor.

(1-6)

The photodetector according to (1-5), in which
a plurality of the insulated gate field effect transistors is provided, and
the plurality of the insulated gate field effect transistors is electrically coupled in series.
   (1-7)

The photodetector according to any one of (1-3) to (1-6), in which
one end of the resistor element is electrically coupled to the avalanche diode, and
another end of the resistor element is electrically coupled to a clamp element that clamps an overcurrent.
   (1-8)

The photodetector according to (1-7), in which the clamp element is provided in the second region.

(1-9)

The photodetector according to (1-2), in which the avalanche diode is electrically coupled, via the protective circuit, to a readout circuit that reads out the amplified carrier.

(1-10)

The photodetector according to (1-9), further including a second base stacked on the first base in a thickness direction of the first base, in which
the readout circuit is provided in the second base.
   (1-11)

The photodetector according to (1-7), further including a second base stacked on the first base in a thickness direction of the first base, in which
the clamp element is provided in the second base.
   (1-12)

The photodetector according to any one of (1-1) to (1-11), in which
a planar shape of the first region is a triangular or more polygonal shape, a circular shape, or an elliptical shape as viewed in a photon incident direction, and
the second region is surrounded by three or more of the first regions in a plane direction.
   (1-13)

The photodetector according to (1-12), in which
the planar shape of the first region is an octagonal shape, and
the second region is surrounded by four of the first regions.
   (1-14)

The photodetector according to any one of (1-1) to (1-13), in which
the insulating isolator includes
a trench provided in a thickness direction of the first base, and
an embedded member embedded inside the trench.
   (1-15)

The photodetector according to (1-14), in which
the embedded member includes
an insulator provided along an inner wall of the trench, and
a metallic body embedded inside the trench with the insulator interposed therebetween.
   (1-16)

A distance measurement system including:
a photodetector; and
a circuit device, in which
the photodetector includes
an avalanche diode that is provided in a first region of a first base, and amplifies a carrier generated by an incident photon,
a protective circuit that is provided in a second region adjacent to the first region of the first base in a plane direction of the first base, and includes one or more elements that reduce an overcurrent from the avalanche diode, and
an insulating isolator that is provided between the first region and the second region, and at least electrically isolates the avalanche diode and the one or more elements from each other, and
the circuit device includes
a readout circuit that is electrically coupled to the avalanche diode via the protective circuit, and reads out the amplified carrier, and
a time measurement circuit that is electrically coupled to the readout circuit, and measures time of flight of light.
   (1-17)

The distance measurement system according to (1-16), further including a second base stacked on the first base in a thickness direction of the first base, in which
the readout circuit is provided in the second base.
   (1-18)

The distance measurement system according to (1-16) or (1-17), further including a second base stacked on the first base in a thickness direction of the first base, in which
the time measurement circuit is provided in the second base.
   (2-1)

A photodetector including:
an avalanche diode that is provided in a first region of a first base, and amplifies a carrier generated by an incident photon;
a light-receiving element that is provided in a second region adjacent to the first region of the first base in a plane direction of the first base, and converts incident light into electric charge; and
an insulating isolator that is provided between the first region and the second region, and at least electrically isolates the avalanche diode and the light-receiving element from each other.
   (2-2)

The photodetector according to (2-1), in which the light-receiving element includes a photodiode.

(2-3)

The photodetector according to (2-1), in which
the light-receiving element includes
a voltage applied section to which a voltage is applied to distribute electric charge converted from light, and
a charge detector that detects the electric charge distributed by the voltage applied section.
   (2-4)

The photodetector according to any one of (2-1) to (2-3), in which
a planar shape of the first region is a triangular or more polygonal shape, a circular shape, or an elliptical shape as viewed in a photon incident direction, and
the second region is surrounded by three or more of the first regions in a plane direction.
   (2-5)

The photodetector according to (2-4), in which
the planar shape of the first region is an octagonal shape, and
the second region is surrounded by four of the first regions.
   (2-6)

A distance measurement system including:
a photodetector;
a first time measurement circuit; and
a second time measurement circuit, in which
the photodetector includes
an avalanche diode that is provided in a first region of a first base, and amplifies a carrier generated by an incident photon;
a light-receiving element that is provided in a second region adjacent to the first region of the first base in a plane direction of the first base, and converts incident light into electric charge, and
an insulating isolator that is provided between the first region and the second region, and at least electrically isolates the avalanche diode and the light-receiving element from each other,
the first time measurement circuit is electrically coupled to the avalanche diode, and measures time of flight of light, and
the second time measurement circuit is electrically coupled to the light-receiving element, and measures time of flight of light at a shorter distance than the first time measurement circuit.
   (2-7)

The distance measurement system according to (2-6), in which
the first time measurement circuit is electrically coupled to the avalanche diode via a protective circuit and a readout circuit, the protective circuit that reduces an overcurrent from the avalanche diode, the readout circuit that is electrically coupled via the protective circuit, and reads out the amplified carrier.
   (2-8)

The distance measurement system according to (2-7), further including a second base stacked on the first base in a thickness direction of the first base, in which
the readout circuit is provided in the second base.
   (2-9)

The distance measurement system according to any one of (2-6) to (2-8), further including a second base stacked on the first base in a thickness direction of the first base, in which
the first time measurement circuit and the second time measurement circuit are provided in the second base.
   (3-1)

A photodetector including:
an avalanche diode that is provided in a first region of a first base, and amplifies a carrier generated by an incident photon;
a charge storage type photodiode that is provided in a second region adjacent to the first region of the first base in a plane direction of the first base, and converts incident light into electric charge; and
an insulating isolator that is provided between the first region and the second region, and at least electrically isolates the avalanche diode and the charge storage type photodiode from each other.
   (3-2)

The photodetector according to (3-1), in which t the charge storage type photodiode is electrically coupled to a readout circuit via a charge holding section, the readout circuit that reads electric charge, the charge holding section that stores converted electric charge. (3-3)

The photodetector according to (3-2), in which t the readout circuit is provided to overlap the charge storage type photodiode in the second region of the first base.

(3-4)

The photodetector according to (3-2) or (3-3), in which a capacitor is electrically coupled to the charge holding section.

(3-5)

The photodetector according to (3-4), in which the capacitor includes a metal-insulator-semiconductor capacitor element.

(3-6)

The photodetector according to (3-4), in which the capacitor includes a metal-insulator-metal capacitor element.

(3-7)

The photodetector according to any one of (3-1) to (3-6), in which a wavelength band of light incident on the charge storage type photodiode is different from a wavelength band of light incident on the avalanche diode.

(3-8)

The photodetector according to any one of (3-1) to (3-7), in which
a planar shape of the first region is a triangular or more polygonal shape, a circular shape, or an elliptical shape as viewed in a photon incident direction, and
the second region is surrounded by three or more of the first regions in a plane direction.
   (3-9)

The photodetector according to (3-8), in which
the planar shape of the first region is an octagonal shape, and
the second region is surrounded by four of the first regions.
   (3-10)

The photodetector according to any one of (3-1) to (3-9), further including a second base stacked on the first base in a thickness direction of the first base, in which
the readout circuit is provided in the second base.
   (3-11)

The photodetector according to any one of (3-2) to (3-10), in which
a plurality of the charge storage type photodiodes is provided,
a plurality of the charge holding sections is provided for each of the charge storage type photodiodes, and
electric charge stored in the plurality of the charge holding sections is collectively read out.
   (3-12)

The photodetector according to any one of (3-1) to (3-11), further including an analog-to-digital convertor circuit that is electrically coupled to the charge storage type photodiode, and converts electric charge from an analog signal to a digital signal.

(3-13)

The photodetector according to (3-12), in which in the analog-to-digital convertor circuit, readout time of an analog signal is adjusted.

(3-14)

A distance measurement system including:
a photodetector;
a time measurement circuit; and
an analog-to-digital convertor circuit, in which
the photodetector includes
an avalanche diode that is provided in a first region of a first base, and amplifies a carrier generated by an incident photon,
a charge storage type photodiode that is provided in a second region adjacent to the first region of the first base in a plane direction of the first base, and converts incident light into electric charge, and
an insulating isolator that is provided between the first region and the second region, and at least electrically isolates the avalanche diode and the charge storage type photodiode from each other,
the time measurement circuit is electrically coupled to the avalanche diode, and measures time of flight of light, and
the analog-to-digital convertor circuit is electrically coupled to the charge storage type photodiode, and converts electric charge from an analog signal to a digital signal.

The present application claims the benefit of Japanese Priority Patent Application JP2023-017424 filed with the Japan Patent Office on Feb. 8, 2023, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photodetector comprising:
an avalanche diode that is provided in a first region of a first base, and amplifies a carrier generated by an incident photon;
one or more elements that are provided in a second region adjacent to the first region of the first base in a plane direction of the first base, and are different from the avalanche diode; and
an insulating isolator that is provided between the first region and the second region, and at least electrically isolates the avalanche diode and the one or more elements from each other.

2. The photodetector according to claim 1, wherein the one or more elements construct a protective circuit that reduces an overcurrent from the avalanche diode.

3. The photodetector according to claim 2, wherein the one or more elements comprise a resistor element.

4. The photodetector according to claim 3, wherein the resistor element includes silicon.

5. The photodetector according to claim 3, wherein the resistor element is formed by an insulated gate field effect transistor.

6. The photodetector according to claim 5, wherein
a plurality of the insulated gate field effect transistors is provided, and
the plurality of the insulated gate field effect transistors is electrically coupled in series.

7. The photodetector according to claim 3, wherein
one end of the resistor element is electrically coupled to the avalanche diode, and
another end of the resistor element is electrically coupled to a clamp element that clamps an overcurrent.

8. The photodetector according to claim 7, wherein the clamp element is provided in the second region.

9. The photodetector according to claim 2, wherein the avalanche diode is electrically coupled, via the protective circuit, to a readout circuit that reads out the amplified carrier.

10. The photodetector according to claim 9, further comprising a second base stacked on the first base in a thickness direction of the first base, wherein
the readout circuit is provided in the second base.

11. The photodetector according to claim 7, further comprising a second base stacked on the first base in a thickness direction of the first base, wherein
the clamp element is provided in the second base.

12. The photodetector according to claim 1, wherein
a planar shape of the first region is a triangular or more polygonal shape, a circular shape, or an elliptical shape as viewed in a photon incident direction, and
the second region is surrounded by three or more of the first regions in a plane direction.

13. The photodetector according to claim 12, wherein
the planar shape of the first region is an octagonal shape, and
the second region is surrounded by four of the first regions.

14. A distance measurement system comprising:
a photodetector; and
a circuit device, wherein
the photodetector includes
an avalanche diode that is provided in a first region of a first base, and amplifies a carrier generated by an incident photon,
a protective circuit that is provided in a second region adjacent to the first region of the first base in a plane direction of the first base, and includes one or more elements that reduce an overcurrent from the avalanche diode, and
an insulating isolator that is provided between the first region and the second region, and at least electrically isolates the avalanche diode and the one or more elements from each other, and
the circuit device includes
a readout circuit that is electrically coupled to the avalanche diode via the protective circuit, and reads out the amplified carrier, and
a time measurement circuit that is electrically coupled to the readout circuit, and measures time of flight of light.

15. A photodetector comprising:
an avalanche diode that is provided in a first region of a first base, and amplifies a carrier generated by an incident photon;
a light-receiving element that is provided in a second region adjacent to the first region of the first base in a plane direction of the first base, and converts incident light into electric charge; and
an insulating isolator that is provided between the first region and the second region, and at least electrically isolates the avalanche diode and the light-receiving element from each other.

16. The photodetector according to claim 15, wherein the light-receiving element comprises a photodiode.

17. The photodetector according to claim 15, wherein
the light-receiving element includes
a voltage applied section to which a voltage is applied to distribute electric charge converted from light, and
a charge detector that detects the electric charge distributed by the voltage applied section.

18. A distance measurement system comprising:
a photodetector;
a first time measurement circuit; and
a second time measurement circuit, wherein
the photodetector includes
an avalanche diode that is provided in a first region of a first base, and amplifies a carrier generated by an incident photon,
a light-receiving element that is provided in a second region adjacent to the first region of the first base in a plane direction of the first base, and converts incident light into electric charge, and
an insulating isolator that is provided between the first region and the second region, and at least electrically isolates the avalanche diode and the light-receiving element from each other,
the first time measurement circuit is electrically coupled to the avalanche diode, and measures time of flight of light, and
the second time measurement circuit is electrically coupled to the light-receiving element, and measures time of flight of light at a shorter distance than the first time measurement circuit.

19. A photodetector comprising:
an avalanche diode that is provided in a first region of a first base, and amplifies a carrier generated by an incident photon;
a charge storage type photodiode that is provided in a second region adjacent to the first region of the first base in a plane direction of the first base, and converts incident light into electric charge; and
an insulating isolator that is provided between the first region and the second region, and at least electrically isolates the avalanche diode and the charge storage type photodiode from each other.

20. The photodetector according to claim 19, wherein the charge storage type photodiode is electrically coupled to a readout circuit via a charge holding section, the readout circuit that reads electric charge, the charge holding section that stores converted electric charge.

21. The photodetector according to claim 20, wherein the readout circuit is provided to overlap the charge storage type photodiode in the second region of the first base.

22. The photodetector according to claim 20, wherein a capacitor is electrically coupled to the charge holding section.

23. The photodetector according to claim 19, wherein a wavelength band of light incident on the charge storage type photodiode is different from a wavelength band of light incident on the avalanche diode.

24. The photodetector according to claim 20, wherein
a plurality of the charge storage type photodiodes is provided,
a plurality of the charge holding sections is provided for each of the charge storage type photodiodes, and
electric charge stored in the plurality of the charge holding sections is collectively read out.

25. The photodetector according to claim 19, further comprising an analog-to-digital convertor circuit that is electrically coupled to the charge storage type photodiode, and converts electric charge from an analog signal to a digital signal.

26. A distance measurement system comprising:
a photodetector;
a time measurement circuit; and
an analog-to-digital convertor circuit, wherein
the photodetector includes
an avalanche diode that is provided in a first region of a first base, and amplifies a carrier generated by an incident photon,
a charge storage type photodiode that is provided in a second region adjacent to the first region of the first base in a plane direction of the first base, and converts incident light into electric charge, and
an insulating isolator that is provided between the first region and the second region, and at least electrically isolates the avalanche diode and the charge storage type photodiode from each other,
the time measurement circuit is electrically coupled to the avalanche diode, and measures time of flight of light, and
the analog-to-digital convertor circuit is electrically coupled to the charge storage type photodiode, and converts electric charge from an analog signal to a digital signal.
